(19) United States
(12) Patent Application Publication
(10) Pub. No.: US 2022/0310923 A1
(43) Pub. Date: Sep. 29, 2022

(54) LIGHT EMITTING ELEMENT

(71) Applicant: SAMSUNG DISPLAY CO., LTD., Yongin-si (KR)

(72) Inventors: Sun Young Pak, Suwon-si (KR); Taeil Kim, Hwaseong-si (KR); Junha Park, Gwacheon-si (KR); Jang Yeol Baek, Yongin-si (KR); Kyoung Sunwoo, Hwaseong-si (KR); Mun-Ki Sim, Seoul (KR); Chanseok Oh, Seoul (KR); Minjung Jung, Hongcheon-gun (KR)

(21) Appl. No.: 17/564,165

(22) Filed: Dec. 28, 2021

(30) Foreign Application Priority Data
Mar. 19, 2021 (KR) 10-2021-0036034

(51) Int. Cl. H01L 51/00

(52) U.S. Cl. CPC H01L 51/008; H01L 51/0072; H01L 51/0073; H01L 51/0074; H01L 51/006; H01L 51/5064

(57) ABSTRACT

A light emitting element includes a first electrode, a second electrode, and an emission layer between the first electrode and the second electrode and including a polycyclic compound represented by Formula 1 below, thereby exhibiting high luminous efficiency characteristics. In Formula 1, the substituents are the same as defined in the Detailed Description.

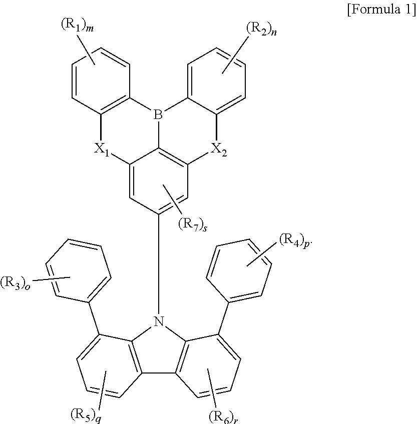

### CROSS-REFERENCE TO RELATED APPLICATION

This application claims priority to and the benefit of Korean Patent Application No. 10-2021-0036034, filed on Mar. 19, 2021, the entire content of which is hereby incorporated by reference.

### BACKGROUND

The present disclosure herein relates to a light emitting element, and more particularly, to a light emitting element including a polycyclic compound in an emission layer.

Recently, the development of an organic electroluminescence display device as an image display device is being actively conducted. Unlike liquid crystal display devices and/or the like, the organic electroluminescence display device is a so-called self-luminescent display device, in which holes and electrons injected from a first electrode and a second electrode recombine in an emission layer, and thus a luminescent material (including an organic compound) in the emission layer emits light to implement display (e.g., to display an image).

In the application of a light emitting element to a display device, there is a desire (e.g., a demand) for a light emitting element having a low driving voltage, a high luminous efficiency, and/or a long service life (e.g., long lifespan), and the development of materials for a light emitting element capable of stably attaining such characteristics is being continuously pursued (e.g., required).

### SUMMARY

An aspect according to embodiments of the present disclosure is directed toward a light emitting element with high luminous efficiency.

According to an embodiment of the present disclosure, a light emitting element includes: a first electrode; a second electrode on the first electrode; and an emission layer between the first electrode and the second electrode and including a polycyclic compound represented by Formula 1, wherein the first electrode and the second electrode each independently include Ag, Mg, Cu, Al, Pt, Pd, Au, Ni, Nd, Ir, Cr, Li, Ca, LiF/Ca, LiF/Al, Mo, Ti, W, In, Sn, Zn, a compound of two or more thereof, a mixture of two or more thereof, or an oxide thereof.

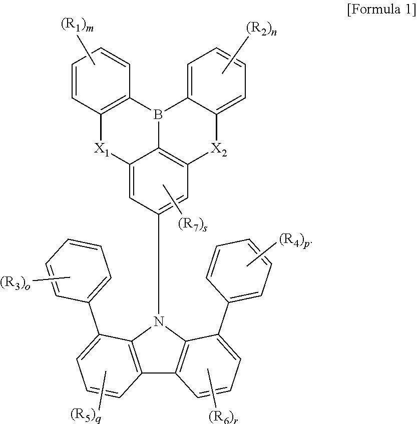

In Formula 1, m and n are each independently an integer of 0 to 4, o and p are each independently an integer of 0 to 5, q and r are each independently an integer of 0 to 3, s is an integer of 0 to 2; R₁ to R₇ are each independently a hydrogen atom, a deuterium atom, a halogen atom, a cyano group, a nitro group, a hydroxy group, a substituted or unsubstituted alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted oxy group, a substituted or unsubstituted thio (e.g., thiol) group, or a substituted or unsubstituted amine group, and/or bonded to an adjacent group to form a ring; X₁ and X₂ are each independently NRₐ, O, S, or Se, and Rₐ is a substituted or unsubstituted aryl group having 6 to 12 ring-forming carbon atoms, or a substituted or unsubstituted heteroaryl group having 2 to 15 ring-forming carbon atoms, and/or bonded to an adjacent group to form a ring.

In Formula 1, X₁ and X₂ may be the same.

In an embodiment, the polycyclic compound represented by Formula 1 may be represented by any one selected among Formula 2A to Formula 2D:

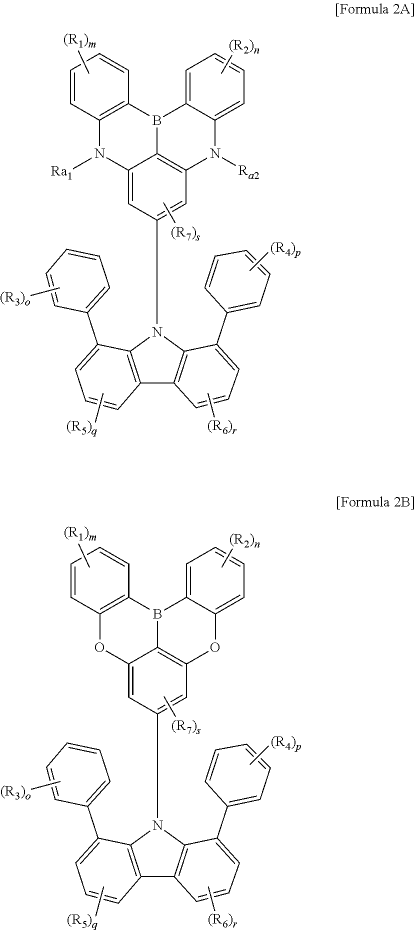

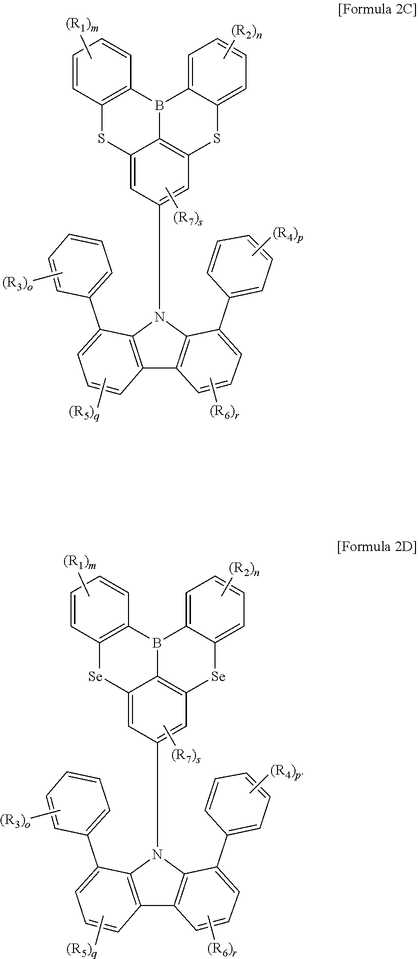

In Formula 2A, Rₐ₁ and Rₐ₂ are each independently a substituted or unsubstituted phenyl group, a substituted or unsubstituted biphenyl group, a substituted or unsubstituted carbazole group, or a substituted or unsubstituted furan group, and/or bonded to an adjacent group to form a ring; and in Formula 2A to Formula 2D, m to s and R₁ to R₇ are the same as respectively defined in connection with Formula 1.

In an embodiment, the polycyclic compound represented by Formula 2A may be represented by any one selected among Formula 2A-1 to Formula 2A-5:

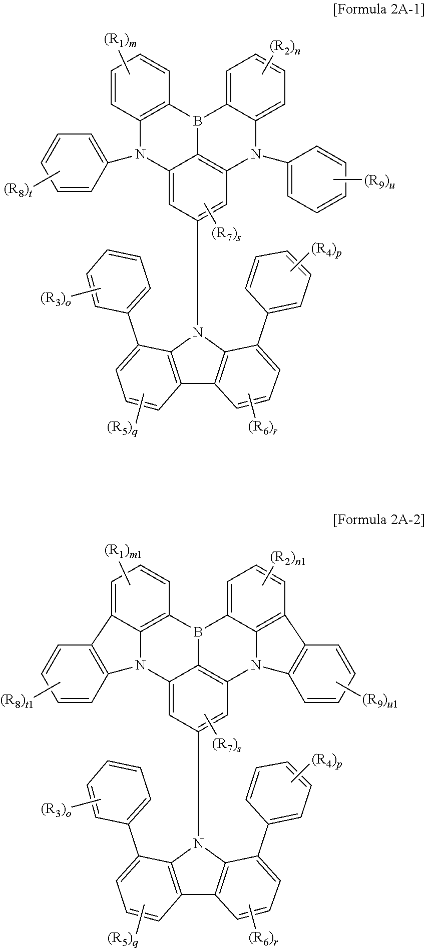

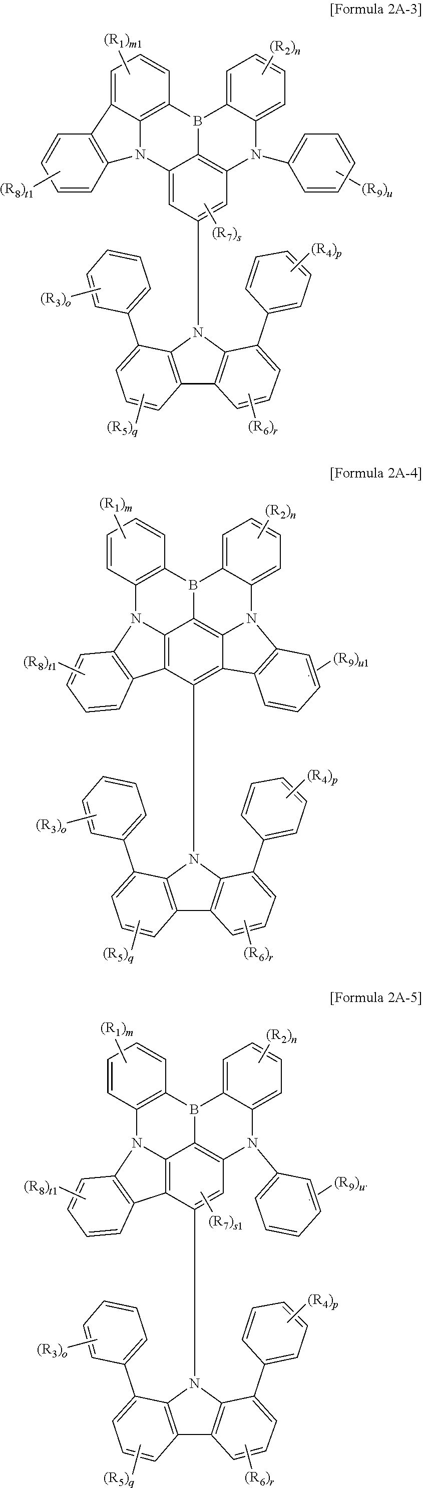

In Formulae 2A-1 to 2A-5, m1 and n1 are each independently an integer of 0 to 3, t and u are each independently an integer of 0 to 5, t1 and u1 are each independently an integer of 0 to 4, s1 is 0 or 1; R₈ and R₉ are each independently a substituted or unsubstituted methyl group, a substituted or unsubstituted t-butyl group, a substituted or unsubstituted phenyl group, a substituted or unsubstituted oxy group, a substituted or unsubstituted thio group, or a substituted or unsubstituted amine group, and/or bonded to an adjacent group to form a ring; and R₁ to R₇ and m to s are the same as respectively defined in connection with Formula 1.

In an embodiment, in Formulae 2A-1 to 2A-5, R₈ and R₉ may be each independently represented by any one selected among moieties represented by Formulae 2A-1 to 2A-17:

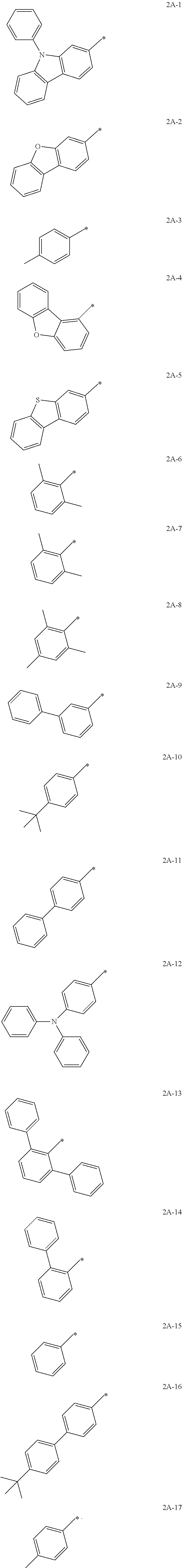

In Formula 1, X₁ and X₂ may be different from each other.

In an embodiment, the polycyclic compound represented by Formula 1 may be represented by Formula 3A:

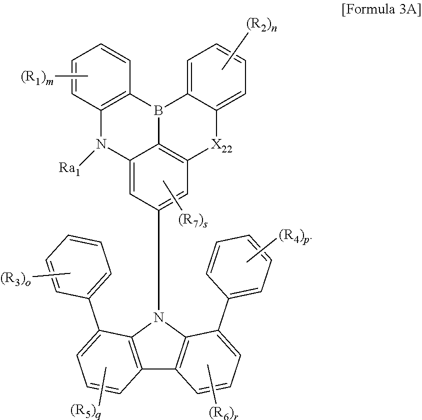

In Formula 3A, X₂₂ is O, S, or Se; Rₐ₁ is a substituted or unsubstituted phenyl group, a substituted or unsubstituted biphenyl group, a substituted or unsubstituted carbazole group, or a substituted or unsubstituted furan group, and/or bonded to an adjacent group to form a ring; and R₁ to R₇ and m to s are the same as respectively defined in connection with Formula 1.

In an embodiment, the polycyclic compound represented by Formula 3A may be represented by any one selected among Formula 3A-1 to Formula 3A-3:

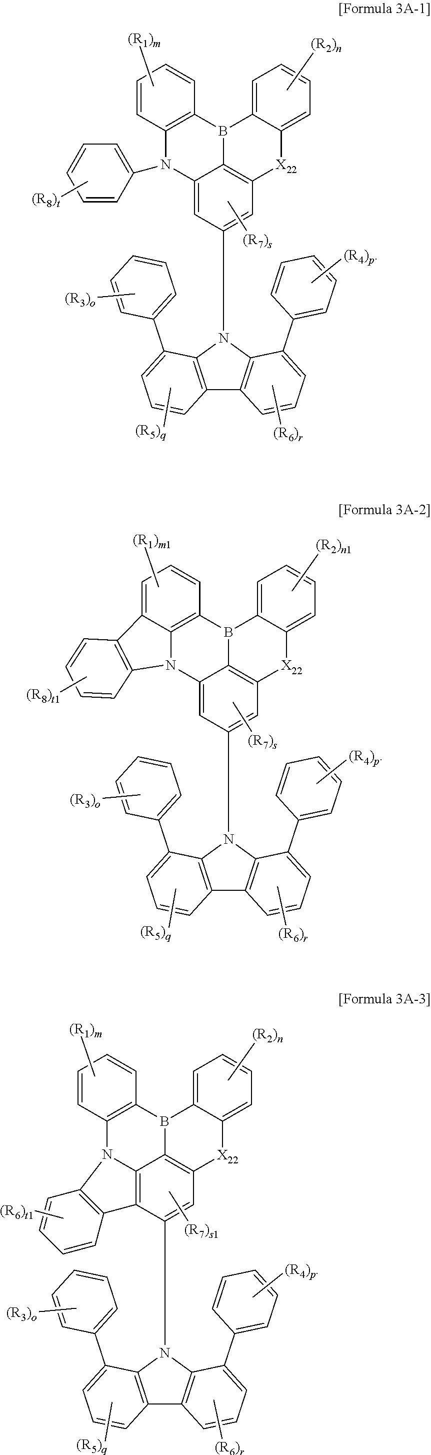

In Formula 3A-1 to Formula 3A-3, t is an integer of 0 to 5, s1 is 0 or 1, m1 is an integer of 0 to 3, t1 is an integer of 0 to 4; R₈ is a substituted or unsubstituted methyl group, a substituted or unsubstituted t-butyl group, a substituted or unsubstituted phenyl group, a substituted or unsubstituted oxy group, a substituted or unsubstituted thio group, or a substituted or unsubstituted amine group, and/or bonded to an adjacent group to form a ring; X₂₂ is the same as defined in connection with Formula 3A, and R₁ to R₇ and m to s are the same as respectively defined in connection with Formula 1.

In an embodiment, in Formula 3A-1 to Formula 3A-3, R₈ may be represented by any one selected among moieties represented by Formulae 2A-1 to 2A-17:

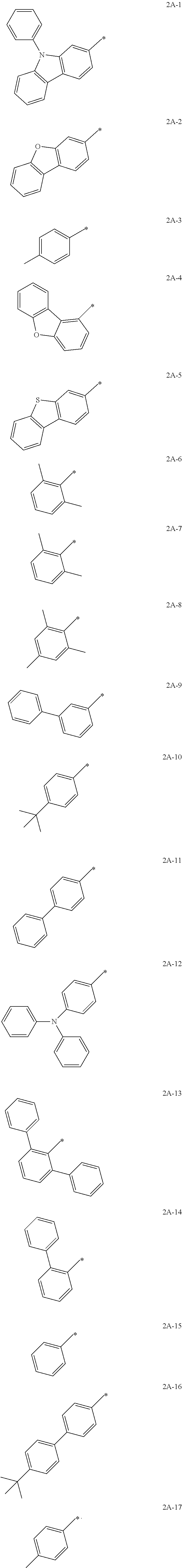

In an embodiment, the polycyclic compound represented by Formula 1 may be represented by Formula 4-1 or Formula 4-2:

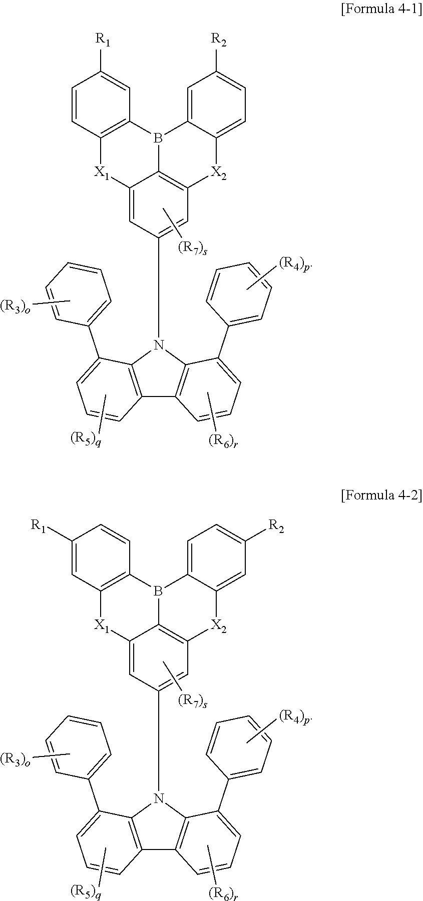

In Formula 4-1 and Formula 4-2, R₁ and R₂ are each independently a substituted or unsubstituted t-butyl group, a substituted or unsubstituted phenyl group, a substituted or unsubstituted thio group, a substituted or unsubstituted amine group, or a substituted or unsubstituted oxy group, and/or bonded to an adjacent group to form a ring; and o to s, X₁, X₂, and R₃ to R₇ are the same as respectively defined in connection with Formula 1.

In an embodiment, the polycyclic compound represented by Formula 4-1 may be represented by any one selected among Formula 4A to Formula 4C:

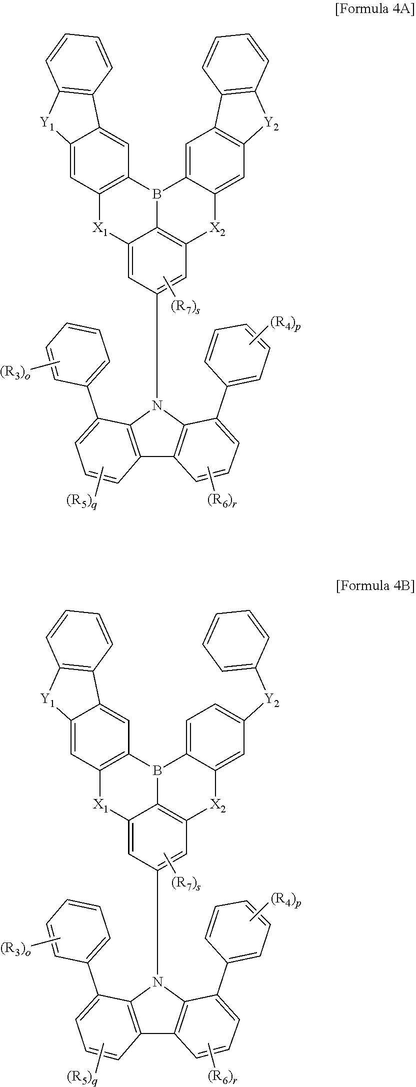

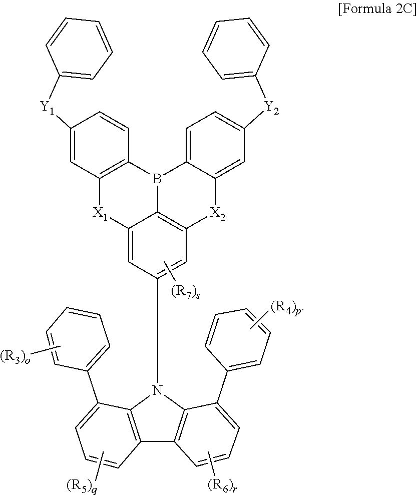

In Formulae 4A to 4C, Y₁ and Y₂ are each independently O, S, or NRₑ, Rₑ is a substituted or unsubstituted phenyl group, and X₁, X₂, R₃ to R₇, and o to s are the same as respectively defined in connection with Formula 1.

In an embodiment, the polycyclic compound represented by Formula 1 may be represented by Formula 5:

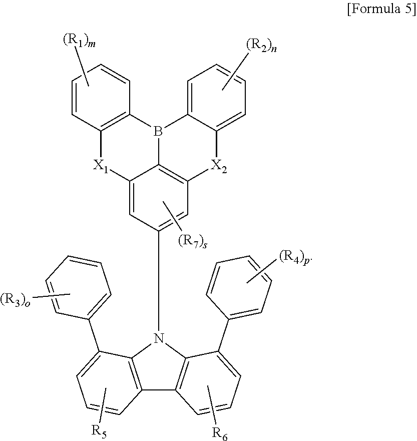

In Formula 5, R₅ and R₆ are each independently an unsubstituted methyl group, an unsubstituted t-butyl group, or a cyano group; and m to p, s, X₁, X₂, R₁ to R₄, and R₇ are the same as respectively defined in connection with Formula 1.

In an embodiment, the polycyclic compound represented by Formula 1 may be represented by Formula 6-1 or Formula 6-2:

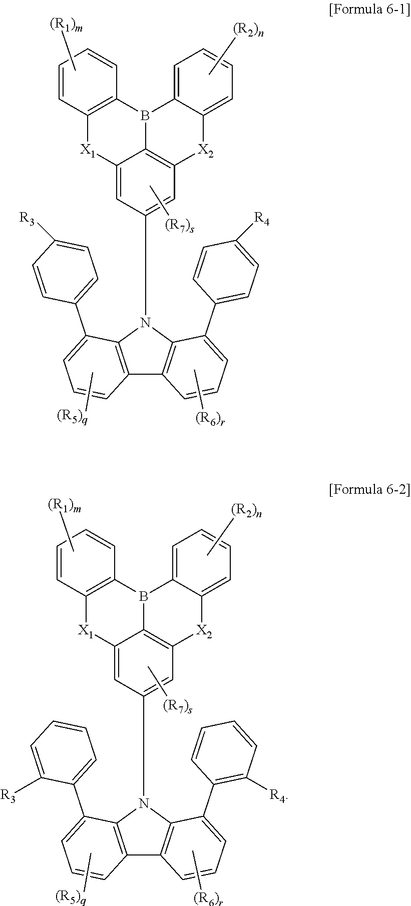

In Formula 6-1 and Formula 6-2, R₃ and R₄ are each independently a substituted or unsubstituted t-butyl group, a fluorine group, or a substituted or unsubstituted oxy group, the substituted or unsubstituted oxy group being optionally banded to an adjacent group to form a ring; and m, n, q to s, X₁, X₂, R₁, R₂, and R₅ to R₇ are the same as respectively defined in connection with Formula 1.

In an embodiment, the emission layer may be to emit blue light.

In an embodiment, the emission layer may include a dopant and a host, and the dopant may include the polycyclic compound.

In an embodiment, the polycyclic compound may be to emit thermally activated delayed fluorescence.

In an embodiment, the light emitting element may further include a hole transport region between the first electrode and the emission layer, and the hole transport region may include Compound G-1 or Compound G-2:

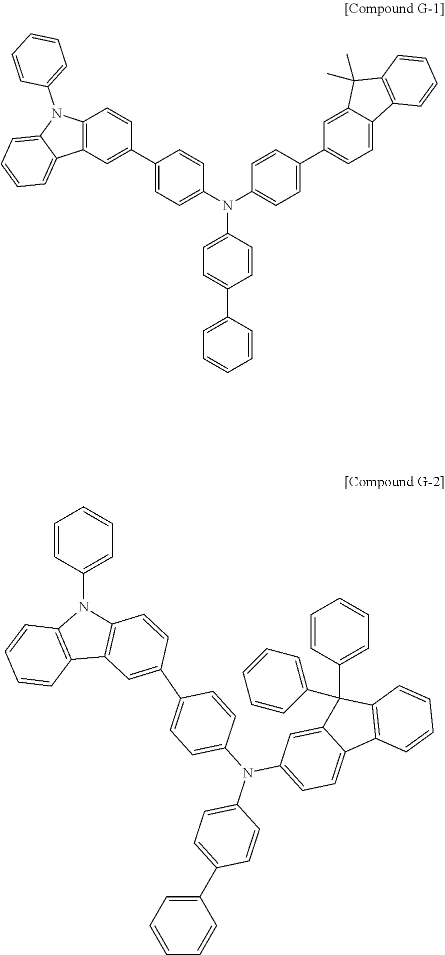 [SMILES: CC1(C)c2ccccc2-c2ccc(-c3ccc(N(c4ccc(-c5ccccc5)cc4)c4ccc(-c5ccc6c(c5)c5ccccc5n6-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In an embodiment of the present disclosure, a light emitting element includes a first electrode, a hole transport region on the first electrode and including Compound G-1 or Compound G-2, a second electrode on the hole transport region, and an emission layer between the hole transport region and the second electrode and including a polycyclic compound represented by formula 1:

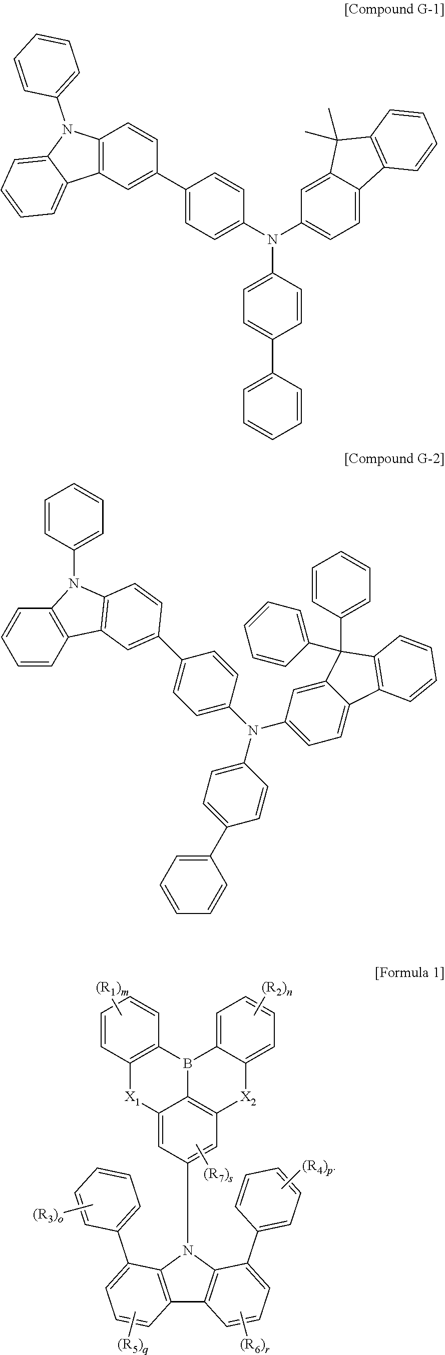

In Formula 1, m and n are each independently an integer of 0 to 4, o and p are each independently an integer of 0 to 5, q and r are each independently an integer of 0 to 3, s is an integer of 0 to 2; R₁ to R₇ are each independently a hydrogen atom, a deuterium atom, a halogen atom, a cyano group, a nitro group, a hydroxy group, a substituted or unsubstituted alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted oxy group, a substituted or unsubstituted thio group, or a substituted or unsubstituted amine group, and/or bonded to an adjacent group to form a ring; X₁ and X₂ are each independently NRₐ, O, S, or Se, and Rₐ is a substituted or unsubstituted aryl group having 6 to 12 ring-forming carbon atoms, or a substituted or unsubstituted heteroaryl group having 2 to 15 ring-forming carbon atoms, and/or bonded to an adjacent group to form a ring.

In an embodiment, the polycyclic compound represented by Formula 1 may be represented by any one selected among Formula 7-1 to Formula 7-5:

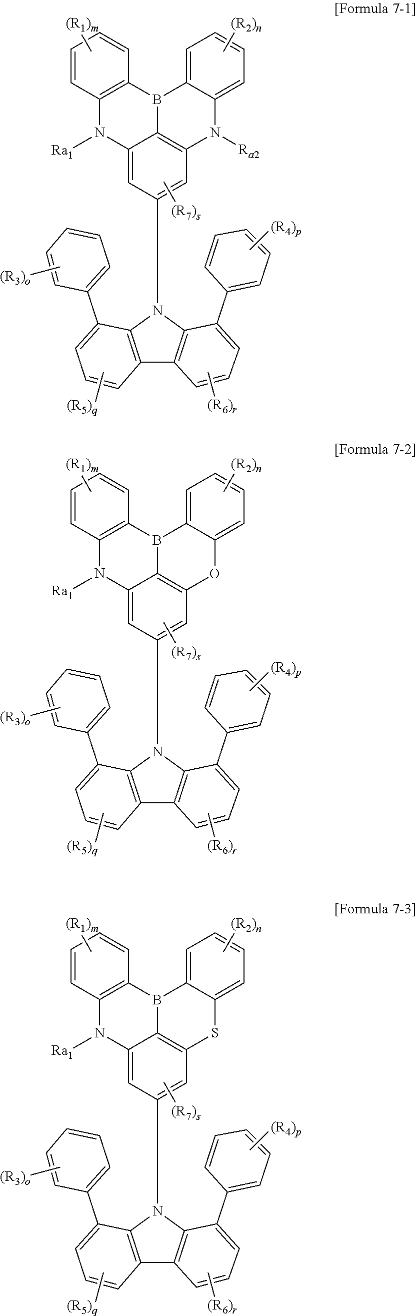

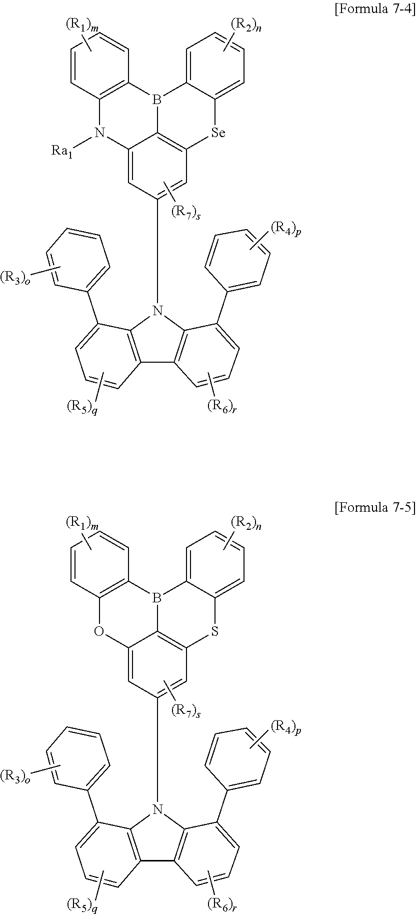

In Formula 7-1 to Formula 7-5, Rₐ₁ and Rₐ₂ are each independently a hydrogen atom, a deuterium atom, a halogen atom, a cyano group, a nitro group, a hydroxy group, an alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted alkoxy group, a substituted or unsubstituted thio group, or a substituted or unsubstituted amine group, and/or bonded to an adjacent group to form a ring; and m to s, and R₁ to R₇ are the same as respectively defined in connection with Formula 1.

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the present disclosure. In the drawings:

FIG. 1 is a plan view of a display device according to an embodiment of the present disclosure;

FIG. 2 is a cross-sectional view of a display device according to an embodiment of the present disclosure;

FIG. 3 is a cross-sectional view schematically illustrating a light emitting element according to an embodiment of the present disclosure;

FIG. 4 is a cross-sectional view schematically illustrating a light emitting element according to an embodiment of the present disclosure;

FIG. 5 is a cross-sectional view schematically illustrating a light emitting element according to an embodiment of the present disclosure;

FIG. 6 is a cross-sectional view schematically illustrating a light emitting element according to an embodiment of the present disclosure;

FIG. 7 is a cross-sectional view of a display device according to an embodiment of the present disclosure; and

FIG. 8 is a cross-sectional view of a display device according to an embodiment of the present disclosure.

### DETAILED DESCRIPTION

The subject matter of the present disclosure may be modified in many alternate forms, and thus specific embodiments will be shown in the drawings and described in more detail. It should be understood, however, that it is not intended to limit the subject matter of the present disclosure to the particular forms disclosed, but rather, is intended to cover all modifications, equivalents, and alternatives falling within the spirit and scope of the present disclosure, and equivalents thereof.

When explaining each of the drawings, like reference numbers are used for referring to like elements. In the accompanying drawings, the dimensions of each structure may be exaggerated for clarity. It will be understood that, although the terms “first,” “second,” etc. may be used herein to describe various elements, these elements should not be limited by these terms. These terms are only used to distinguish one element from another. For example, a first element may be referred to as a second element, and, similarly, a second element may be referred to as a first element, without departing from the scope of the present disclosure. The terms of a singular form may include plural forms unless the context clearly indicates otherwise.

In the present description, it will be understood that terms such as “include,” “have,” “comprise,” etc., specify the presence of a feature, a fixed number, a step (task), an operation, an element, a component, or a combination thereof disclosed in the specification, but do not exclude the possibility of presence or addition of one or more other features, fixed numbers, steps (tasks), operations, elements, components, or combinations thereof.

In the present description, when a part such as a layer, a film, a region, or a plate is referred to as being “on” or “above” another part, it can be directly on the other part, or an intervening part may also be present. On the contrary, when a part such as a layer, a film, a region, or a plate is referred to as being “under” or “below” another part, it can be directly under the other part, or an intervening part may also be present. In addition, it will be understood that when a part is referred to as being “on” another part, it can be disposed on the other part, or disposed under the other part as well.

In the specification, the term “substituted or unsubstituted” may refer to a functional group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the substituents described above may be substituted or unsubstituted. For example, a biphenyl group may be interpreted as an aryl group or a phenyl group substituted with a phenyl group.

In the specification, the phrase “bonded to an adjacent group to form a ring” may indicate that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by adjacent groups being bonded to each other may be connected to another ring to form a spiro structure.

In the specification, the term “adjacent group” may refer to a substituent substituted for an atom which is directly bonded to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be a linear, branched or cyclic alkyl group. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the present disclosure is not limited thereto.

The term “hydrocarbon ring group” as used herein may refer to any functional group or substituent derived from an aliphatic hydrocarbon ring. The hydrocarbon ring group may be a saturated hydrocarbon ring group having 5 to 20 ring-forming carbon atoms.

The term “aryl group” as used herein may refer to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the present disclosure is not limited thereto.

In the specification, the fluorenyl group may be substituted, and two substituents may be bonded to each other to form a spiro structure. Examples of cases where the fluorenyl group is substituted may be as follows. However, the present disclosure is not limited thereto.

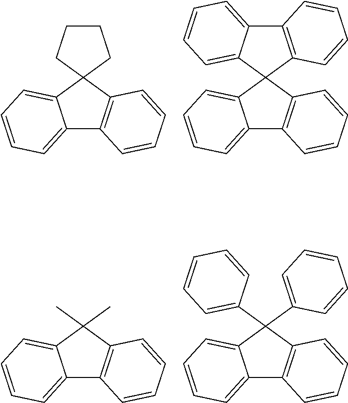

The term “heterocyclic group” as used herein may refer to any functional group or substituent derived from a ring including at least one of B, O, N, P, Si, or Se as a ring-forming heteroatom. The heterocyclic group may include an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the term “heterocyclic group” may include at least one of B, O, N, P, Si or S as a ring-forming heteroatom. When the heterocyclic group includes two or more heteroatoms, the two or more heteroatoms may be the same as or different from each other. The heterocyclic group may be a monocyclic heterocyclic group or a polycyclic heterocyclic group and may include a heteroaryl group. The number of ring-forming carbon atoms in the heterocyclic group may be 2 to 30, 2 to 20, or 2 to 10.

In the specification, the aliphatic heterocyclic group may include one or more among B, O, N, P, Si, and S as a ring-forming heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the present disclosure is not limited thereto.

The term “heteroaryl group” as used herein may include at least one of B, O, N, P, Si, or S as a ring-forming heteroatom. When the heteroaryl group contains two or more heteroatoms, the two or more heteroatoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a triazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the present disclosure is not limited thereto.

In the specification, the above description on the aryl group may be applied to an arylene group except that the arylene group is a divalent group. The above description on the heteroaryl group may be applied to a heteroarylene group except that the heteroarylene group is a divalent group.

In the specification, the silyl group includes an alkyl silyl group and an aryl silyl group. Examples of the silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, the present disclosure is not limited thereto.

In the specification, the number of carbon atoms in an amino group is not specifically limited, but may be 1 to 30. The amino group may include an alkyl amino group, an aryl amino group, or a heteroaryl amino group. Examples of the amino group may include a methylamino group, a dimethylamino group, a phenylamino group, a diphenylamino group, a naphthylamino group, a 9-methyl-anthracenylamino group, a triphenylamino group, etc., but the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the present disclosure is not limited thereto.

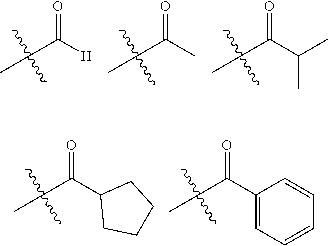

In the specification, the number of carbon atoms in a sulfinyl group and a sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

The term “thio group” or “thiol group” as used herein may include an alkylthio group and an arylthio group. The thio group or “thiol group” may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the present disclosure is not limited thereto.

The term “oxy group” as used herein may refer to that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but the present disclosure is not limited thereto.

The term “boron group” as used herein may refer to that a boron atom is bonded to the alkyl group or the aryl group as defined above. The boron group may include an alkyl boron group and an aryl boron group. Examples of the boron group may include a trimethylboron group, a triethylboron group, a t-butyldimethylboron group, a triphenylboron group, a diphenylboron group, a phenylboron group, etc., but the present disclosure is not limited thereto.

In the specification, the alkenyl group may be linear or branched. The number of carbon atoms in the alkenyl group is not specifically limited, but may be 2 to 30, 2 to 20, or 2 to 10. Non-limiting examples of the alkenyl group may include a vinyl group, a 1-butenyl group, a 1-pentenyl group, a 1,3-butadienyl aryl group, a styrenyl group, a styrylvinyl group, etc.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but the present disclosure is not limited thereto.

In the specification, the alkyl group in each of the alkylthio group, the alkylsulfoxy group, the alkylaryl group, the alkylamino group, the alkyl boron group, the alkyl silyl group, and the alkyl amine group may be the same as the examples of the alkyl group described above.

In the specification, the aryl group in each of the aryloxy group, the arylthio group, the arylsulfoxy group, the arylamino group, the arylboron group, the aryl silyl group, and the arylamine group may be the same as the examples of the aryl group described above.

The term “a direct linkage” as used herein may refer to a single bond (e.g., a single covalent bond).

In the specification,

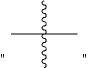

and [symbol] each refer to a position to be connected.

Hereinafter, embodiments of the present disclosure will be described with reference to the accompanying drawings.

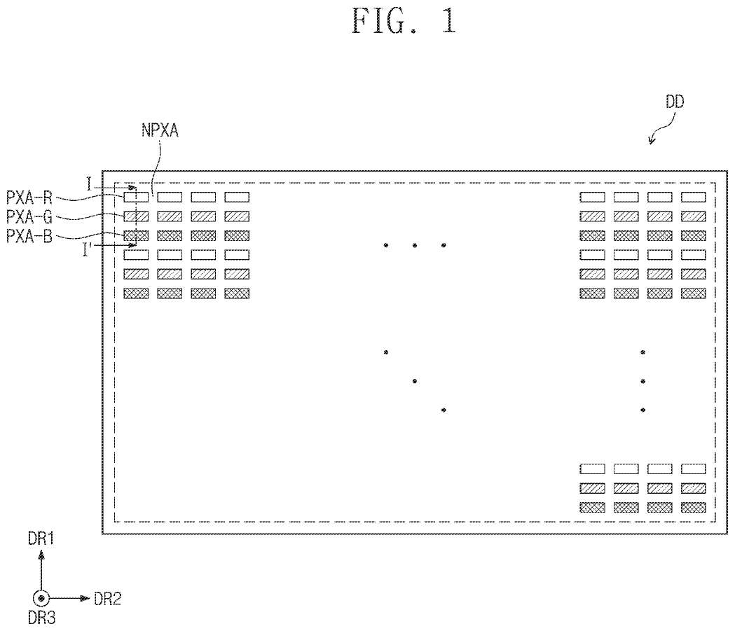

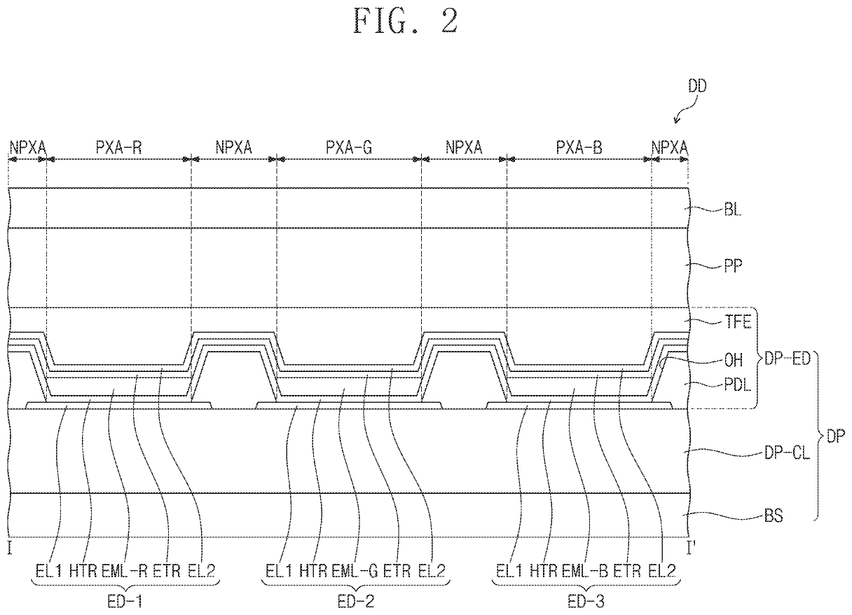

FIG. 1 is a plan view of a display device DD according to an embodiment. FIG. 2 is a cross-sectional view of the display device DD according to an embodiment. FIG. 2 is a cross-sectional view illustrating a part taken along the line I-I′ of FIG. 1.

The display device DD may include a display panel DP and an optical layer PP disposed on the display panel DP. The display panel DP includes light emitting elements ED-1, ED-2, and ED-3. The display device DD may include a plurality of light emitting elements ED-1, ED-2, and ED-3. The optical layer PP may be disposed on the display panel DP and control reflected light in the display panel DP due to external light. The optical layer PP may include, for example, a polarization layer or a color filter layer. In one or more embodiments, different from the one shown in the drawings, the optical layer PP may be omitted from the display device DD of an embodiment.

A base substrate BL may be disposed on the optical layer PP. The base substrate BL may be a member which provides a base surface on which the optical layer PP is disposed. The base substrate BL may be a glass substrate, a metal substrate, a plastic substrate, etc. However, the present disclosure is not limited thereto, and the base substrate BL may be an inorganic layer, an organic layer, or a composite material layer. In an embodiment, different from the one shown, the base substrate BL may be omitted.

The display device DD according to an embodiment may further include a filling layer. The filling layer may be disposed between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and a display element layer DP-ED. The display element layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may be a member which provides a base surface on which the display element layer DP-ED is disposed. The base layer BS may be a glass substrate, a metal substrate, a plastic substrate, etc. However, the present disclosure is not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor in order to drive the light emitting elements ED-1, ED-2, and ED-3 of the display element layer DP-ED.

Each of the light emitting elements ED-1, ED-2, and ED-3 may have a structure of a light emitting element ED of an embodiment according to FIGS. 3 to 6, which will be described in more detail later. Each of the light emitting elements ED-1, ED-2 and ED-3 may include a first electrode EL1, a hole transport region HTR, emission layer(s) EML (EML-R, EML-G and/or EML-B (e.g., a corresponding one of the emission layer EML-R, the emission layer EML-G, or the emission layer EML-B)), an electron transport region ETR, and a second electrode EL2.

FIG. 2 illustrates an embodiment in which the emission layers EML-R, EML-G, and EML-B of the light emitting elements ED-1, ED-2, and ED-3 are disposed in the openings OH defined in the pixel defining film PDL, and the hole transport region HTR, the electron transport region ETR, and the second electrode EL2 are provided as a common layer in the entire light emitting elements ED-1, ED-2, and ED-3. However, the present disclosure is not limited thereto, and unlike (different from) the one illustrated in FIG. 2, the hole transport region HTR and the electron transport region ETR in an embodiment may be provided by being patterned inside the opening OH defined in the pixel defining film PDL. For example, the hole transport region HTR, the emission layers EML-R, EML-G, and EML-B, and the electron transport region ETR of the light emitting elements ED-1, ED-2, and ED-3 in an embodiment may be provided by being patterned through an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be formed as one layer or by laminating a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but the present disclosure is not particularly limited thereto. The encapsulation-organic film may include an acrylic-based compound, an epoxy-based compound, and/or the like. The encapsulation-organic film may include a photopolymerizable organic material, but the present disclosure is not particularly limited thereto.

The encapsulation layer TFE may be disposed on the second electrode EL2 and may be disposed to fill the opening OH.

Referring to FIGS. 1 and 2, the display device DD may include a non-light emitting region NPXA and light emitting regions PXA-R, PXA-G and PXA-B. The light emitting regions PXA-R, PXA-G and PXA-B each may be a region which emits light generated from the light emitting elements ED-1, ED-2 and ED-3, respectively. The light emitting regions PXA-R, PXA-G, and PXA-B may be spaced apart from one another on a plane (e.g., in a plan view).

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In one or more embodiments, each of the light emitting regions PXA-R, PXA-G, and PXA-B may correspond to a pixel. The pixel defining film PDL may separate the light emitting elements ED-1, ED-2, and ED-3. The emission layers EML-R, EML-G and EML-B of the light emitting elements ED-1, ED-2 and ED-3 may be disposed in openings OH defined by the pixel defining film PDL and separated from one another.

The light emitting regions PXA-R, PXA-G and PXA-B may be divided into a plurality of groups according to the color of light generated from the light emitting elements ED-1, ED-2 and ED-3. In the display device DD of an embodiment shown in FIGS. 1 and 2, three light emitting regions PXA-R, PXA-G, and PXA-B which emit red light, green light, and blue light, respectively are illustrated as an example. For example, the display device DD of an embodiment may include the red light emitting region PXA-R, the green light emitting region PXA-G, and the blue light emitting region PXA-B, which are separated from one another.

In the display device DD according to an embodiment, the plurality of light emitting elements ED-1, ED-2 and ED-3 may emit light (e.g., light beams) having wavelengths different from one another. For example, in an embodiment, the display device DD may include a first light emitting element ED-1 that emits red light, a second light emitting element ED-2 that emits green light, and a third light emitting element ED-3 that emits blue light. That is, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the present disclosure is not limited thereto, and the first to third light emitting elements ED-1, ED-2, and ED-3 may emit light (e.g., light beams) in the same wavelength range or at least one light emitting element may emit light (e.g., light beam) in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In addition, the red light emitting region PXA-R, the green light emitting region PXA-G, and the blue light emitting region PXA-B may be alternately arranged in the stated order along a first directional axis DR1.

FIGS. 1 and 2 illustrate that all the light emitting regions PXA-R, PXA-G, and PXA-B have similar area, but the present disclosure is not limited thereto, and the light emitting regions PXA-R, PXA-G, and PXA-B may have different areas from one another according to a wavelength range of the emitted light. In one or more embodiments, the areas of the light emitting regions PXA-R, PXA-G, and PXA-B may refer to areas when viewed in or on a plane defined by the first directional axis DR1 and the second directional axis DR2 (e.g., in a plan view).

In one or more embodiments, the arrangement form of the light emitting regions PXA-R, PXA-G, and PXA-B is not limited to the one illustrated in FIG. 1, and the order in which the red light emitting region PXA-R, the green light emitting region PXA-G, and the blue light emitting region PXA-B are arranged may be variously combined and provided according to characteristics of a display quality desired for the display device DD. For example, the light emitting regions PXA-R, PXA-G, and PXA-B may be arranged in the form of a PENTILE® arrangement form (e.g., an RGBG matrix, RGBG structure, or RGBG matrix structure) or a diamond arrangement form.

PENTILE® is a duly registered trademark of Samsung Display Co., Ltd.

In addition, the areas of the light emitting regions PXA-R, PXA-G, and PXA-B may be different from one another. For example, in an embodiment, the area of the green light emitting region PXA-G may be smaller than that of the blue light emitting region PXA-B, but the present disclosure is not limited thereto.

Hereinafter, FIGS. 3 to 6 are cross-sectional views schematically illustrating light emitting elements according to embodiments. Each of the light emitting elements ED according to embodiments may include a first electrode EL1, a hole transport region HTR, an emission layer EML, an electron transport region ETR, and a second electrode EL2 that are sequentially stacked.

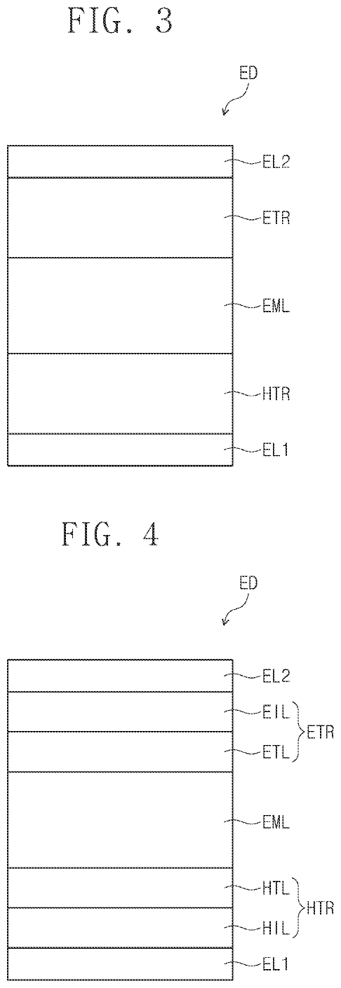

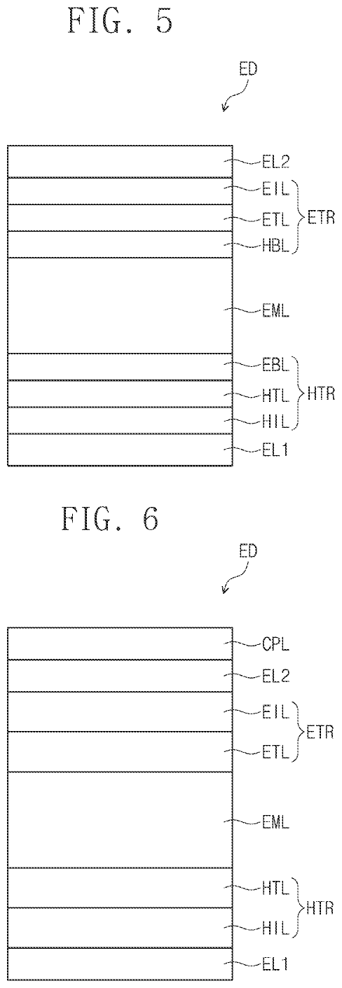

Compared to FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. In addition, compared to FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared to FIG. 4, FIG. 6 illustrates a cross-sectional view of a light emitting element ED of an embodiment including a capping layer CPL disposed on a second electrode EL2.

The first electrode EL1 has conductivity (e.g., electrical conductivity). The first electrode EL1 may be formed of a metal material, a metal alloy, or a conductive compound. The first electrode EL1 may be an anode or a cathode. However, the present disclosure is not limited thereto. In addition, the first electrode EL1 may be a pixel electrode. The first electrode EL1 may be a transmissive electrode, a transflective electrode, or a reflective electrode. When the first electrode EL1 is the transmissive electrode, the first electrode EL1 may be formed utilizing a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (e.g., a mixture of Ag and Mg). In the present disclosure, LiF/Ca may refer to a two-layer structure in which LiF is stacked on Ca, and LiF/Al may refer to a two-layer structure in which LiF is stacked on Al. In one or more embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the present disclosure is not limited thereto. In some embodiments, the first electrode EL1 may include one or more of the above-described metal materials, a combination of two or more metal materials selected from the above-described metal materials, or one or more oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The emission layer EML is provided on the first electrode EL1. The emission layer EML may have a thickness of, for example, about 100 Å to about 1,000 Å, or about 100 Å to about 300 Å. The emission layer EML may have a single layer structure formed of a single material, a single layer structure formed of a plurality of different materials, or a multilayer structure having a plurality of layers formed of a plurality of different materials.

The emission layer EML in the light emitting element ED of an embodiment may include a polycyclic compound represented by Formula 1 below:

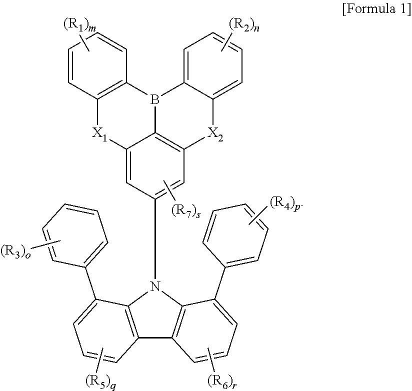

In Formula 1, m and n may be each independently an integer of 0 to 4. For example, when m is 0, R₁ is not substituted (e.g., is not included as a substituent), when m is 1, one R₁ is substituted (e.g., one R₁ is included as a substituent), and when m is 2, two R₁'s are substituted (e.g., two R₁'s are included as substituents). When m 20 is 2 or greater, a plurality of R₁'s may all be the same or at least one may be different from the rest.

When n is 0, R₂ is not substituted (e.g., is not included as a substituent), when n is 1, one R₂ is substituted (e.g., one R₂ is included as a substituent), and when n is 2, two R's are substituted (e.g., two R's are included as substituents). When n is 2, a plurality of R₂'S may all be the same as or different from each other.

o and p may be each independently an integer of 0 to 5. For example, when o is 0, R₃ is not substituted (e.g., is not included as a substituent), when o is 1, one R₃ is substituted (e.g., one R₃ is included as a substituent), and when o is 2, two R₃'s are substituted (e.g., two R₃'s are included as substituents). When o is 2, two R₃'s may all be the same as or different from each other. When p is 0, R₄ is not substituted (e.g., is not included as a substituent), when p is 1, one R₄ is substituted (e.g., one R₄ is included as a substituent), and when p is 2, two R₄'s are substituted (e.g., two R₄'s are included as substituents). When p is 2, two R₄'s may all be the same as or different from each other.

q and r may be each independently an integer of 0 to 3. For example, when q is 0, R₅ is not substituted (e.g., is not included as a substituent), when q is 1, one R₅ is substituted (e.g., one R₅ is included as a substituent), and when q is 2, two R₅'s are substituted (e.g., two R₅'s are included as substituents). When q is 2, two R₅'s may be the same as or different from each other.

When r is 0, R₅ is not substituted (e.g., is not included as a substituent), when r is 1, one R₅ is substituted (e.g., one R₅ is included as a substituent), and when r is 2, two R₅'s are substituted (e.g., two R₅'s are included as substituents). When r is 2, two RB's may be the same as or different from each other.

s may be an integer of 0 to 2. For example, when s is 0, R₇ is not substituted (e.g., is not included as a substituent), when s is 1, one R₇ is substituted (e.g., one R₇ is included as a substituent), and when s is 2, two R₇'s are substituted (e.g., two R₇'s are included as substituents). When s is 2, two R₇'s may be the same as or different from each other.

R₁ to R₇ may be each independently a hydrogen atom, a deuterium atom, a halogen atom, a cyano group, a nitro group, a hydroxy group, a substituted or unsubstituted alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted oxy group, a substituted or unsubstituted thio group, or a substituted or unsubstituted amine group, and/or may be bonded to an adjacent group to form a ring.

X₁ and X₂ may be each independently NRₐ, O, S, or Se, and Rₐ may be a substituted or unsubstituted aryl group having 6 to 12 ring-forming carbon atoms, or a substituted or unsubstituted heteroaryl group having 2 to 15 ring-forming carbon atoms, and/or may be bonded to an adjacent group to form a ring.

The polycyclic compound represented by Formula 1 has a broad planar skeleton having a heterocyclic substituent containing a boron atom, and is thus favorable for multiple resonance. Moreover, the polycyclic compound represented by Formula 1 may contain a substituent having a high steric hindrance at the ortho-position of each of the two phenyl groups of the carbazole group. The substituent having a high steric hindrance may induce high electric density in the core of the polycyclic compound of an embodiment, thereby further promoting the multiple resonance of the core. It is difficult for the polycyclic compound represented by Formula 1 to have the carbazole group and the core on the same plane due to the substituent having a high steric hindrance. Because the carbazole group and the core are not on the same plane, the resonance between the core and the carbazole group is reduced, and thus the multiple resonance inside the core may be further promoted. As a result, the polycyclic compound represented by Formula 1 has a high oscillator strength and low E_{ST} (e.g., a small difference between the lowest triplet excitation energy level (T1 level) and the lowest singlet excitation energy level (S1 level)), thereby improving luminous efficiency. In addition, the polycyclic compound represented by Formula 1 contains a substituent having a high steric hindrance at the ortho-position of each of the two phenyl groups of the carbazole group to deter (or disturb) the attack of a nucleophile at the boron atom, thereby improving molecular stability, resulting in the improvement of luminous efficiency.

The polycyclic compound represented by Formula 1 may be utilized as a thermally activated delayed fluorescence (TADF) material. For example, the polycyclic compound of an embodiment may be utilized as a TADF dopant material to emit blue light. The polycyclic compound represented by Formula 1 of an embodiment may be a luminescent material having a luminescence center wavelength (λmax) in a wavelength region of about 490 nm or less. For example, the polycyclic compound represented by Formula 1 of an embodiment may be a luminescent material having a luminescence center wavelength in a wavelength region of about 430 nm to about 490 nm. The polycyclic compound represented by Formula 1 of an embodiment may be a blue thermally activated delayed fluorescence dopant.

In Formula 1, X₁ and X₂ may be the same. That is, both X₁ and X₂ may each be NRₐ, S, O, or Se. The polycyclic compound represented by Formula 1 may be represented by any one selected among Formulae 2A to 2D below: Formula 2A is the case where X₁ and X₂ are NRa₁ and NRa₂, respectively, Formula 2B is the case where both X₁ and X₂ are O, Formula 2C is the case where both X₁ and X₂ are S, and Formula 2D is the case where both X₁ and X₂ are Se.

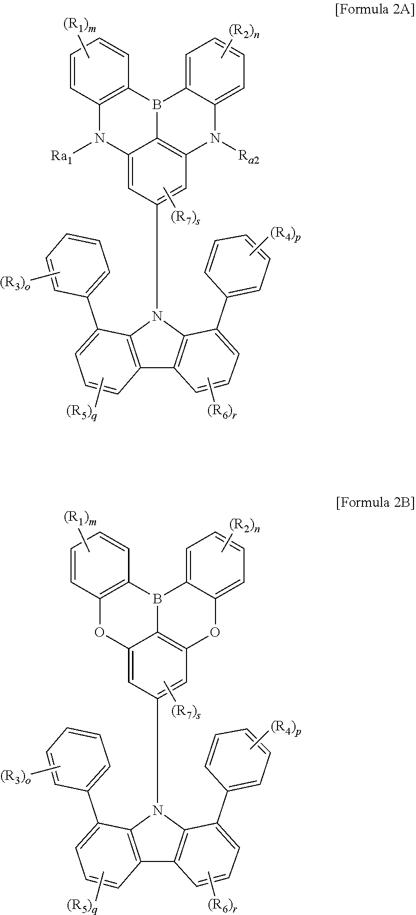

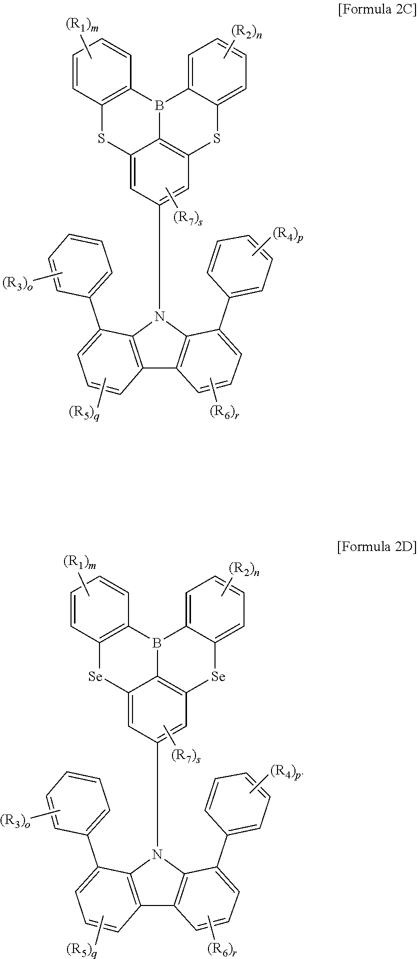

In Formula 2A, Rₐ₁ and Rₐ₂ may be each independently a substituted or unsubstituted phenyl group, a substituted or unsubstituted biphenyl group, a substituted or unsubstituted carbazole group, or a substituted or unsubstituted furan group, and/or may be banded to an adjacent group to form a ring. In Formulae 2A to 2D, the same described as those in Formula 1 may be applied to m to s and R₁ to R₇.

The polycyclic compound represented by Formula 2A may be represented by any one selected among Formula 2A-1 to Formula 2A-5 below. Formula 2A-1 is the case where neither Rₐ₁ nor Rₐ₂ are banded to an adjacent group to form a ring. Formulae 2A-2 to 2A-5 are the cases where at least one of Rₐ₁ or Rₐ₂ is banded to an adjacent group to form a ring. Formula 2A-2 and Formula 2A-4 are the cases where each of Rₐ₁ and Rₐ₂ is bonded to an adjacent group to form a ring, and Formula 2A-3 and Formula 2A-5 are the cases where one of Rₐ₁ or Rₐ₂ is banded to an adjacent group to form a ring. Formula 2A-2 is the case where Rₐ₁ is bonded to the benzene ring banded with R₁ to form a ring, and Rₐ₂ is banded to a benzene ring banded with R₂ to form a ring. Formula 2A-3 is the case where Rₐ₁ is bonded to the benzene ring banded with R₁ to form a form, or Rₐ₂ is bonded to a benzene ring banded with R₂ to form a ring. Formula 2A-4 is the case where each of Rₐ₁ and Rₐ₂ is bonded to the benzene ring banded with R₇ to form a ring. Formula 2A-5 is the case where one of Rₐ₁ or Rₐ₂ is bonded to the benzene ring banded with R₇ to form a ring.

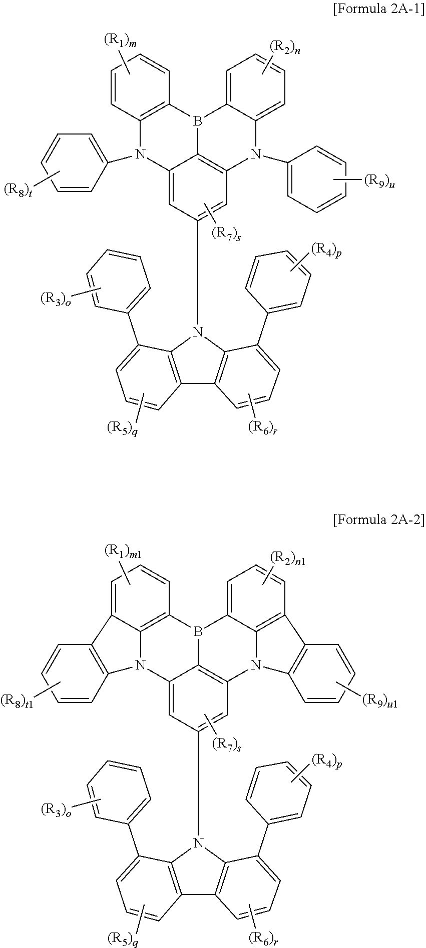

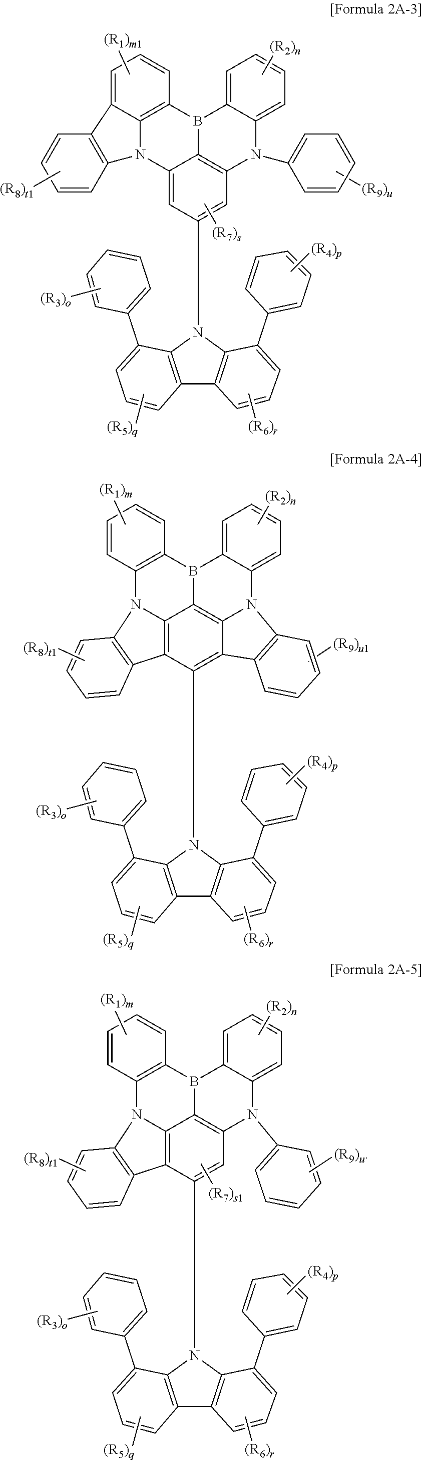

In Formulae 2A-1 to 2A-5, m1 and n1 may be each independently an integer of 0 to 3. For example, when m1 is 0, R₁ may not be substituted at the benzene ring (e.g., the benzene ring may not be substituted by R₁), when m1 is 1, one R₁ may be substituted at the benzene ring (e.g., the benzene ring may be substituted with one R₁), and when m1 is 2, two R₁'s may be substituted at the benzene ring (e.g., the benzene ring may be substituted with two R₁'s). When m1 is 2, two R₁'s may be the same as or different from each other. When n1 is 0, R₂ may not be substituted at the benzene ring (e.g., the benzene ring may not be substituted by R₂), when n1 is 1, one R₂ may be substituted at the benzene ring (e.g., the benzene ring may be substituted with one R₂), and when n1 is 2, two R's may be substituted at the benzene ring (e.g., the benzene ring may be substituted with two R₂'s). When n1 is 2, two R₂'s may be the same as or different from each other.

t and u may be each independently an integer of 0 to 5. For example, when t is 0, R₈ may not be substituted at the benzene ring (e.g., the benzene ring may not be substituted by R₈), when t is 1, one R₈ may be substituted at the benzene ring (e.g., the benzene ring may be substituted with one R₈), and when t is 2, two R₈'s may be substituted at the benzene ring (e.g., the benzene ring may be substituted with two R₈'s). When t is 2 or greater, a plurality of R₈'s may all be the same or at least one may be different from the rest. When u is 0, R₉ may not be substituted at the benzene ring (e.g., the benzene ring may not be substituted by R₉), when u is 1, one R₉ may be substituted at the benzene ring (e.g., the benzene ring may be substituted with one R₉), and when u is 2, two R₉'s may be substituted at the benzene ring (e.g., the benzene ring may be substituted with two R₉'s). When u is 2 or greater, a plurality of R₉'s may all be the same or at least one may be different from the rest.

t1 and u1 may be each independently an integer of 0 to 4, and s1 may be 0 or 1. R₈ and R₉ may be each independently a substituted or unsubstituted methyl group, a substituted or unsubstituted t-butyl group, a substituted or unsubstituted phenyl group, a substituted or unsubstituted oxy group, a substituted or unsubstituted thio (e.g., thiol) group, or a substituted or unsubstituted amine group, or may be banded to an adjacent group to form a ring. In Formula 2A-1 to Formula 2A-5, the same as those described in Formula 1 above may be applied to R₁ to R₇ and m to s. In Formulae 2A-1 to 2A-5, R₈ and R₉ may be each independently represented by any one selected among moieties (e.g., groups) below:

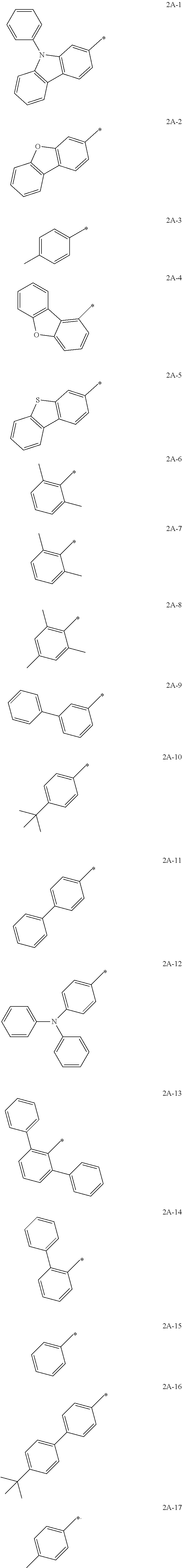

In Formulae 2A-1 to 2A-17, “ [symbol] ” corresponds to a part in which moieties represented by Formulae 2A-1 to 2A-17 are bonded to the Rₐ group that is bonded to the nitrogen atom of NRₐ.

In Formula 1, X₁ and X₂ may be different from each other. The polycyclic compound represented by Formula 1 may be represented by Formula 3A below:

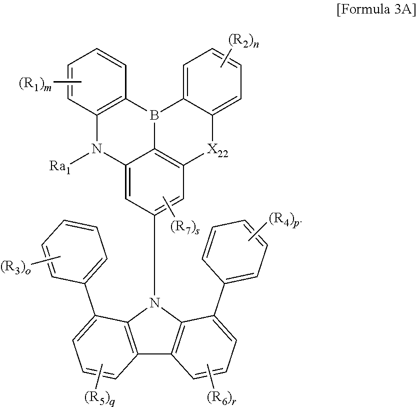

In Formula 3A, X₂₂ may be O, S, or Se, and Rₐ₁ may be a substituted or unsubstituted phenyl group, a substituted or unsubstituted biphenyl group, a substituted or unsubstituted carbazole group, or a substituted or unsubstituted furan group, and/or may be bonded to an adjacent group to form a ring. In Formula 3A, R₁ to R₇, and m to s are the same as respectively defined in connection with Formula 1 above.

The polycyclic compound represented by Formula 3A may be represented by any one selected among Formula 3A-1 to Formula 3A-3 below. Formula 3A-1 is the case where Rₐ₁ is not bonded to an adjacent group to form a ring. Formula 3A-2 is the case where Rₐ₁ is bonded to the benzene ring bonded with R₁ to form a ring. Formula 3A-3 is the case where Rₐ₁ is bonded to the benzene ring bonded with R₇ to form a ring.

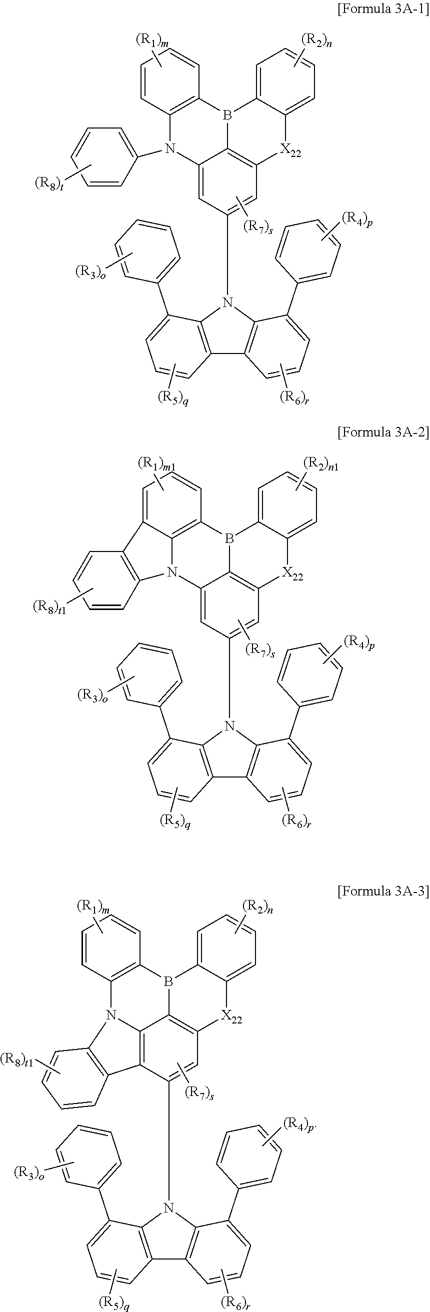

In Formula 3A-1 to 3A-3, t may be an integer of 0 to 5. For example, when t is 0, R₈ may not be substituted at the benzene ring (e.g., the benzene ring may not be substituted by R₈), when t is 1, one R₈ may be substituted at the benzene ring (e.g., the benzene ring may be substituted by one R₈), and when t is 2, two R₈'s may be substituted at the benzene ring (e.g., the benzene ring may be substituted by two R₈'s). When t is 2 or greater, a plurality of R₈'s may all be the same, or at least one may be different from the rest. s1 may be 0 or 1. For example, when s1 is 0, R₇ may not be substituted at the benzene ring (e.g., the benzene ring may not be substituted by R₇), and when s1 is 1, one R₇ may be substituted at the benzene ring (e.g., the benzene ring may be substituted by one R₇).

m1 may be an integer of 0 to 3. For example, when m1 is 0, R₁ may not be substituted at the benzene ring (e.g., the benzene ring may not be substituted by R₁), when m1 is 1, one R₁ may be substituted at the benzene ring (e.g., the benzene ring may be substituted by one R₁), and when m1 is 2, two R₁'s may be substituted at the benzene ring (e.g., the benzene ring may be substituted by two R₁'s). When m1 is 2 or greater, a plurality of R₁'s may all be the same or at least one may be different from the rest.

t1 may be an integer of 0 to 4. For example, when t1 is 0, R₈ may not be substituted at the benzene ring (e.g., the benzene ring may not be substituted by R₈), when t1 is 1, one R₈ may be substituted at the benzene ring (e.g., the benzene ring may be substituted by one R₈), and when t1 is 2, two R₈'s may be substituted at the benzene ring (e.g., the benzene ring may be substituted by two R₈'s). When t1 is 2 or greater, a plurality of R₈'s may all be the same, or at least one may be different from the rest.

R₈ may be a substituted or unsubstituted methyl group, a substituted or unsubstituted t-butyl group, a substituted or unsubstituted phenyl group, a substituted or unsubstituted oxy group, a substituted or unsubstituted thio group, or a substituted or unsubstituted amine group, and/or may be bonded to an adjacent group to form a ring. In Formula 3A-1 to Formula 3A-3, X₂₂ may be the same as defined in Formula 3A, and R₁ to R₇, and m to s may be the same as respectively defined in connection with Formula 1 above.

In Formula 3A-1 to 3A-3, R₈ may be represented by any one selected among compounds below:

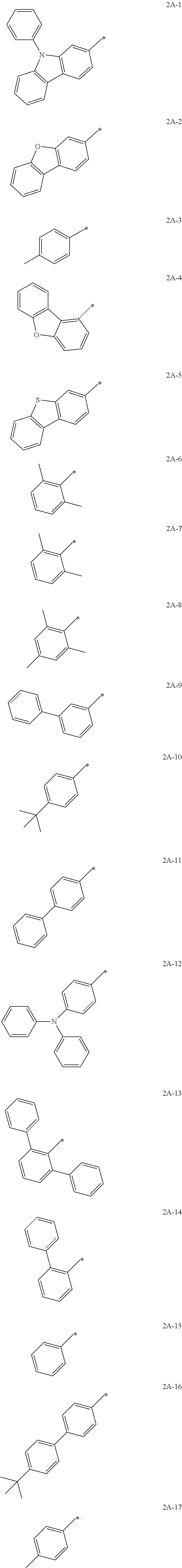

In Formulae 2A-1 to 2A-17, “ [symbol] ” corresponds to apart in which moieties represented by Formulae 2A-1 to 2A-17 are banded to the Rₐ banded to the nitrogen atom of NRₐ.

The polycyclic compound represented by Formula 1 may be represented by Formula 4-1 or Formula 4-2 below. Formula 4-1 and Formula 4-2 are the cases where each of m and n is 1. Formula 4-1 is the case where in Formula 1, R₁ is at the para-position with X₁ and R₂ is at the para-position with X₂, and Formula 4-2 is the case where in Formula 1, R₁ is at the meta-position with X₁ and R₂ is at the meta-position with X₂.

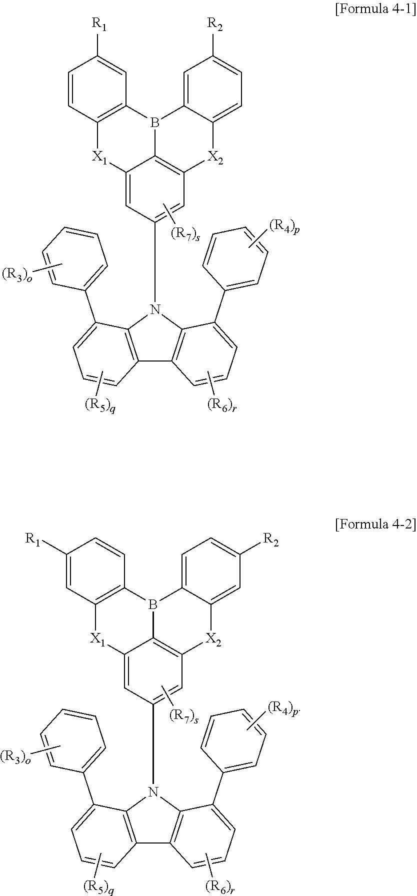

In Formulae 4-1 and 4-2, R₁ and R₂ may be each independently a substituted or unsubstituted t-butyl group, a substituted or unsubstituted phenyl group, a substituted or unsubstituted thio group, a substituted or unsubstituted amine group, or a substituted or unsubstituted oxy group, and/or may be bonded to an adjacent group to form a ring. In Formula 4-1 and Formula 4-2, o to s, X₁, X₂, and R₃ to R₇ may be the same as respectively defined in connection with Formula 1 above.

The polycyclic compound represented by Formula 4-1 may be represented by any one selected among Formula 4A to Formula 4C below. Formula 4A is the case where in Formula 4-1, R₁ is bonded to an adjacent group to form a ring and R₂ is also bonded to an adjacent group to form a ring. Formula 4B is the case where in Formula 4-1, R₁ is bonded to an adjacent group to form a ring and R₂ is not bonded to an adjacent group to form a ring. Formula 4C is the case where in Formula 4-1, R₁ is not bonded to an adjacent group to form a ring and R₂ is not bonded to an adjacent group to form a ring, either.

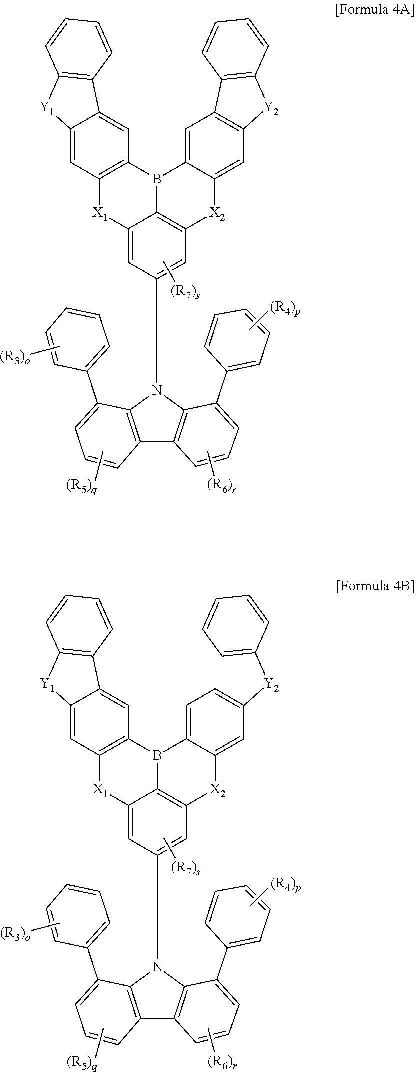

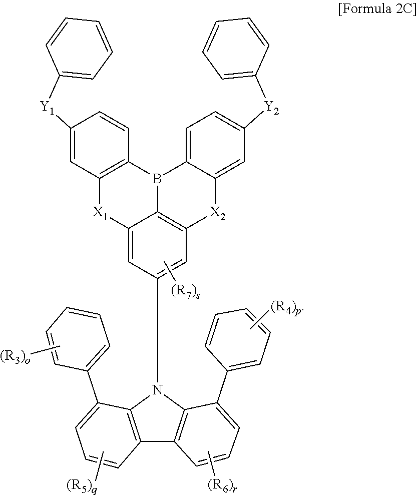

In Formulae 4 Å to 4C, Y₁ and Y₂ may be each independently O, S, or NRₑ, and Rₑ may be a substituted or unsubstituted phenyl group. X₁, X₂, R₃ to R₇, and o to s may be the same as respectively defined in connection with Formula 1 above.

The polycyclic compound represented by Formula 1 may be represented by Formula 5 below: Formula 5 is the case where in Formula 1, each of q and r is 1, and each of R₅ and R₆ is at the para-position with the nitrogen atom.

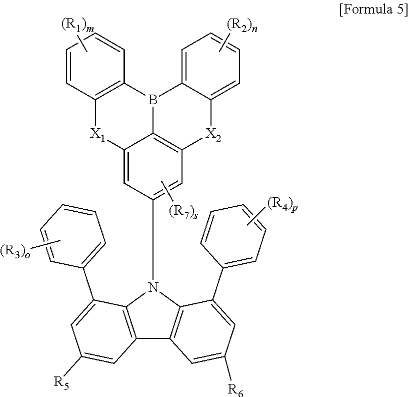

In Formula 5, R₅ and R₆ may be each independently an unsubstituted methyl group, an unsubstituted t-butyl group, or a cyano group. In Formula 5, m to p, s, X₁, X₂, R₁ to R₄, and R₇ may be the same as respectively defined in connection with Formula 1 above.

The polycyclic compound represented by Formula 1 may be represented by Formula 6-1 or Formula 6-2 below. Formula 6-1 and Formula 6-2 are the cases where each of o and p is 1. Formula 6-1 is the case where each of R₃ and R₄ is at the para-position with the carbazole group, and Formula 6-2 is the case where each of R₃ and R₄ is at the meta-position with the carbazole group.

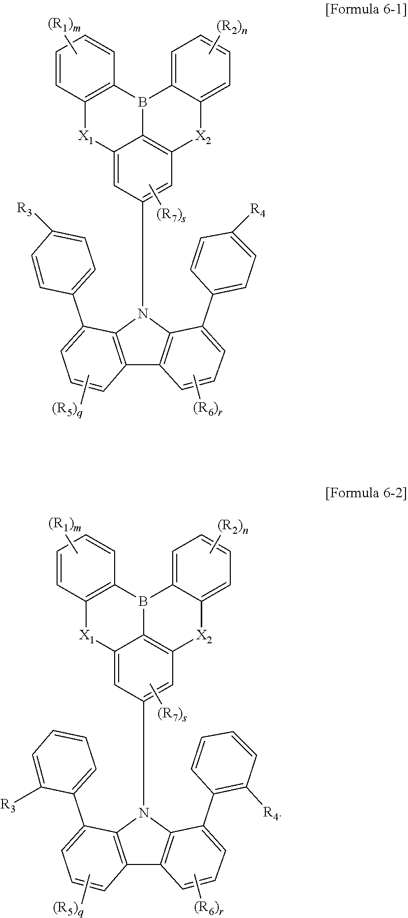

In Formulae 6-1 and 6-2, R₃ and R₄ may be each independently a substituted or unsubstituted t-butyl group, a fluorine group, or a substituted or unsubstituted oxy group, or the substituted or unsubstituted oxy group may be bonded to an adjacent group to form a ring. In Formula 6-1 and Formula 6-2, m, n, q to s, X₁, X₂, R₁, R₂, and R₅ to R₇ may be the same as respectively defined in connection with Formula 1.

The polycyclic compound represented by Formula 1 may be represented by any one selected among Formula 7-1 to Formula 7-5 below. Formula 7-1 to Formula 7-5 are the cases where X₁ is NRₐ1 and X₂ is NR_{b}, O, S, or Se, or X₁ is O and X₂ is S.

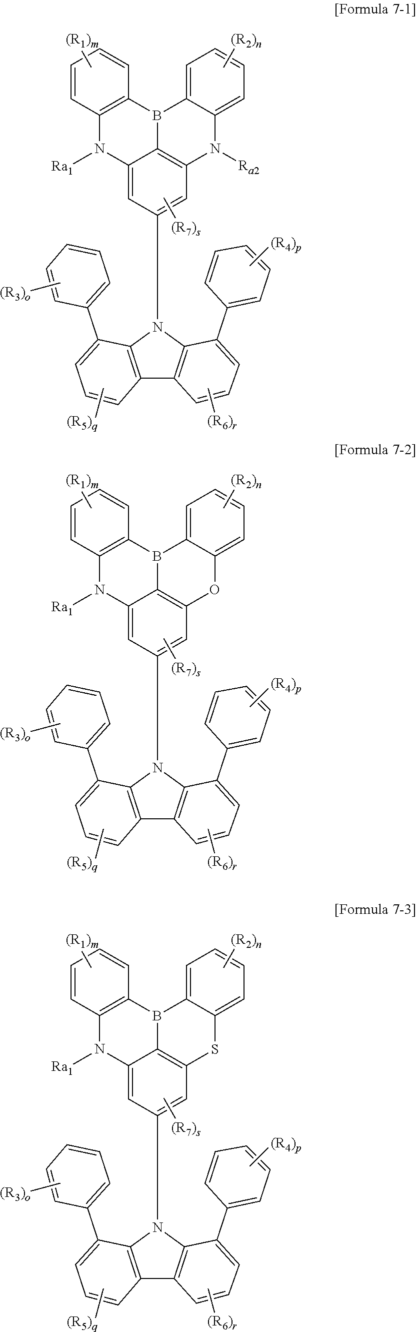

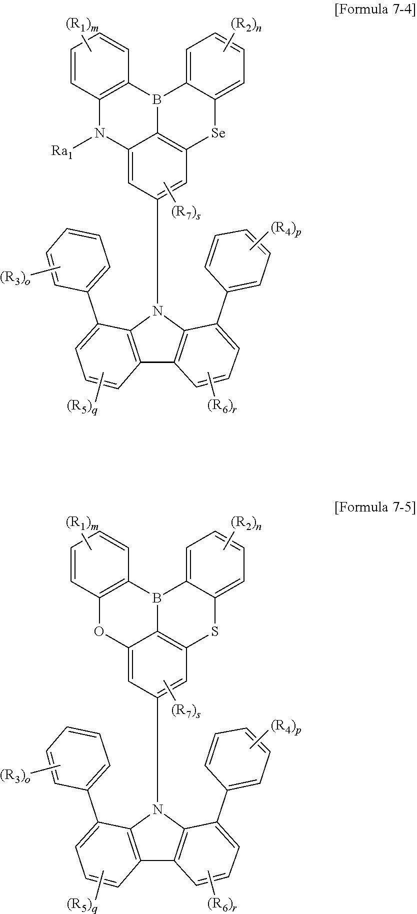

In Formula 7-1 to Formula 7-5, Rₐ₁ and Rₐ₂ may be each independently a hydrogen atom, a deuterium atom, a halogen atom, a cyano group, a nitro group, a hydroxy group, an alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted alkoxy group, a substituted or unsubstituted thio group, or a substituted or unsubstituted amine group, and/or may be bonded to an adjacent group to form a ring. In Formula 7-1 and Formula 7-5, m to s and R₁ to R₇ may be the same as respectively defined in connection with Formula 1 above.

The polycyclic compound represented by Formula 1 may be represented by any one selected among the polycyclic compounds of Compound Group 1 below. The emission layer EML may include at least one selected among the polycyclic compounds of Compound Group 1 below.

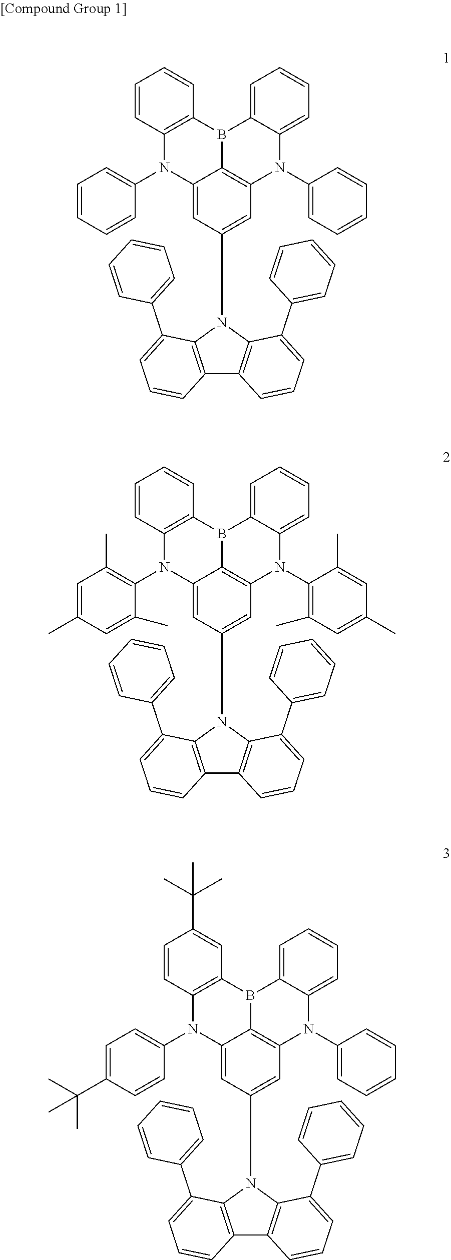

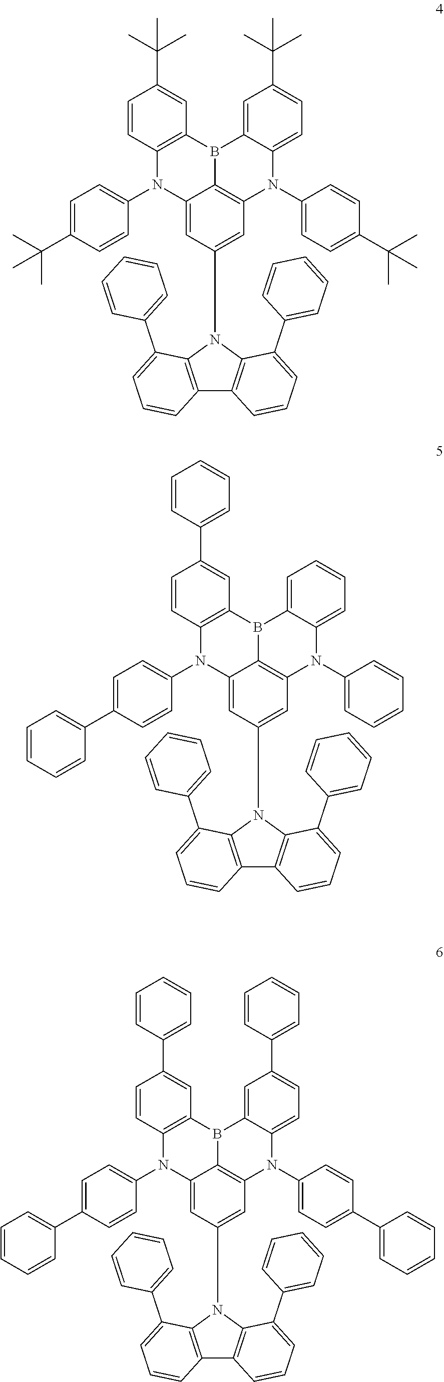

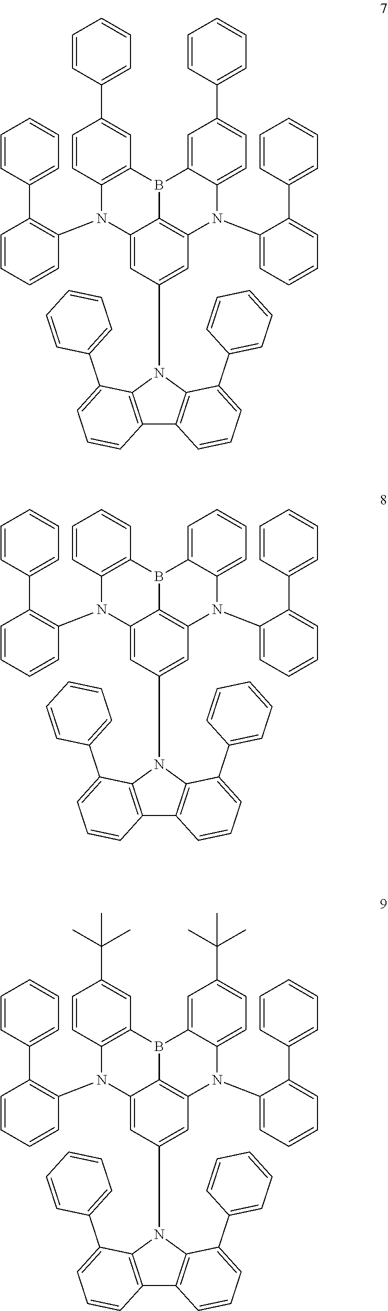

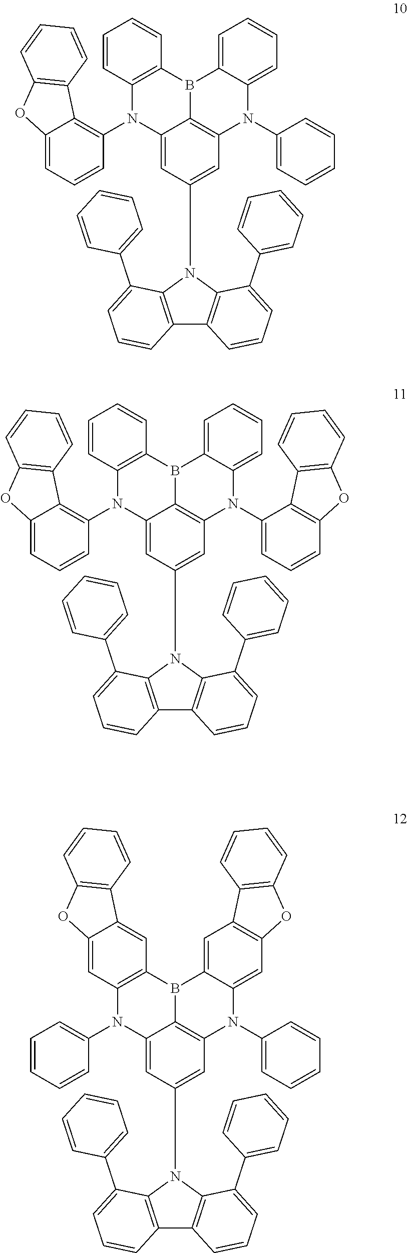

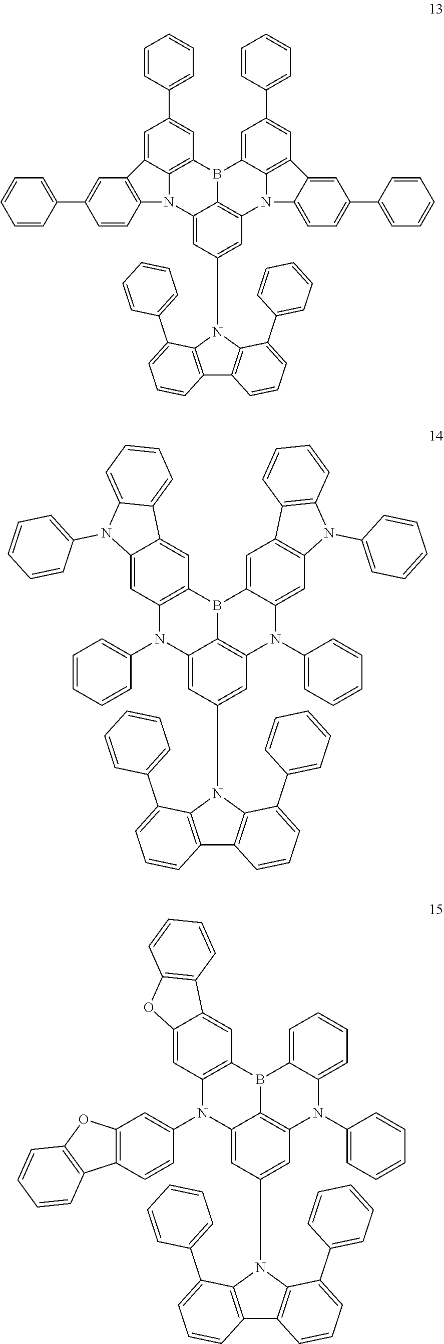

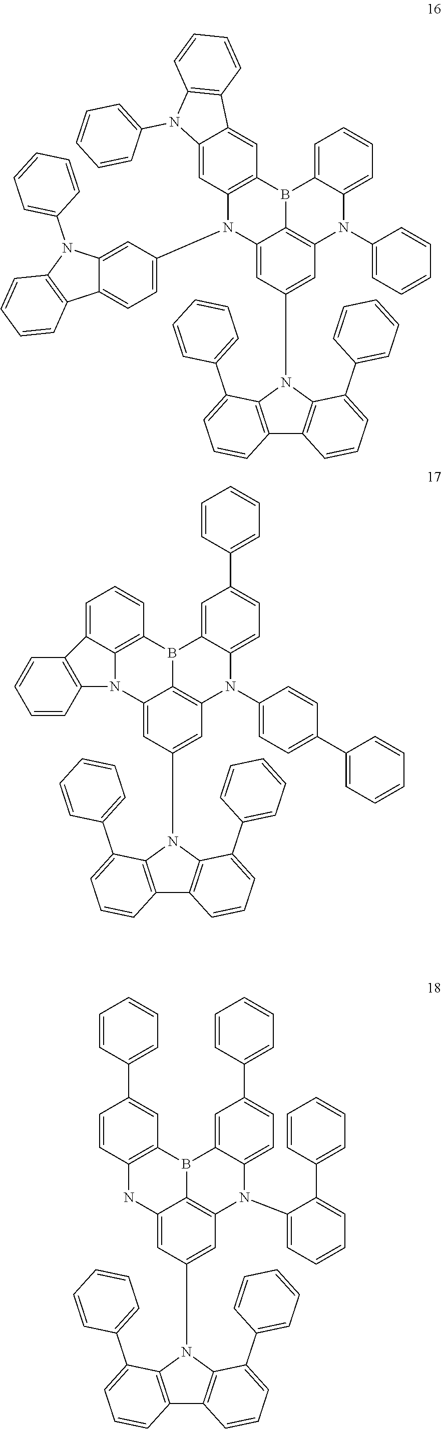

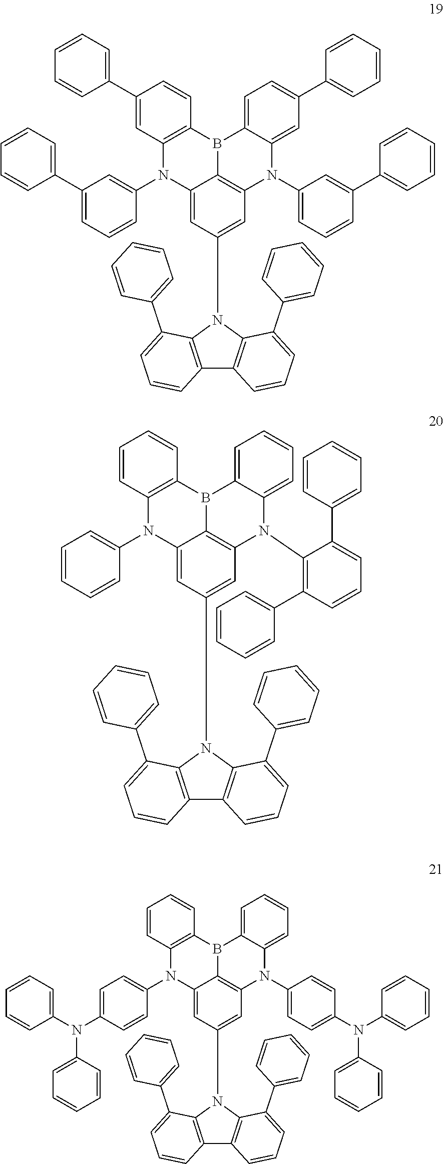

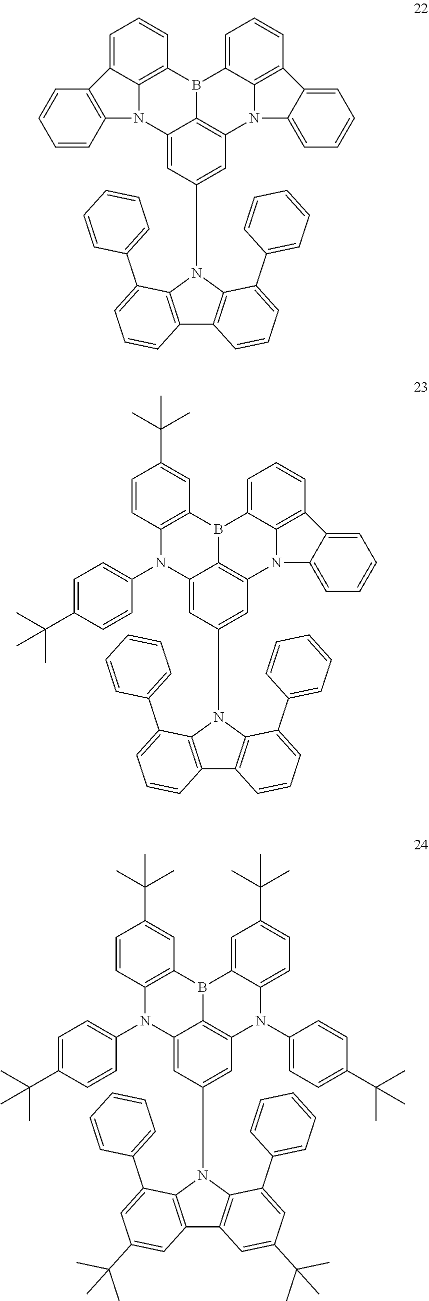

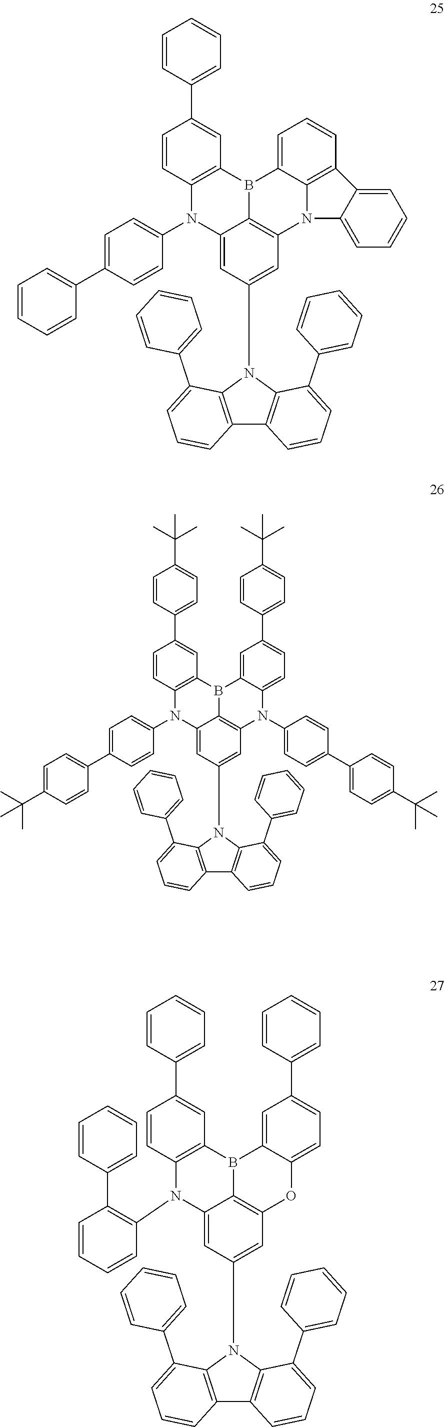

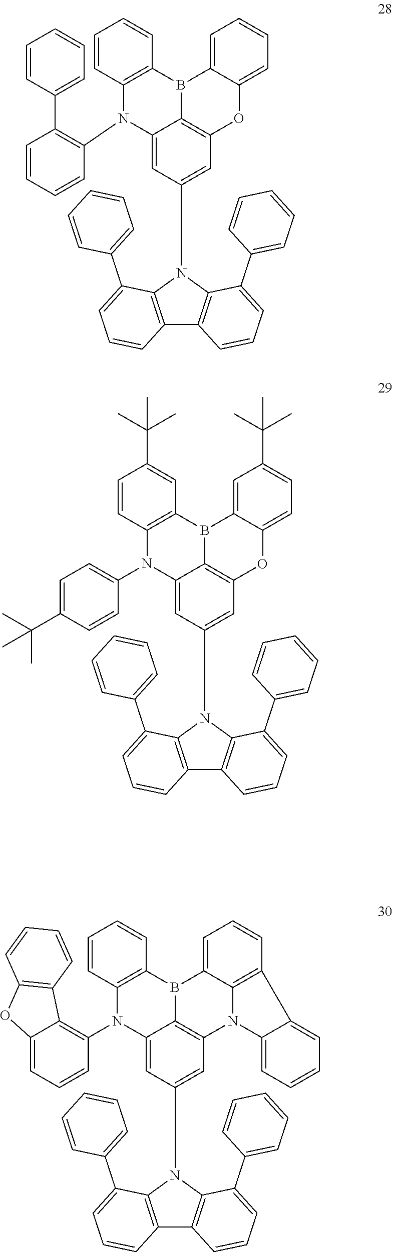

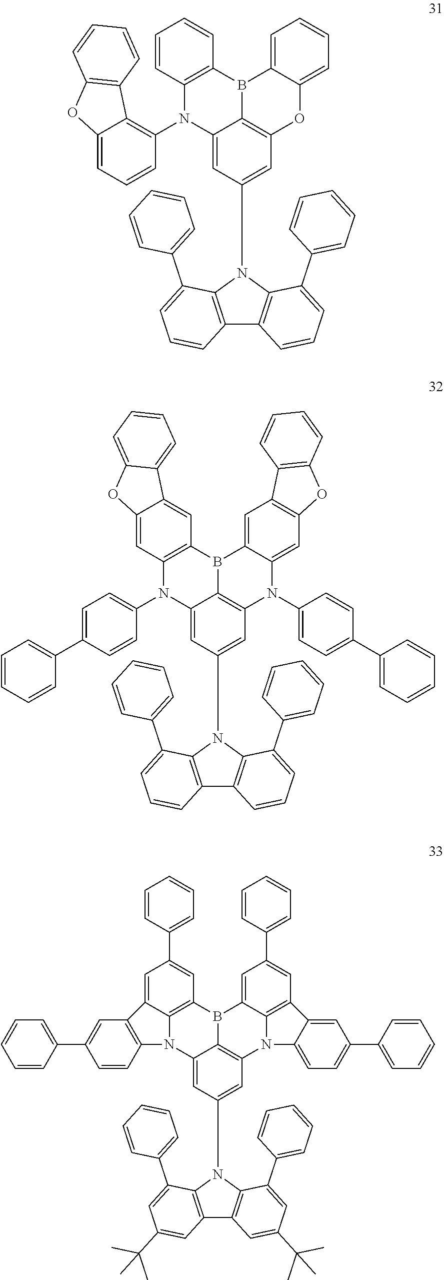

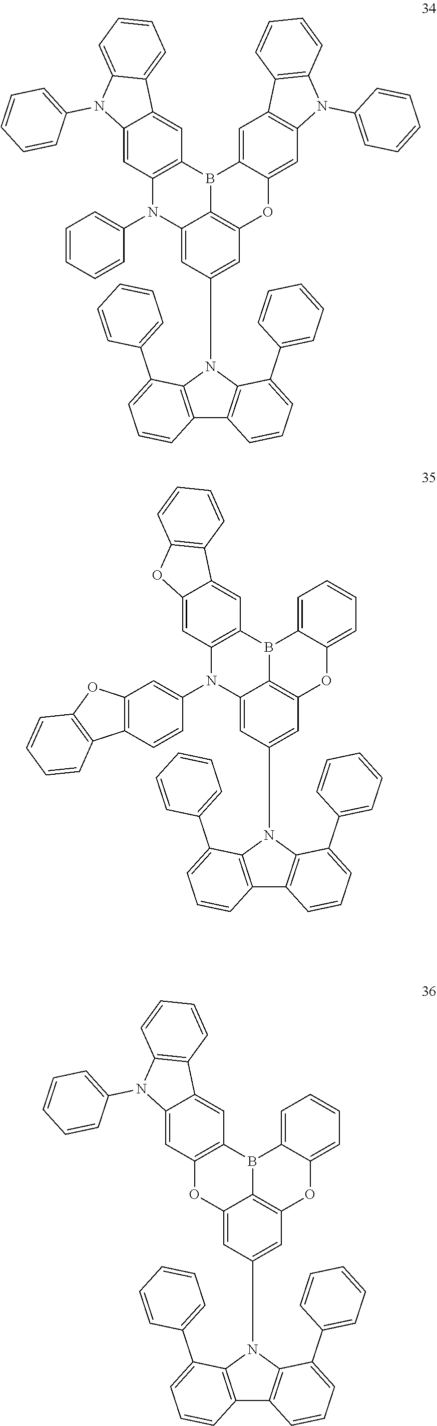

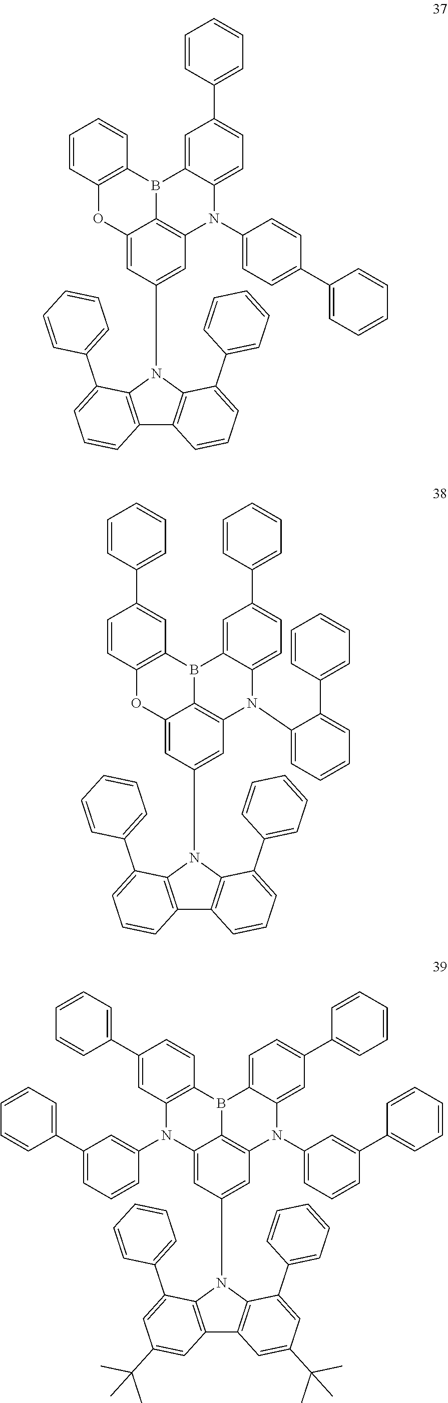

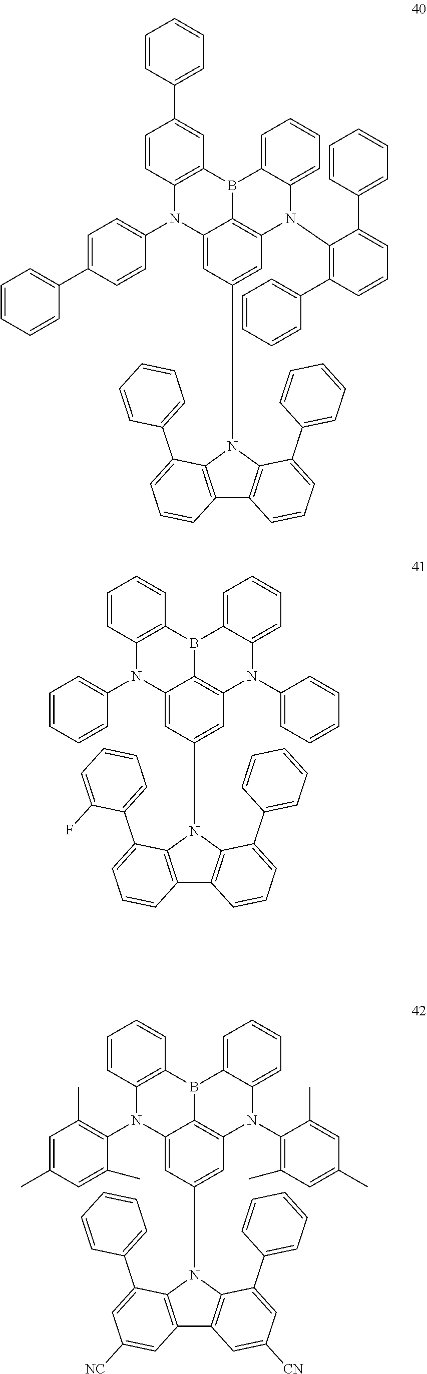

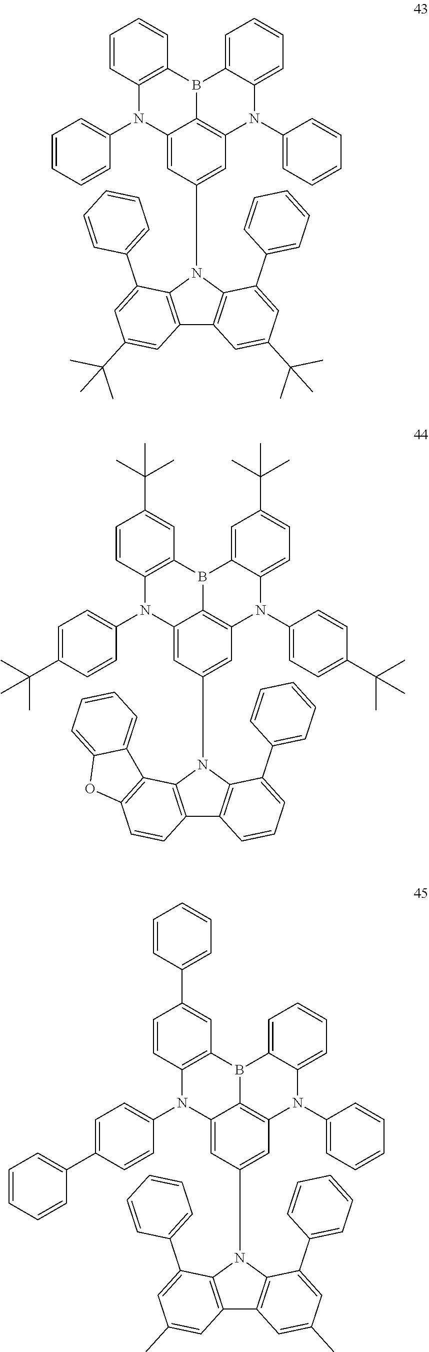

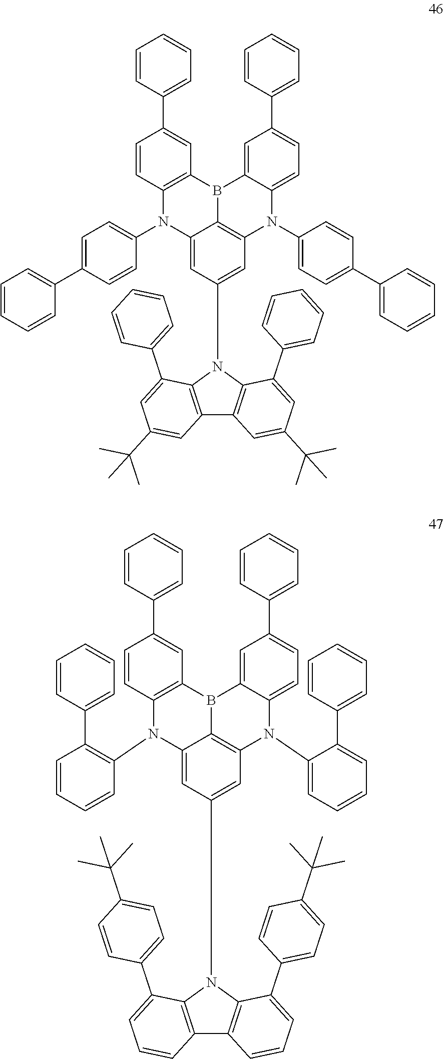

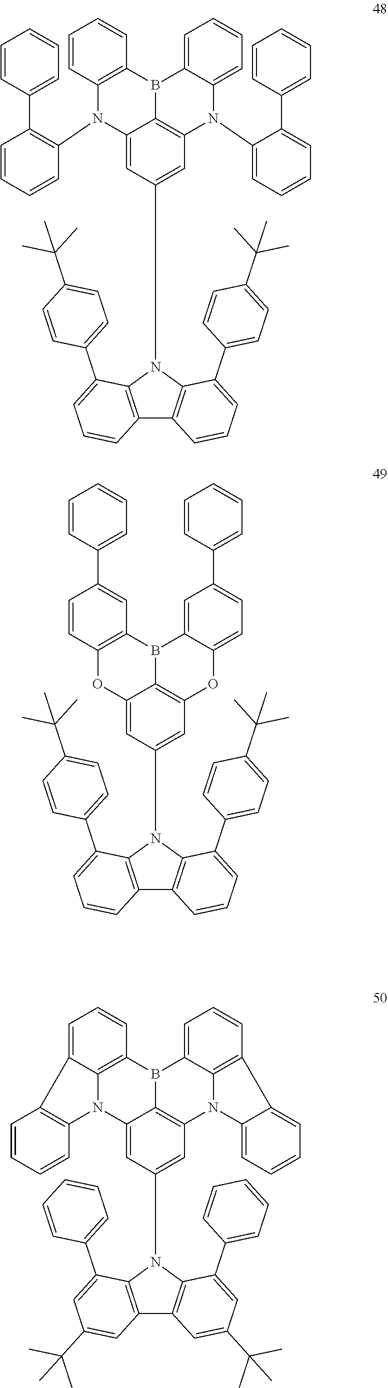

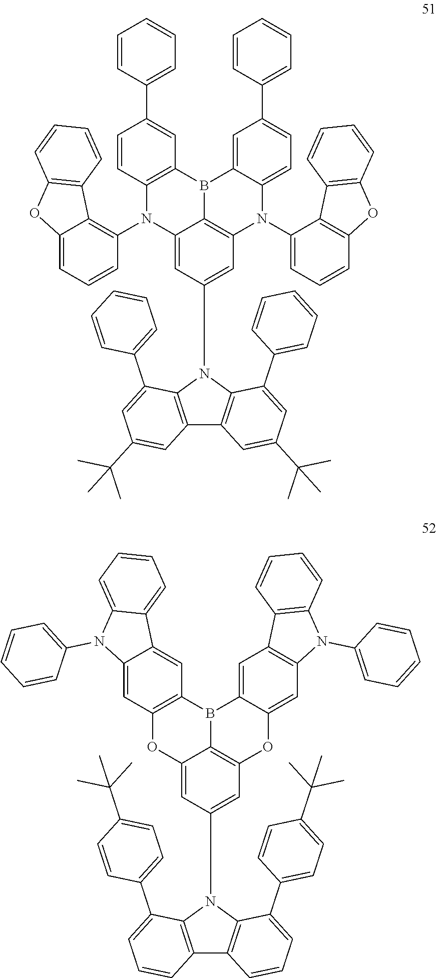

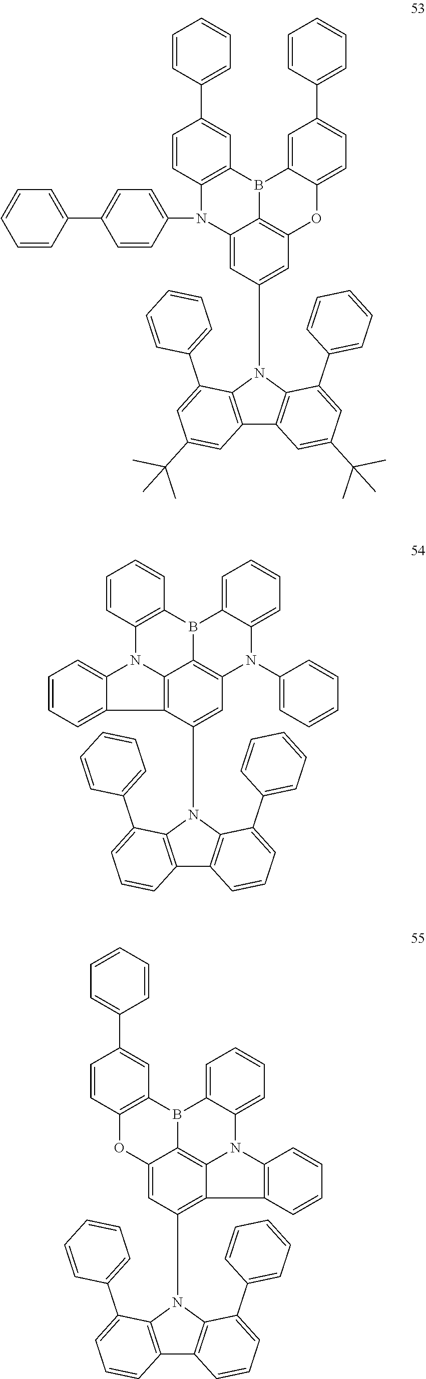

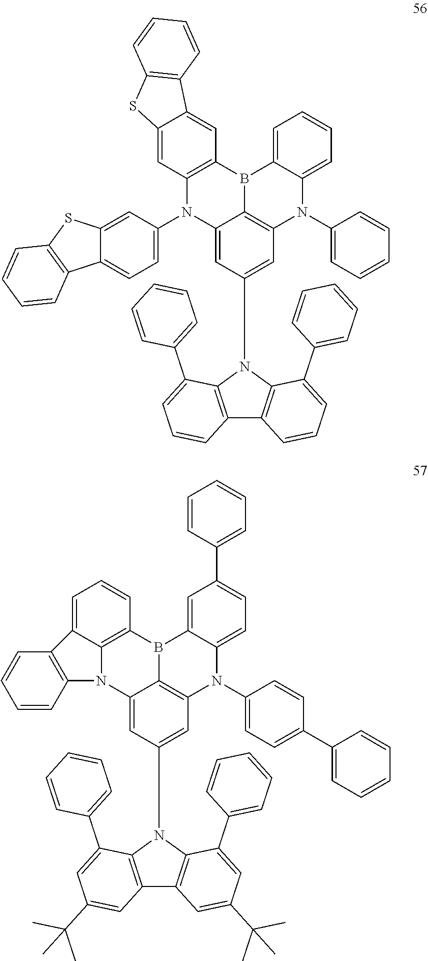

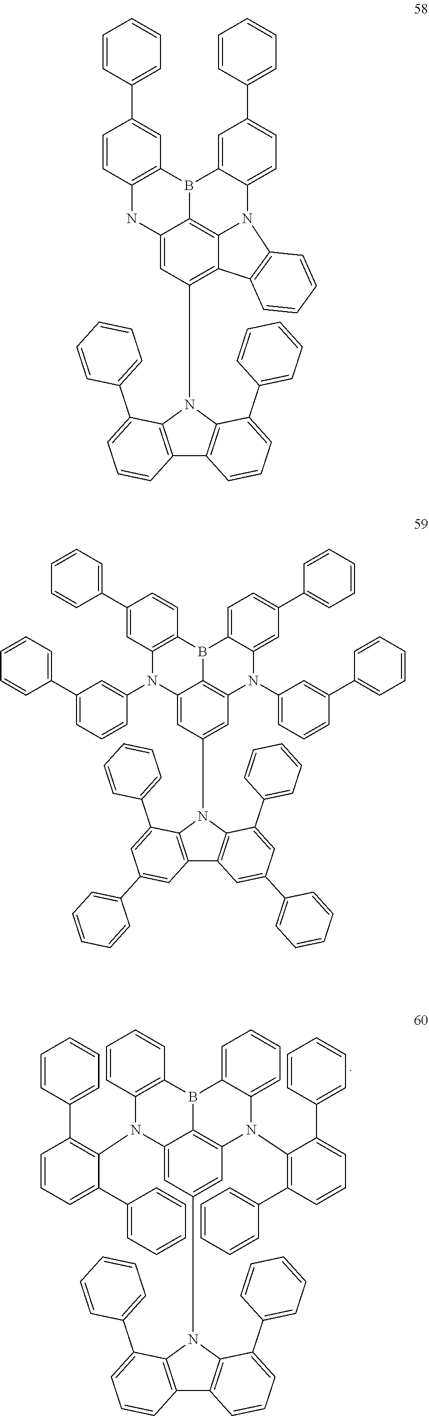

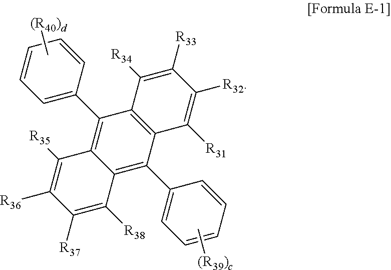

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may be each independently an integer of 0 to 5.

Formula E-1 may be represented by any one selected among Compound E1 to Compound E19 below:

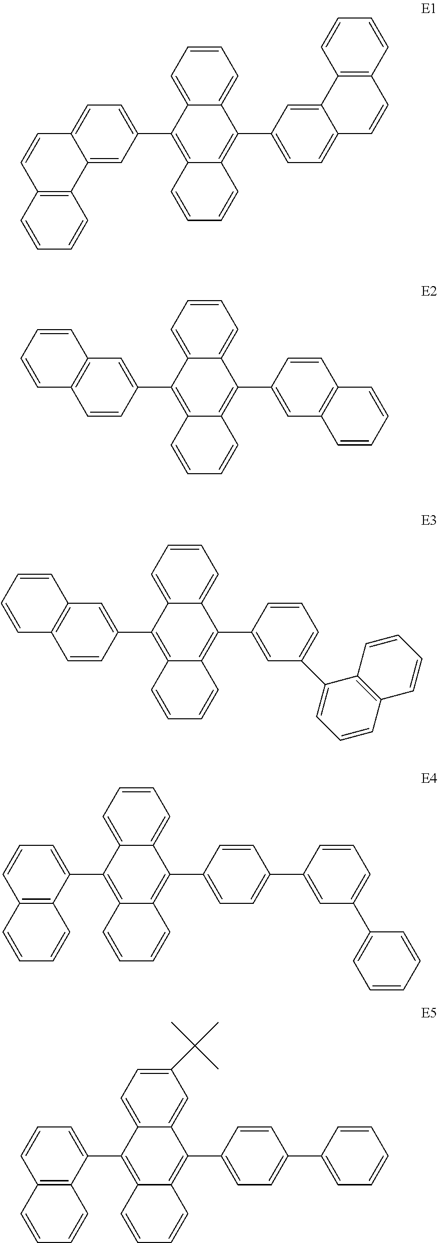

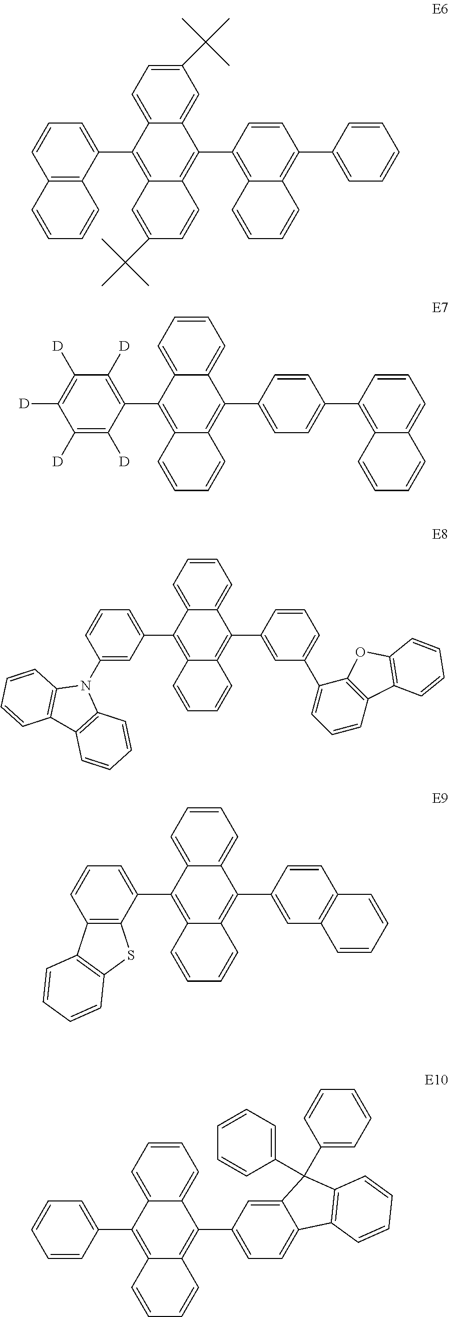

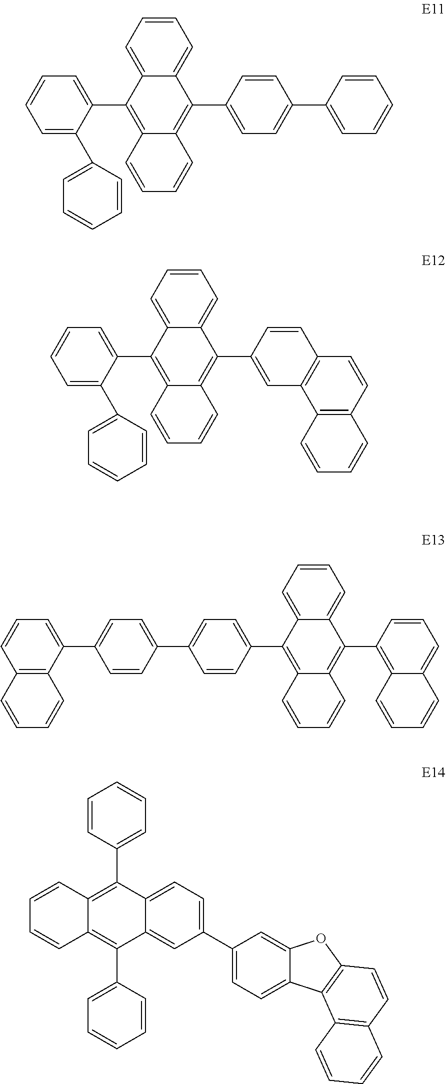

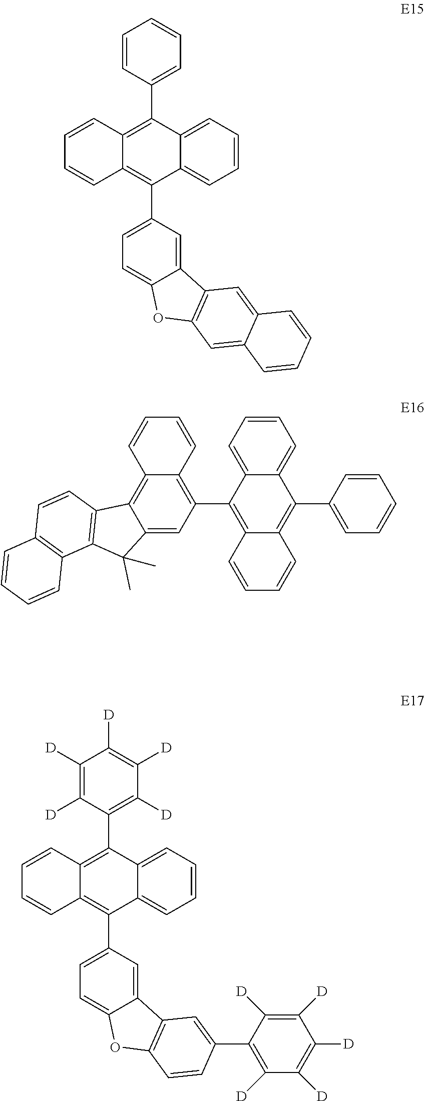

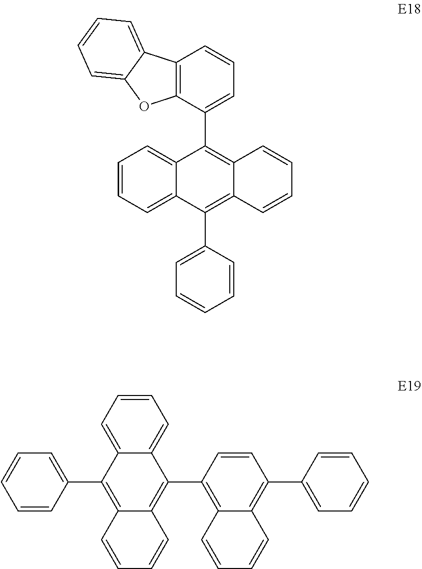

In an embodiment, the emission layer EML may further include a compound represented by Formula E-2a or Formula E-2b below. The compound represented by Formula E-2a or Formula E-2b below may be utilized as a phosphorescence host material.

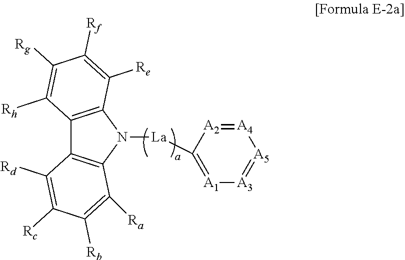

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, when a is an integer of 2 or more, a plurality of Lₐ's may be each independently a substituted or unsubstituted arylene group having 6 to 30 ring-forming carbon atoms, or a substituted or unsubstituted heteroarylene group having 2 to 30 ring-forming carbon atoms.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc. as a ring-forming atom.

In one or more embodiments, in Formula E-2a, two or three selected from among A₁ to A₅ may be N, and the remainder (e.g., the rest) may be CRᵢ.

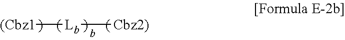

In Formula E-2b, Cbz1 and Cbz2 may be each independently an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. b may be an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected among the compounds of Compound Group E-2 below. However, the compounds listed in Compound Group E-2 below are presented as examples, and the compound represented by Formula E-2a or Formula E-2b is not limited to those represented by Compound Group E-2 below.

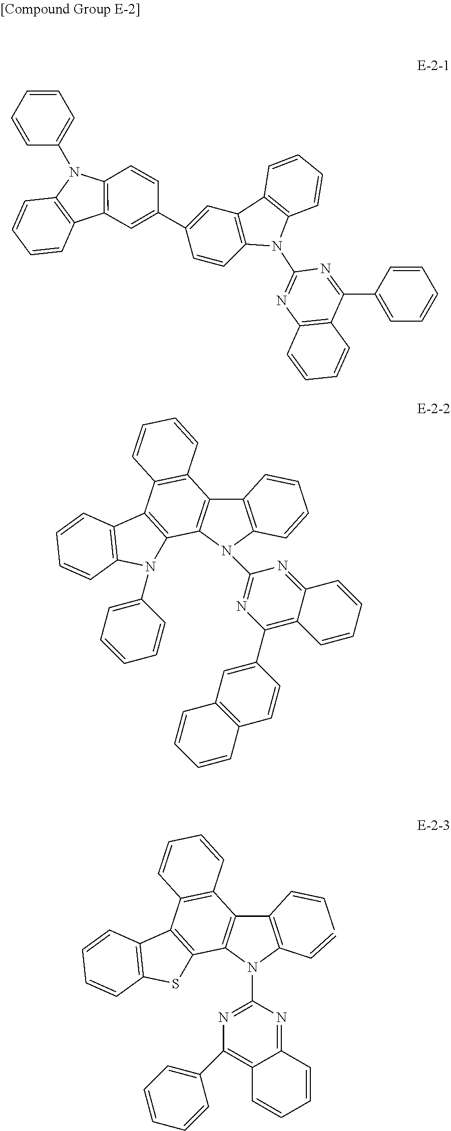 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; C=Cc1c(/C=C\C)c2c3ccccc3c3c4ccccc4sc3c2n1-c1nc(-c2ccccc2)c2ccccc2n1]

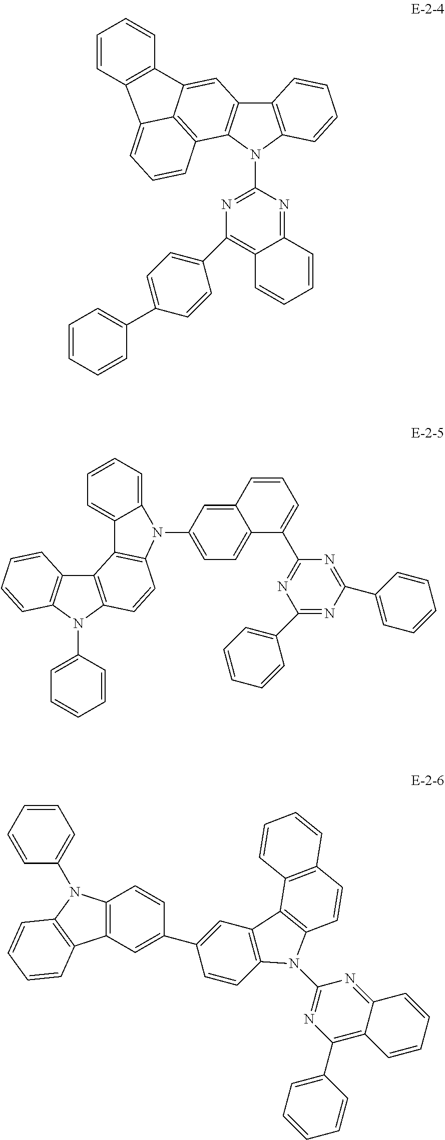 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

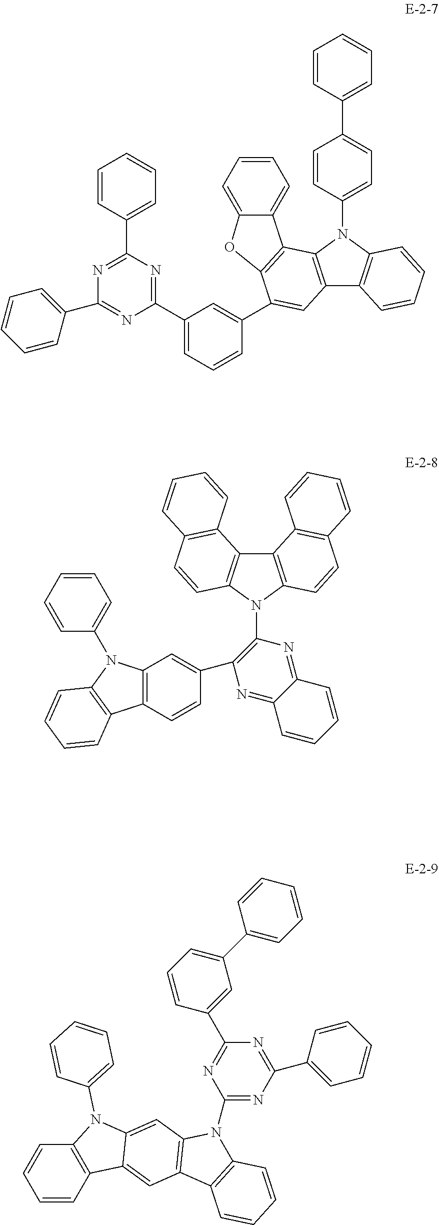 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

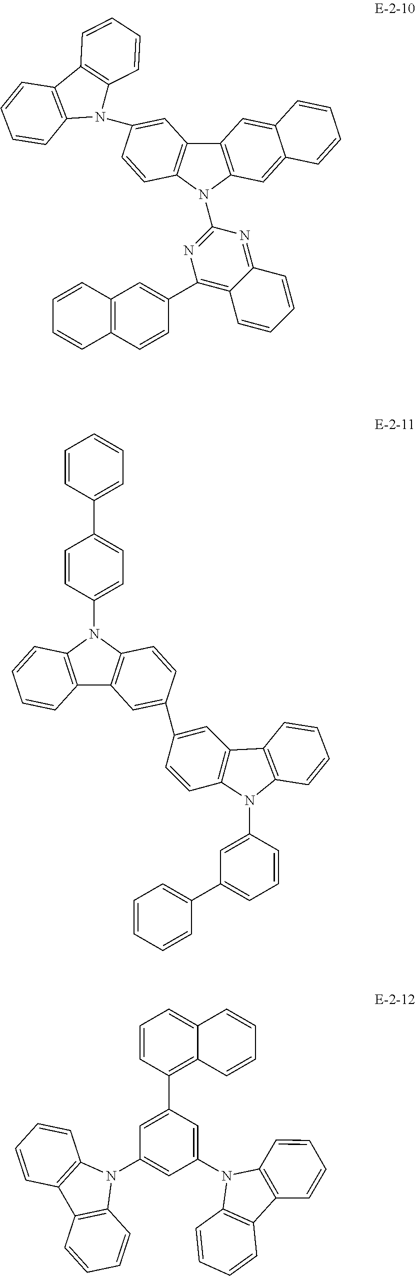 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

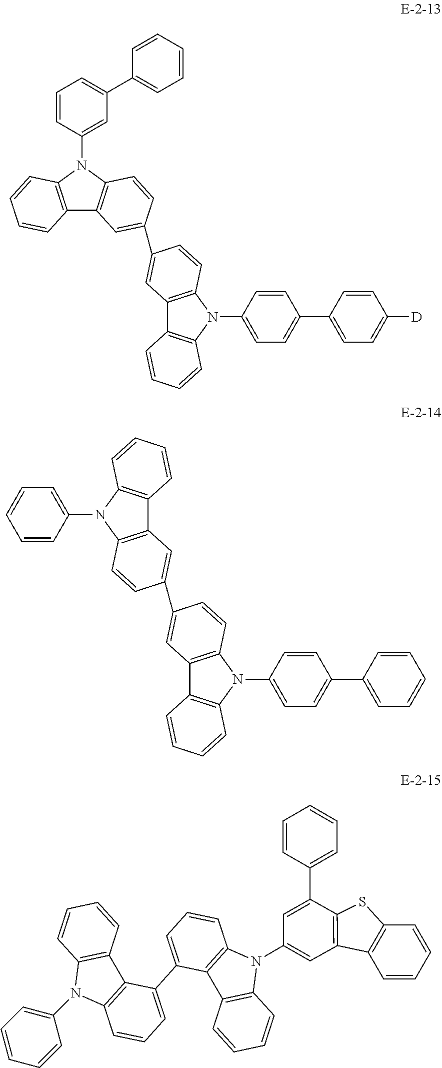 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

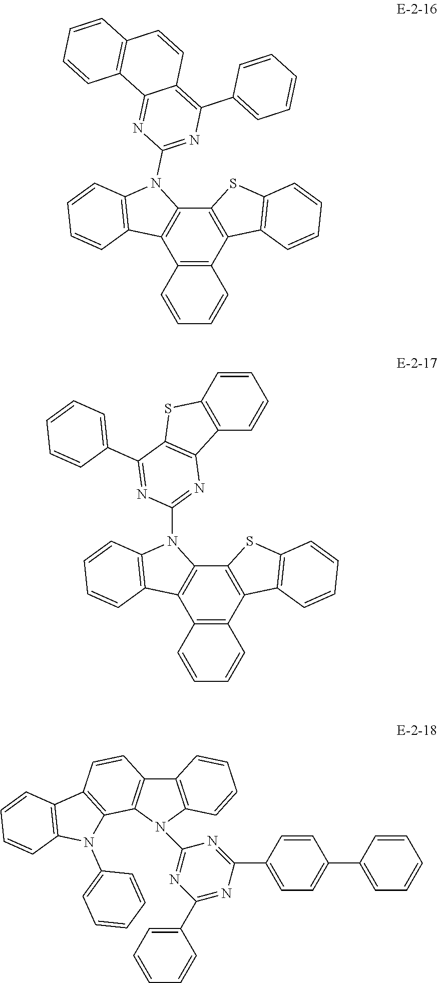 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

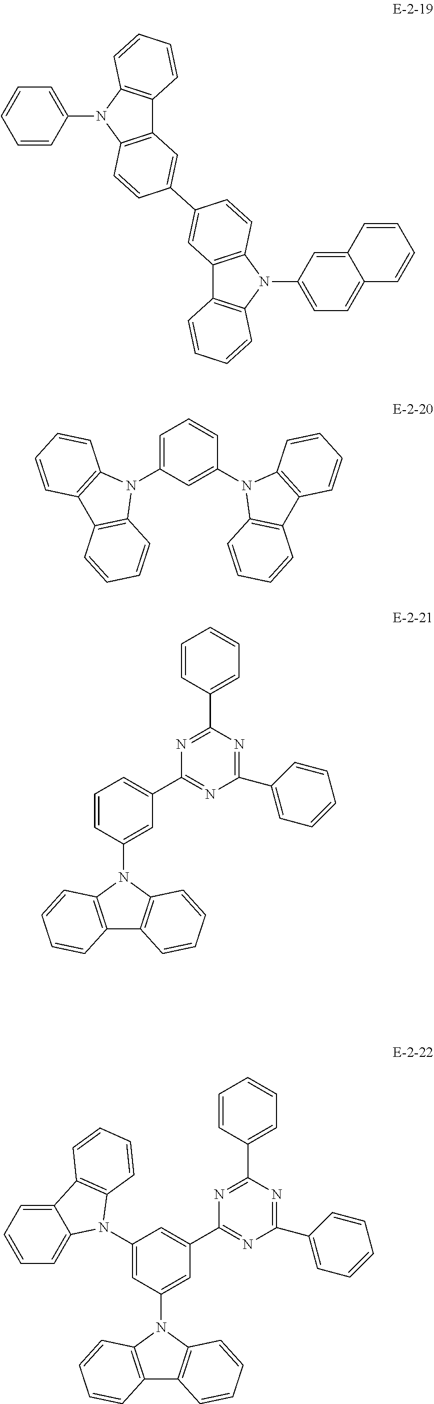 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

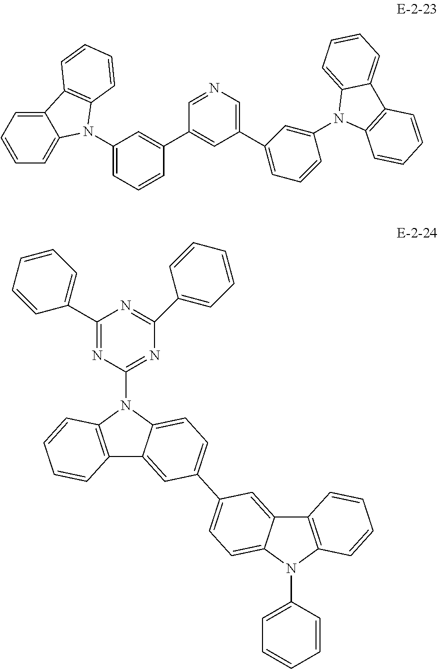 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material generally utilized in the art as a host material. For example, the emission layer EML may include, as a host material, at least one selected from among bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tis(carbazol-9-yl)-triphenylamine (TCTA), or 1,3,5-tris(1-phenyl-1H-benzo[d]imidazole-2-yl)benzene (TPBi). However, the present disclosure is not limited thereto, and for example, tis(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

In an embodiment, the emission layer EML may further include a compound represented by Formula M-a or Formula M-b below. The compound represented by Formula M-a or Formula M-b below may be utilized as a phosphorescence dopant material.

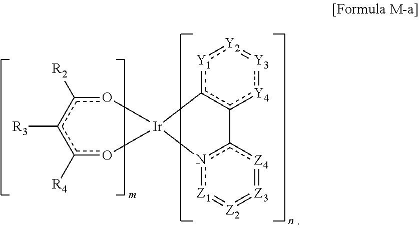

In Formula M-a above, Y₁ to Y₄ and Z₁ to Z₄ may be each independently CR₁ or N, and R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2. The compound represented by Formula M-a may be utilized as a phosphorescence dopant.

The compound represented by Formula M-a may be represented by any one selected among Compound M-a1 to Compound M-a25 below. However, Compounds M-a1 to M-a25 below are presented as examples, and the compound represented by Formula M-a is not limited to those represented by Compounds M-a1 to M-a25 below.

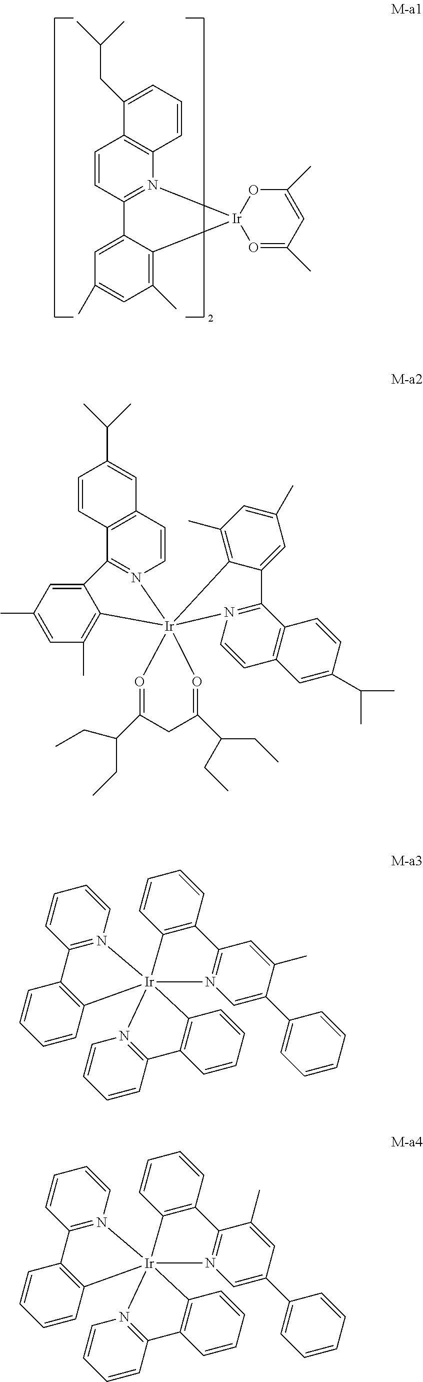

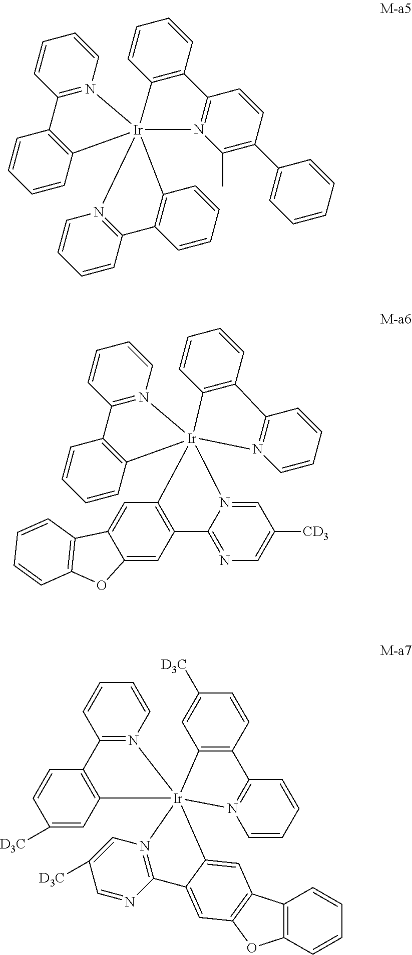

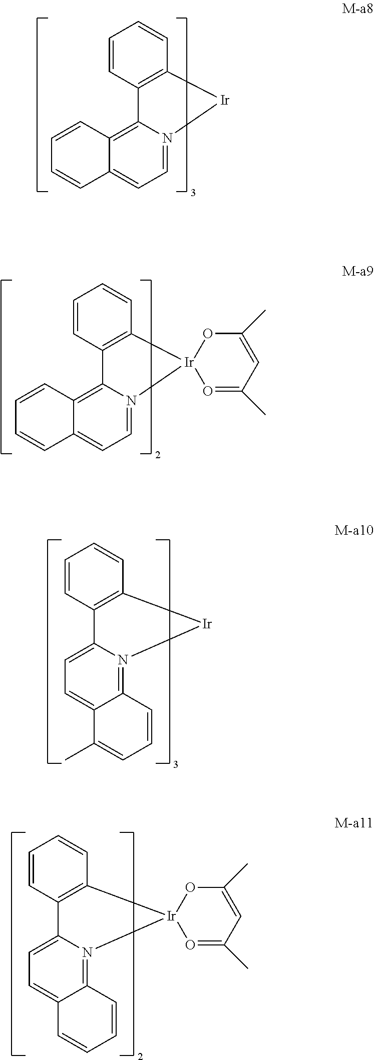

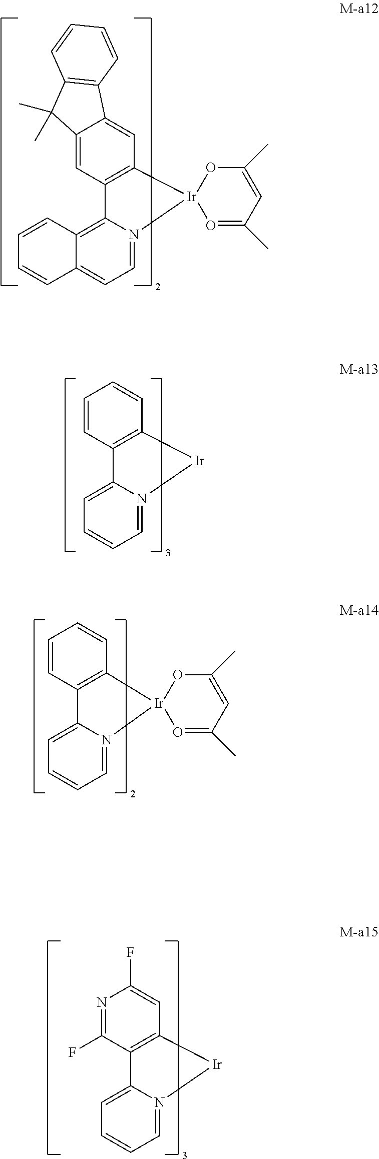

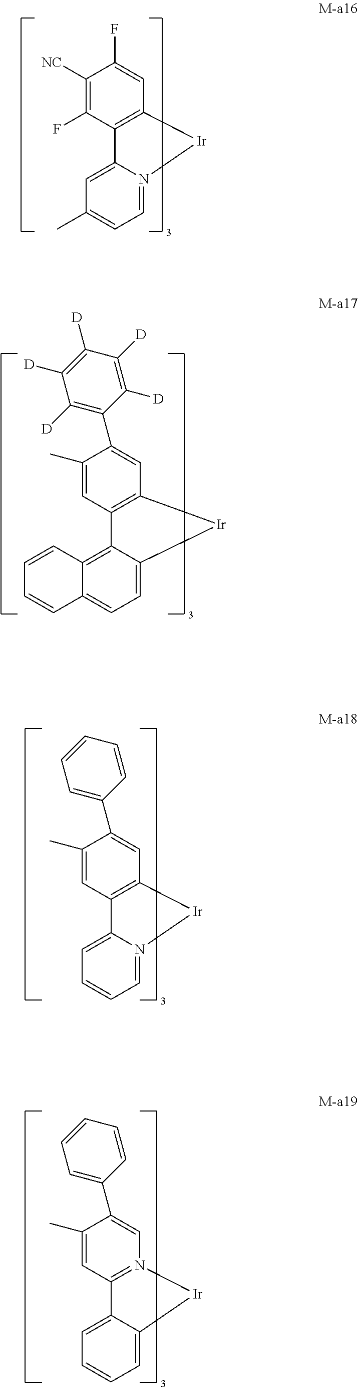

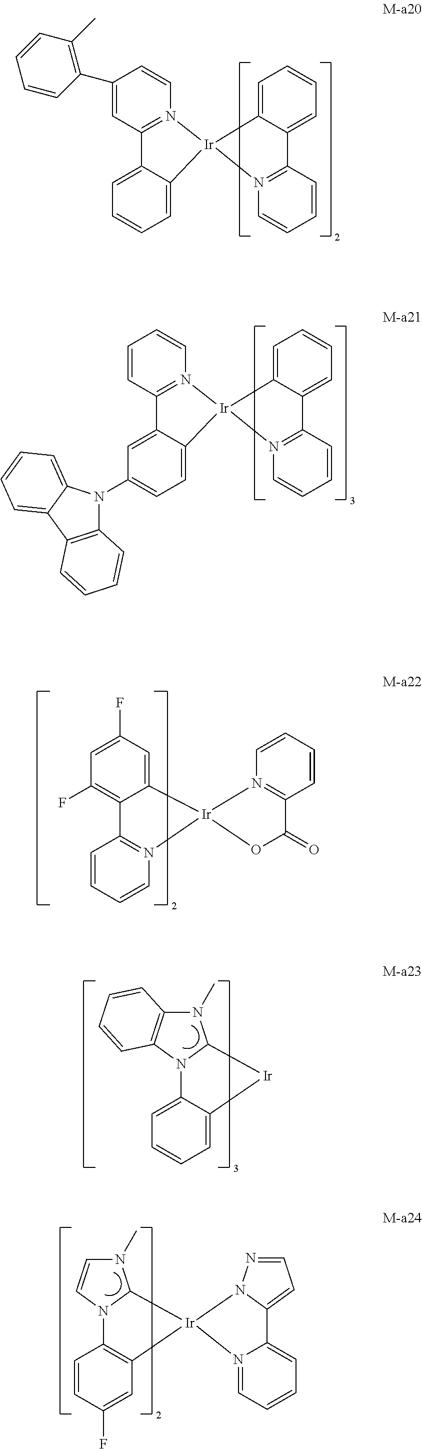

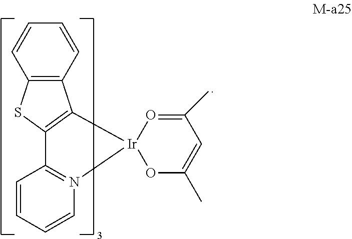

Compound M-a1 and Compound M-a2 may be utilized as a red dopant material, and Compound M-a3 to Compound M-a7 may be utilized as a green dopant material.

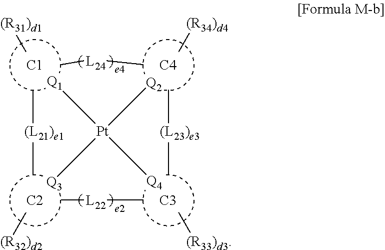

In Formula M-b, Q₁ to Q₄ are each independently C or N, and C1 to C4 are each independently a substituted or unsubstituted hydrocarbon ring having 5 to 30 ring-forming carbon atoms, or a substituted or unsubstituted heterocycle having 2 to 30 ring-forming carbon atoms. L₂₁ to L₂₄ are each independently a direct linkage, *—O—*, *—S—*,

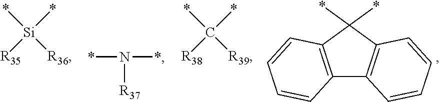

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and e1 to e4 are each independently 0 or 1. R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and d1 to d4 are each independently an integer of 0 to 4.

The compound represented by Formula M-b may be utilized as a blue phosphorescence dopant or a green phosphorescence dopant.

The compound represented by Formula M-b may be represented by any one selected among the compounds below. However, the compounds below are presented as examples, and the compound represented by Formula M-b is not limited to those represented by the compounds below.

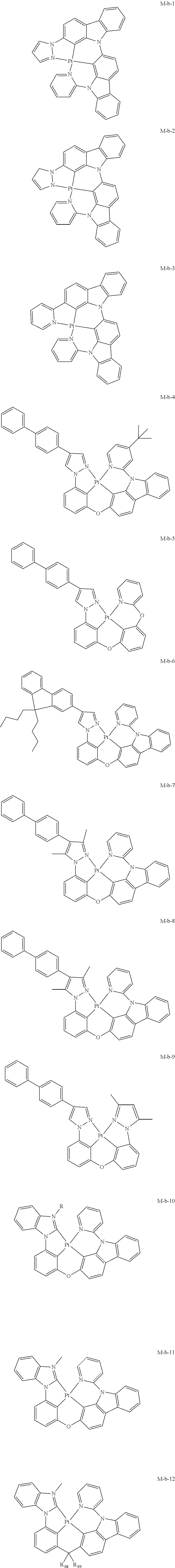

In the compounds above, R, R₃₈, and R₃₉ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may further include a compound represented by any one selected among Formula F-a to Formula F-c below. The compound represented by Formula F-a or Formula F-c below may be utilized as a fluorescence dopant material.

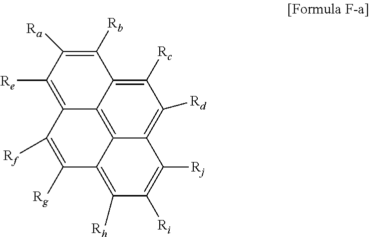

In Formula F-a, two selected from among Rₐ to Rⱼ may each independently be substituted with *—NAr₁Ar₂. The others (e.g., the rest of Rₐ to Rⱼ), which are not substituted with *—NAr₁Ar₂, among Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

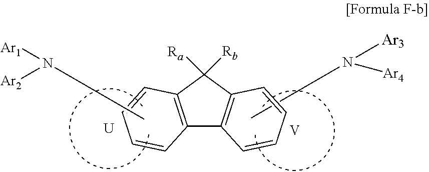

In Formula F-b, Rₐ and R_{b} may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may be each independently 0 or 1. For example, in Formula F-b, when the number of U or V is 1, one ring indicated by U or V forms a condensed ring at the designated part, and when the number of U or V is 0, it indicates that no ring described as U or V is present. For example, when the number of U is 0 and the number of V is 1, or when the number of U is 1 and the number of V is 0, the condensed ring having a fluorene core of Formula F-b may be a cyclic compound having four rings. In addition, when each number of U and V is 0, the condensed ring of Formula F-b may be a cyclic compound having three rings. In addition, when each number of U and V is 1, the condensed ring having a fluorene core of Formula F-b may be a cyclic compound having five rings.

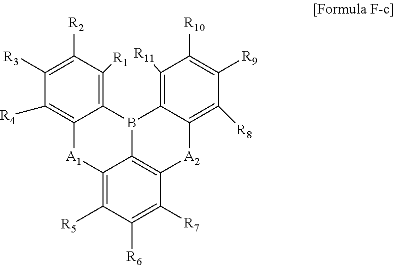

In Formula F-c, A₁ and A₂ may be each independently O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may be each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a condensed ring. For example, when A₁ and A₂ are each independently NRₘ, A₁ may be bonded to R₄ or R₅ to form a ring. In addition, A₂ may be bonded to R₇ or R₈ to form a ring.

In an embodiment, the emission layer EML may further include, as a suitable (e.g., known) dopant material, styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl(DPAVBi)), perylene and the derivatives thereof (e.g., 2,5,8,11-tetra-t-butylperylene (TBP)), pyrene and the derivatives thereof (e.g., 1,1-dipyrene, 1,4-dipyrenylbenzene, 1,4-bis(N,N-diphenylamino)pyrene), etc.

The emission layer EML may include a suitable (e.g., known) phosphorescence dopant material. For example, a metal complex including iridium (Ir), platinum (Pt), osmium (Os), gold (Au), titanium (Ti), zirconium (Zr), hafnium (Hf), europium (Eu), terbium (Tb), and/or thulium (Tm) may be utilized as a phosphorescence dopant. For example, iridium(III) bis(4,6-difluorophenylpyridinato-N,C2′) picolinate (Flrpic), bis(2,4-difluorophenylpyridinato)-tetrakis(1-pyrazolyl)borate iridium(III) (Fir6), and/or platinum octaethyl porphyrin (PtOEP) may be utilized as a phosphorescence dopant. However, the present disclosure is not limited thereto.

The emission layer EML may include a quantum dot material. The core of the quantum dot may be selected from a Group II-VI compound, a Group III-VI compound, a Group 1-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In one or more embodiments, the Group III-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In one or more embodiments, the binary compound, the ternary compound, and/or the quaternary compound may be present in particles in a uniform (e.g., substantially uniform) concentration distribution, or may be present in the same particle in a partially different concentration distribution. In addition, the quantum dot may have a core/shell structure in which one quantum dot is around (e.g., surrounds) another quantum dot. In a core/shell structure, the interface of the shell may have a concentration gradient in which the concentration of an element present in the shell becomes lower towards the core. For example, in a core/shell structure, a concentration gradient may be present in which the concentration of an element present in the shell becomes lower towards the center of the core.

In some embodiments, a quantum dot may have the above-described core-shell structure including a core containing nanocrystals and a shell around (e.g., surrounding) the core. The shell of the quantum dot may serve as a protection layer to prevent or substantially prevent the chemical deformation of the core so as to maintain semiconductor properties, and/or as a charging layer to impart electrophoresis properties to the quantum dot. The shell may be a single layer or a multilayer. An example of the shell of the quantum dot may include a metal oxide, a non-metal oxide, a semiconductor compound, or a combination thereof.

For example, the metal oxide and/or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; and/or a ternary compound such as MgAl₂O₄, CoFe₂O₄, NiFe₂O₄, and/or CoMn₂O₄, but the present disclosure is not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the present disclosure is not limited thereto.

The quantum dot may have a full width at half maximum (FWHM) of a light emission wavelength spectrum of about 45 nm or less, for example about 40 nm or less, or about 30 nm or less, and color purity or color reproducibility may be improved in the above ranges. In addition, light emitted through such a quantum dot is emitted in all directions, and thus a wide viewing angle may be obtained (e.g., improved).

In addition, the form of the quantum dot is not particularly limited as long as it is a form commonly utilized in the art, and for example, a quantum dot in the form of spherical, pyramidal, multi-arm, and/or cubic nanoparticles, nanotubes, nanowires, nanofibers, nanoplate particles, etc., may be utilized.

The quantum dot may control the color of emitted light according to the particle size thereof, and accordingly, the quantum dot may have various suitable emission colors such as blue, red, and/or green.

The hole transport region HTR is provided between the first electrode EL1 and the emission layer EML. The hole transport region HTR may include at least one of a hole injection layer HIL, a hole transport layer HTL, a buffer layer, an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, and may have a single layer structure formed of a hole injection material and a hole transport material. In addition, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in the respective stated order from the first electrode EL1, but the present disclosure is not limited thereto.

The hole transport region HTR may be formed utilizing various suitable methods such as a vacuum deposition method, a spin coating method, a cast method, a Langmuir-Blodgett (LB) method, an inkNet printing method, a laser printing method, and/or a laser induced thermal imaging (LITI) method.

In an embodiment, the hole transport region HTR may include Compound G-1 and/or Compound G-2 below:

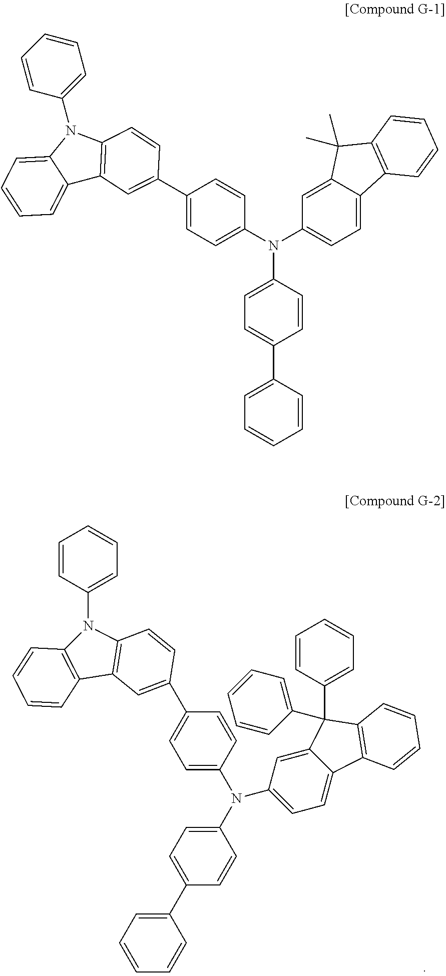 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a compound represented by Formula H-1 below:

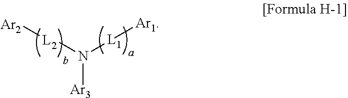

In Formula H-1 above, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. a and b may be each independently an integer of 0 to 10. In one or more embodiments, when a or b is an integer of 2 or greater, a plurality of L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. In addition, in Formula H-1, Ara may be a substituted or unsubstituted aryl group having 6 to 30 ring-forming carbon atoms.

The compound represented by Formula H-1 above may be a monoamine compound (e.g., a compound including a single amine group). In some embodiments, the compound represented by Formula H-1 above may be a diamine compound in which at least one selected among Ar₁ to Ar₃ includes the amine group as a substituent. In addition, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected among the compounds of Compound Group H below. However, the compounds listed in Compound Group H below are presented as examples, and the compound represented by Formula H-1 is not limited to the ones listed in Compound Group H below:

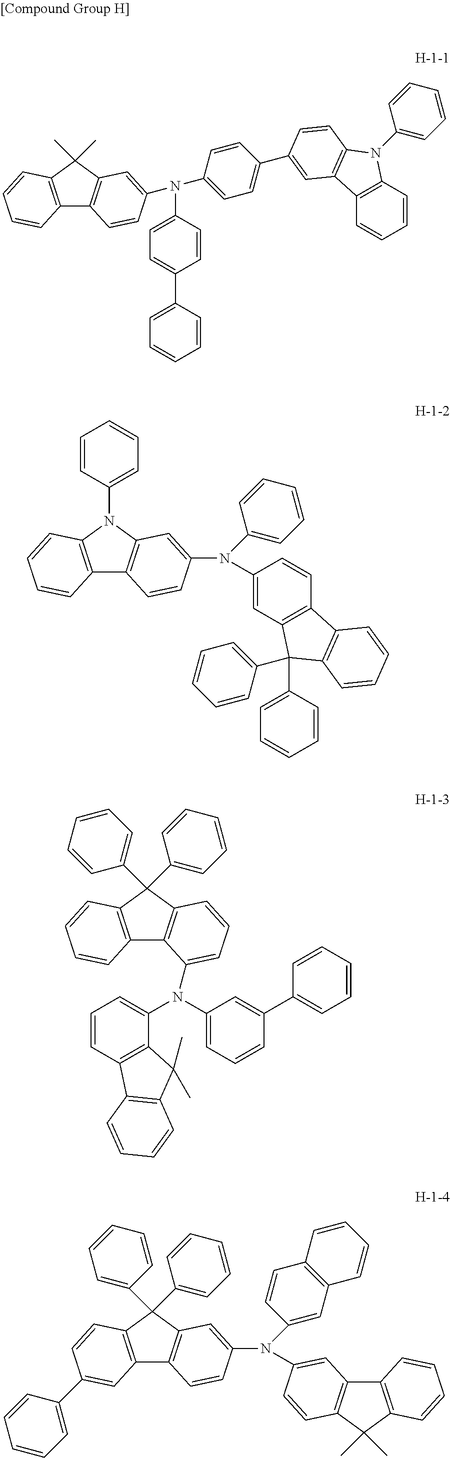 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

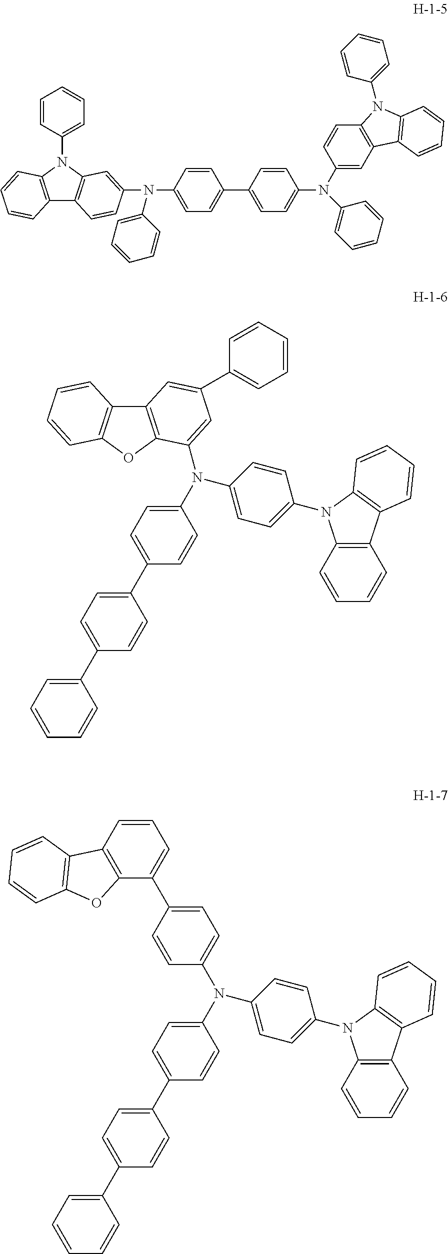 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

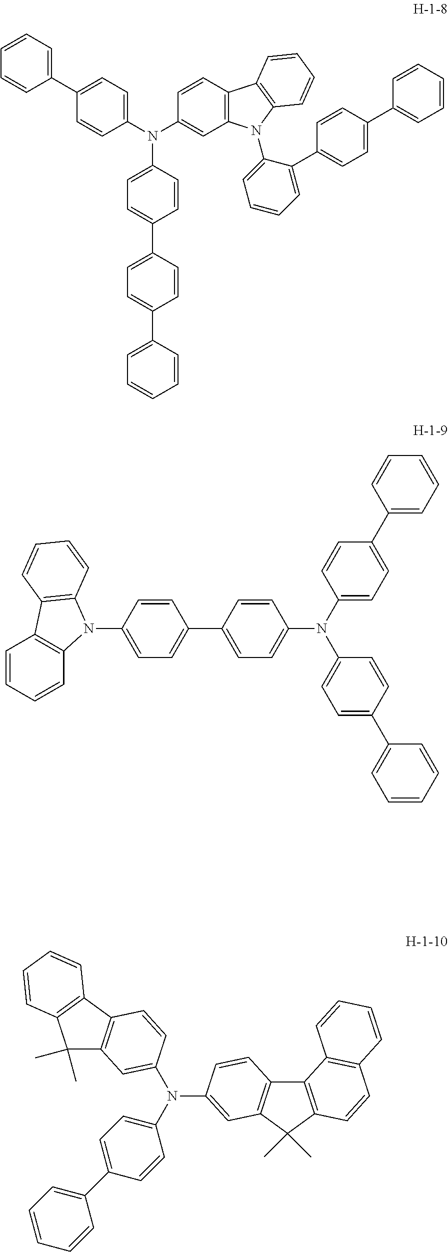 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

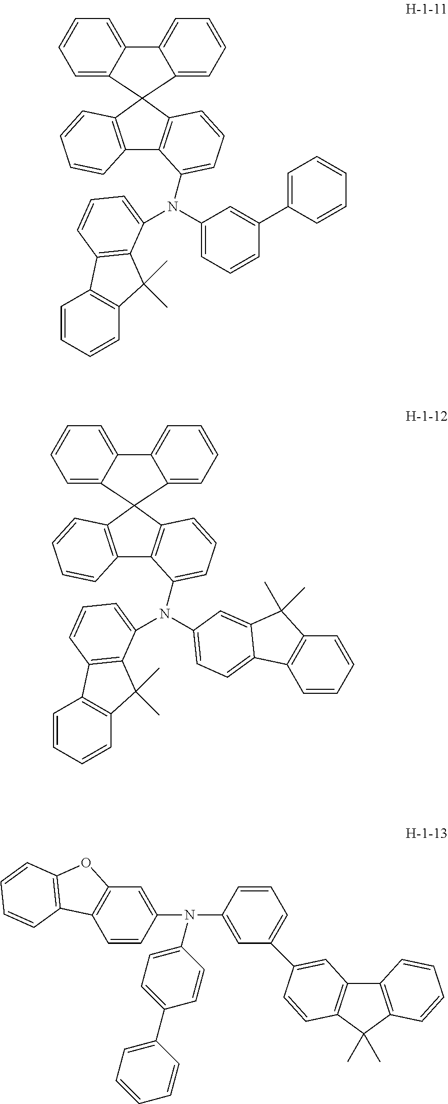 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

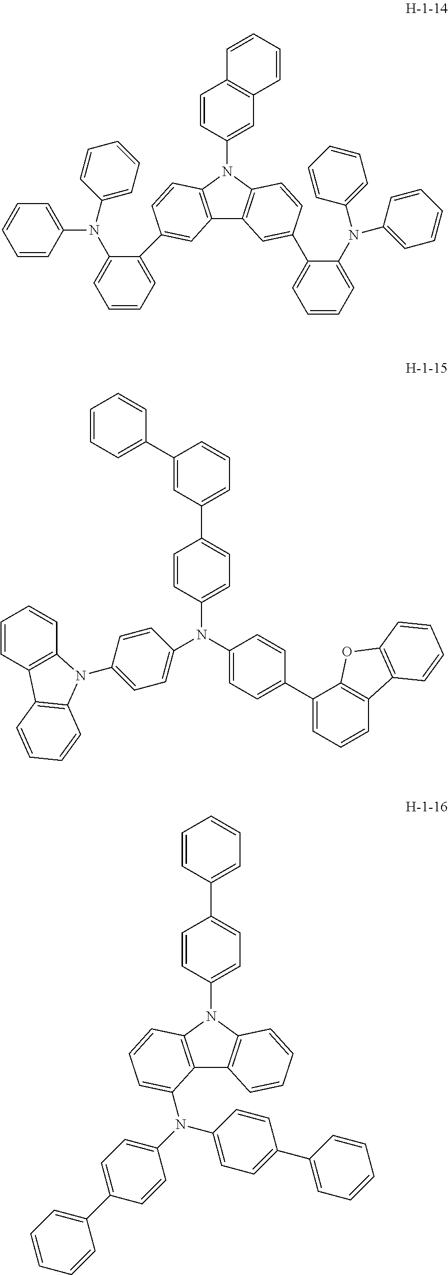 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

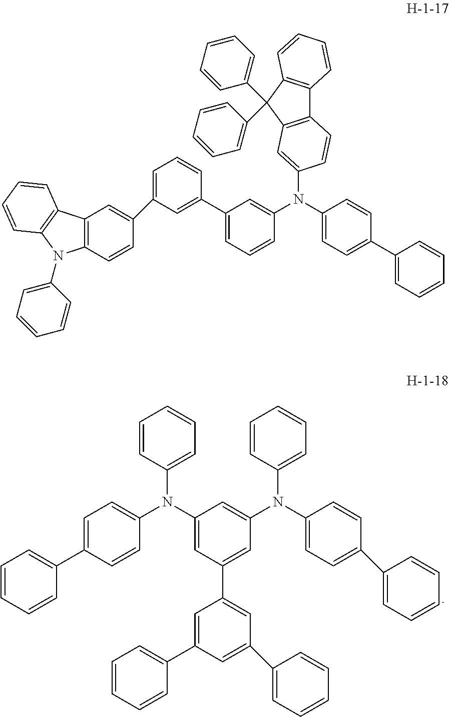 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tis(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include one or more carbazole derivatives such as N-phenyl carbazole and/or polyvinyl carbazole, fluorene derivatives, N,N′-bis(3-methylphenyl)-N,N′-diphenyl-[1,1-biphenyl]-4,4′-diamine (TPD), triphenylamine derivatives such as 4,4′,4″-tis(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In addition, the hole transport region HTR may include 9-(4-tert-butylphenyl)-3,6-bis(tiphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one selected from among the hole injection layer HIL, the hole transport layer HTL, or the electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 30 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described respective ranges, satisfactory hole transport properties may be achieved (e.g., obtained) without a substantial increase in a driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the present disclosure is not limited thereto. For example, the p-dopant may include one or more metal halides such as CuI and/or RbI, quinone derivatives such as tetracyanoquinodimethane (TCNQ) and/or 2,3,5,6-tetrafluoro-7,7′8,8-tetracyanoquinodimethane (F4-TCNQ), metal oxides such as tungsten oxide and/or molybdenum oxide, dipyrazino[2,3-f: 2′,3′-h] quinoxaline-2,3,6,7,10,11-hexacarbonitrile (HATCN), 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the present disclosure is not limited thereto.

As described above, the hole transport region HTR may further include at least one of the buffer layer or the electron blocking layer EBL in addition to the hole injection layer HIL and the hole transport layer HTL. The buffer layer may compensate a resonance distance according to the wavelength of light emitted from the emission layer EML and may thus increase light emission efficiency. Materials which may be included in the hole transport region HTR may be utilized as materials to be included in the buffer layer. The electron blocking layer EBL is a layer that serves to prevent or substantially prevent electrons from being injected from the electron transport region ETR to the hole transport region HTR.

In each light emitting element ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in the respective stated order from the emission layer EML, but the present disclosure is not limited thereto. The electron transport region ETR may have a thickness, for example, from about 1,000 Å to about 1,500 Å.

The electron transport region ETR may be formed by utilizing various suitable methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include a compound represented by Formula ET-1 below:

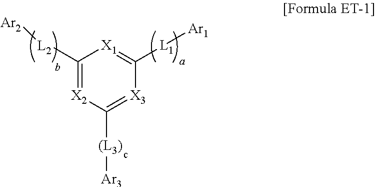

In Formula ET-1, at least one selected among X₁ to X₃ is N, and the remainder (e.g., the rest) are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may be each independently an integer of 0 to 10. In Formula ET-1, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, when a to c are each an integer of 2 or greater, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the present disclosure is not limited thereto, and the electron transport region ETR may include, for example, tis(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

The electron transport region ETR may include at least one selected among Compound ET1 to Compound ET36 below:

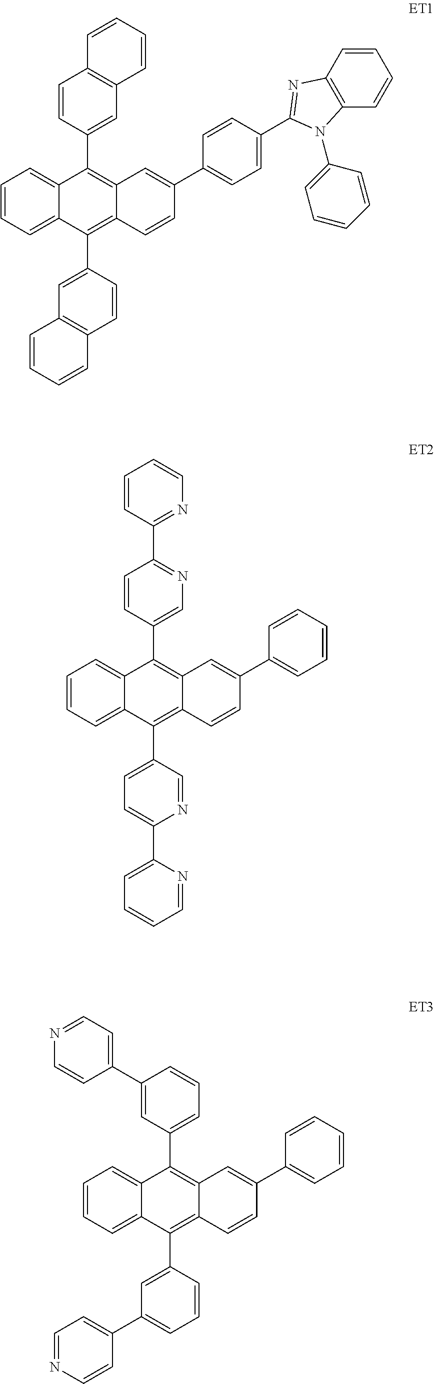 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

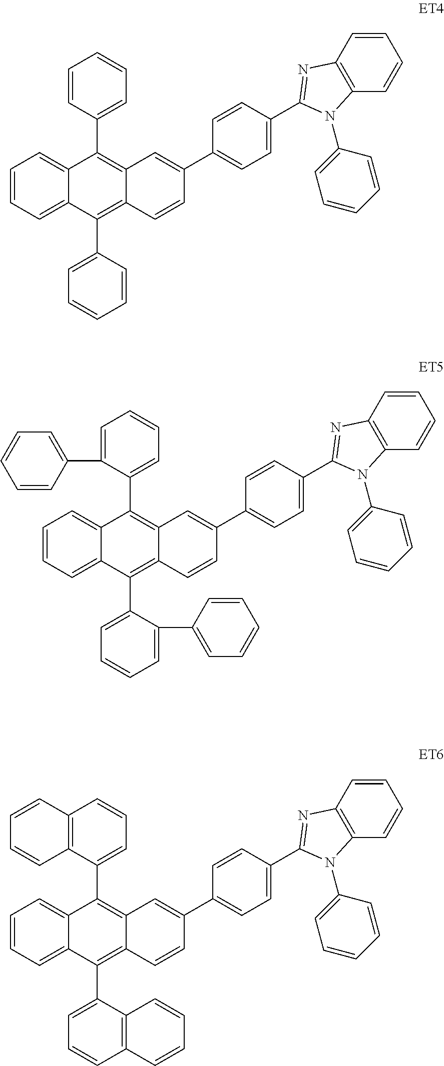 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

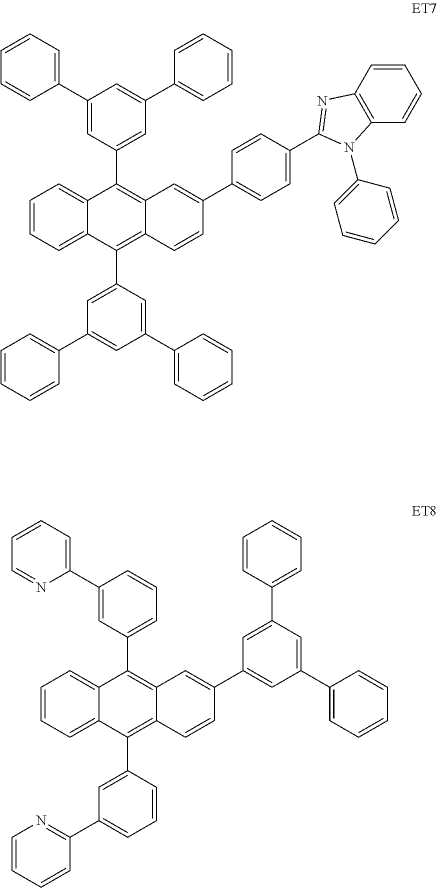 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

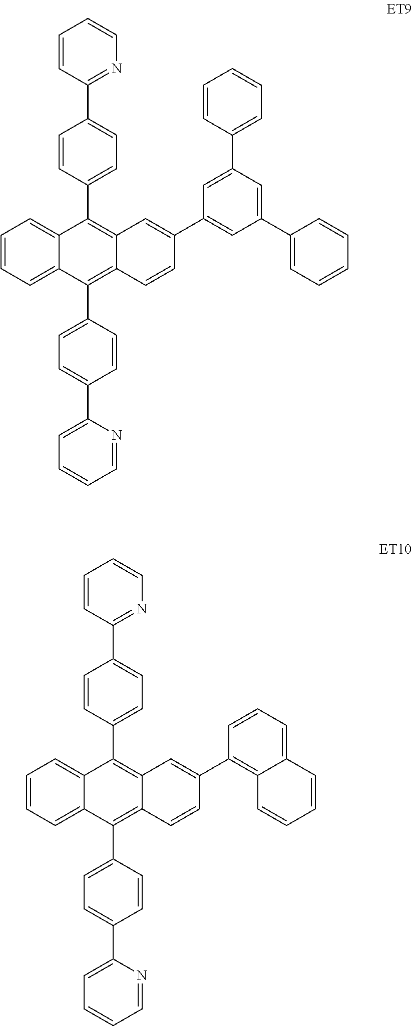 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

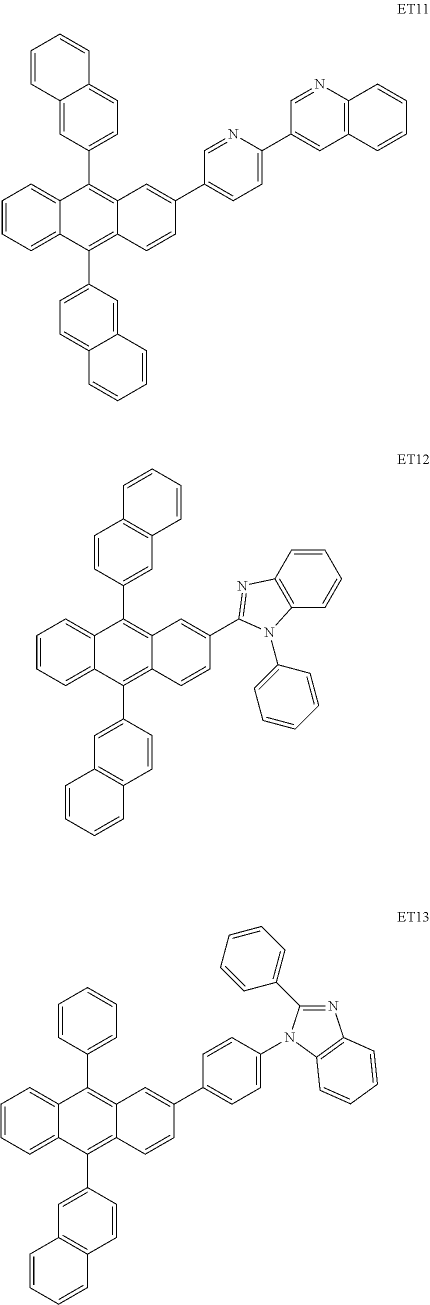 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

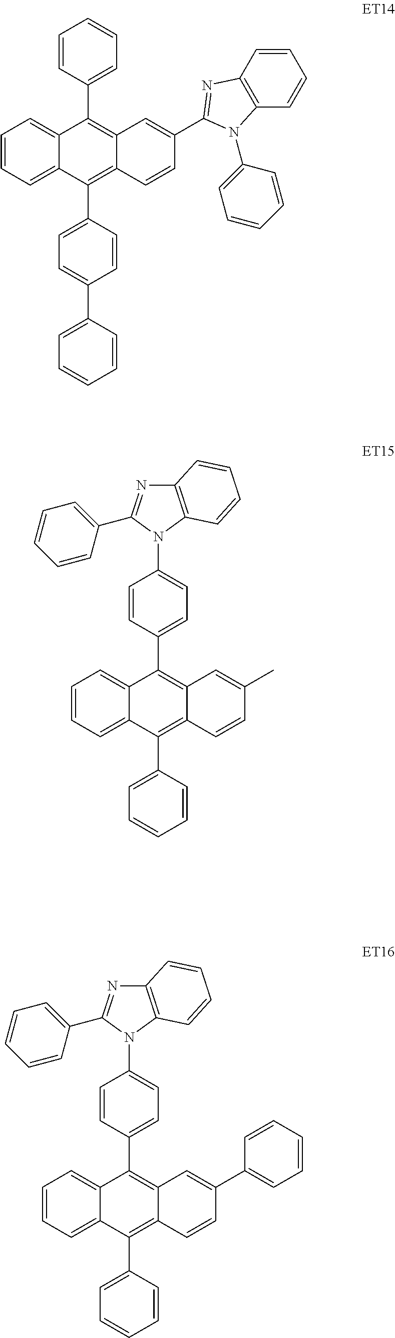 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

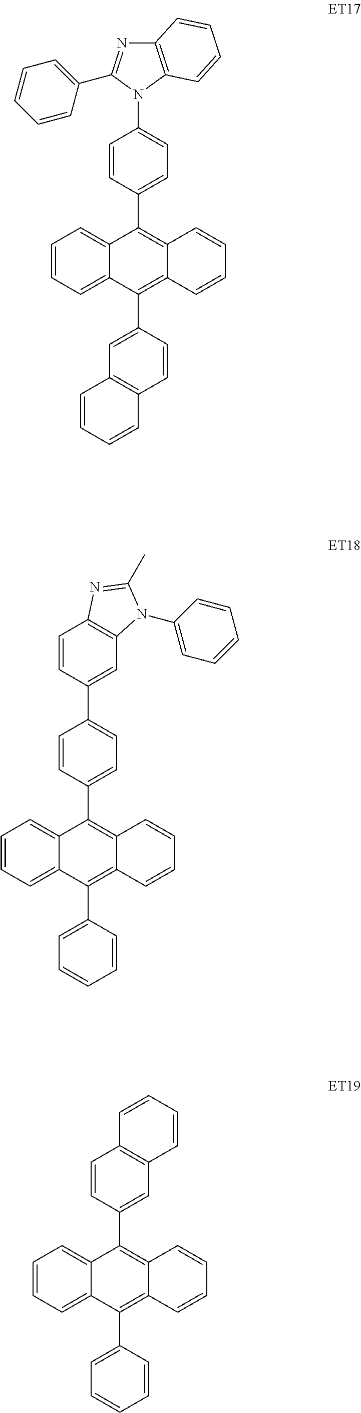

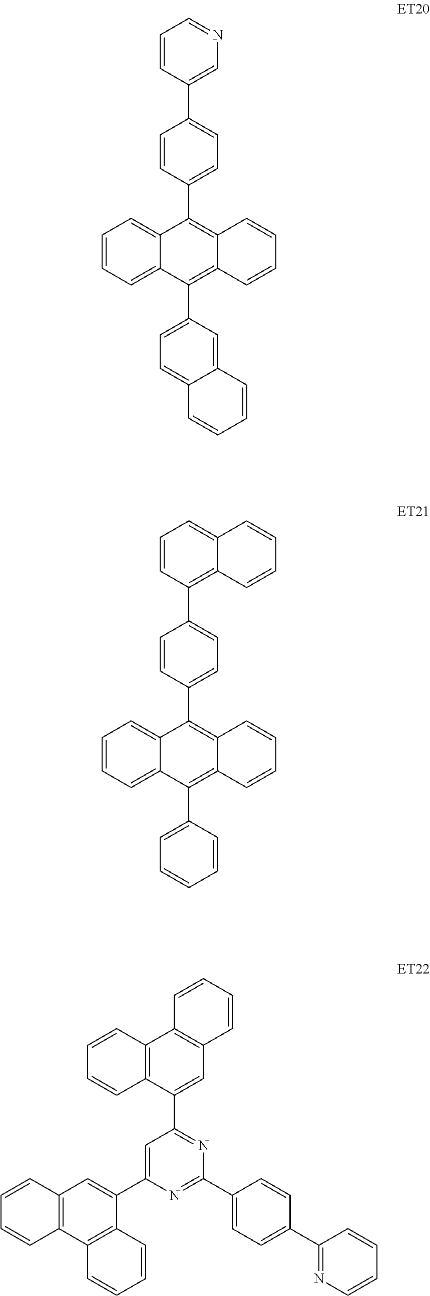

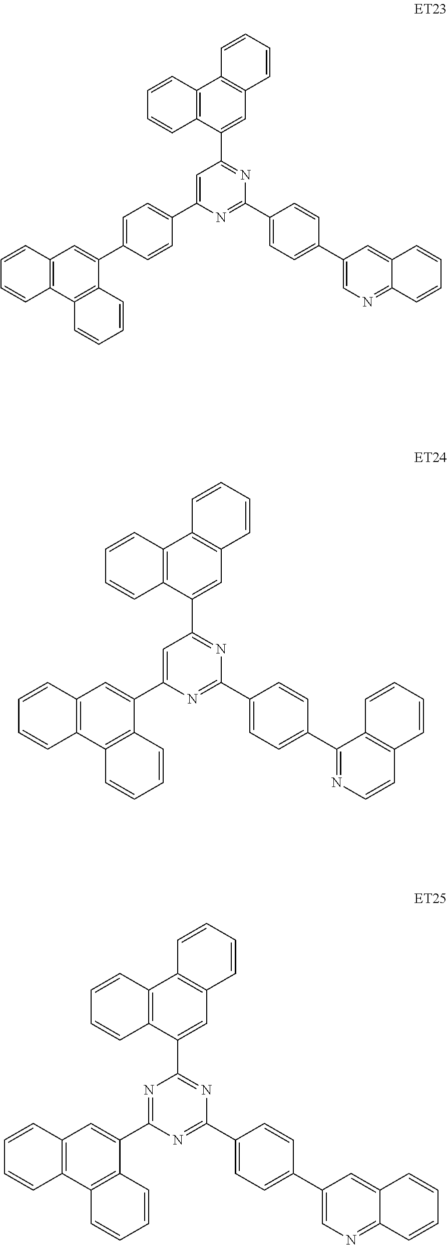 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

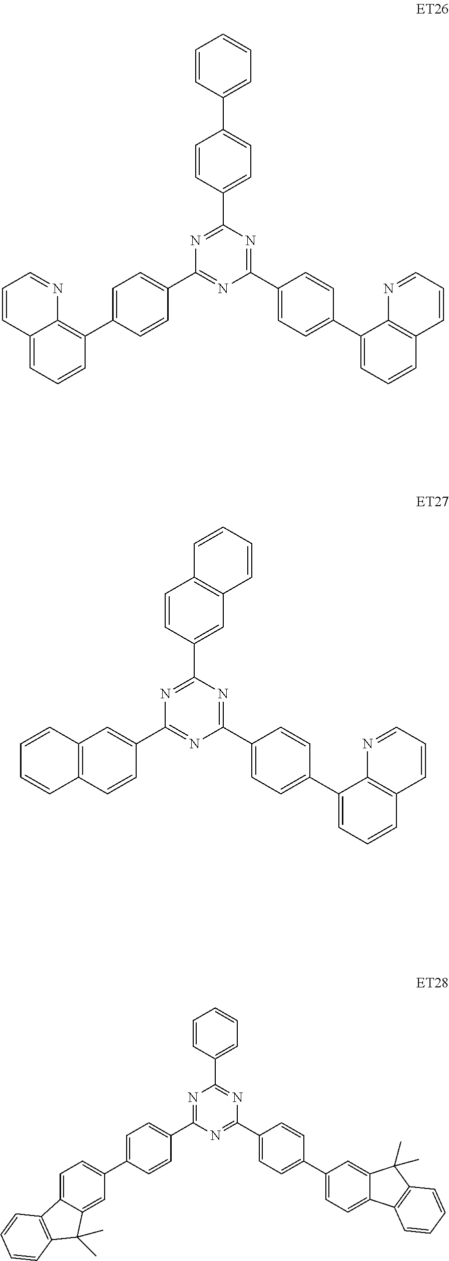 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

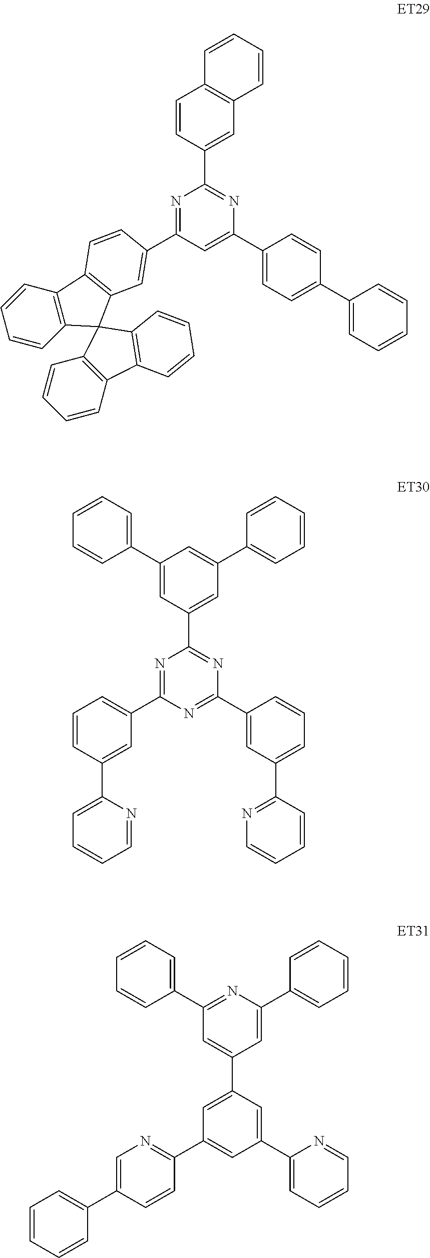 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

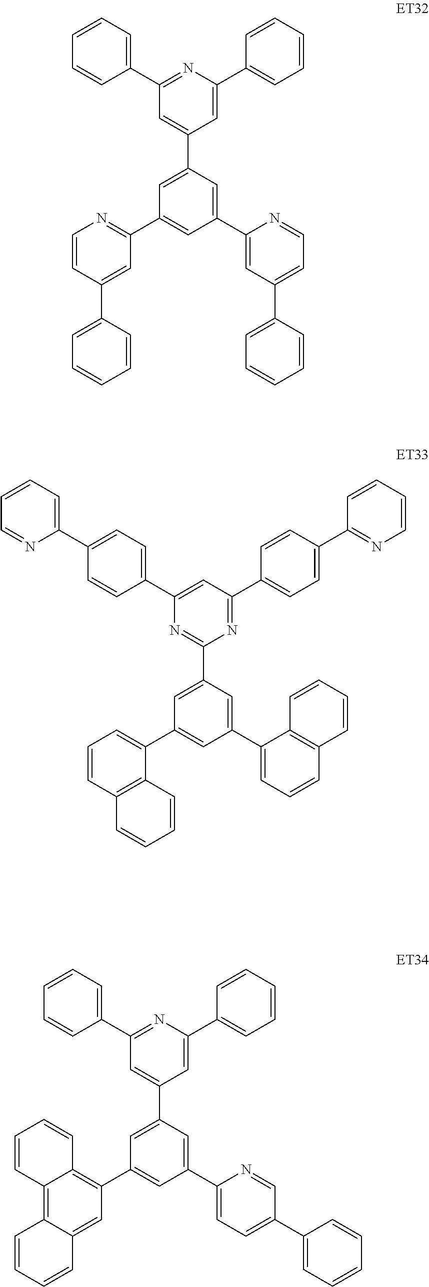 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

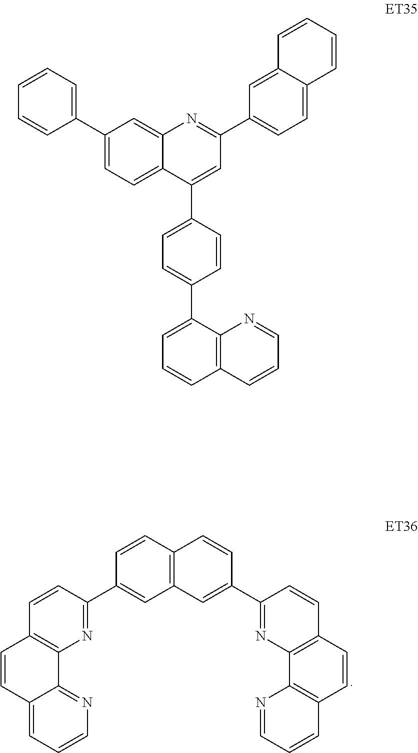 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport regions ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, etc., as a co-deposited material. In one or more embodiments, the electron transport region ETR may be formed utilizing a metal oxide such as Li₂O and/or BaO, 8-hydroxyl-lithium quinolate (Liq), etc., but the present disclosure is not limited thereto. The electron transport region ETR may also be formed of a mixture material of an electron transport material and an insulating organometallic salt. The organometallic salt may be a material having an energy band gap of about 4 eV or more. The organometallic salt may include, for example, one or more metal acetates, metal benzoates, metal acetoacetates, metal acetylacetonates, and/or metal stearates.

The electron transport region ETR may further include 2,9-dimethyl-4,7-diphenyl-1,10-phenanthroline (BCP), and/or 4,7-diphenyl-1,10-phenanthroline (Bphen) in addition to the above-described materials, but the present disclosure is not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned ranges, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, and/or MgAg). LiF/Ca may be a two-layer structure in which LiF is stacked on Ca, and LiF/Al may be a two-layer structure in which LiF is stacked on Al. In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of two or more metal materials of the above-described metal materials, oxides of the above-described metal materials, and/or the like.

In some embodiments, the second electrode EL2 may be connected with an auxiliary electrode. When the second electrode EL2 is connected with the auxiliary electrode, the resistance of the second electrode EL2 may decrease.

In one or more embodiments, a capping layer CPL may be further disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL includes an inorganic material, the inorganic material may include an alkaline metal compound such as LiF, an alkaline earth metal compound such as MgF₂, SiON, SiNₓ, SiO_{y}, etc.

For example, when the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., an epoxy resin, and/or an acrylate such as methacrylate. However, the present disclosure is not limited thereto, and the capping layer CPL may include at least one selected among Compounds P1 to P5 below:

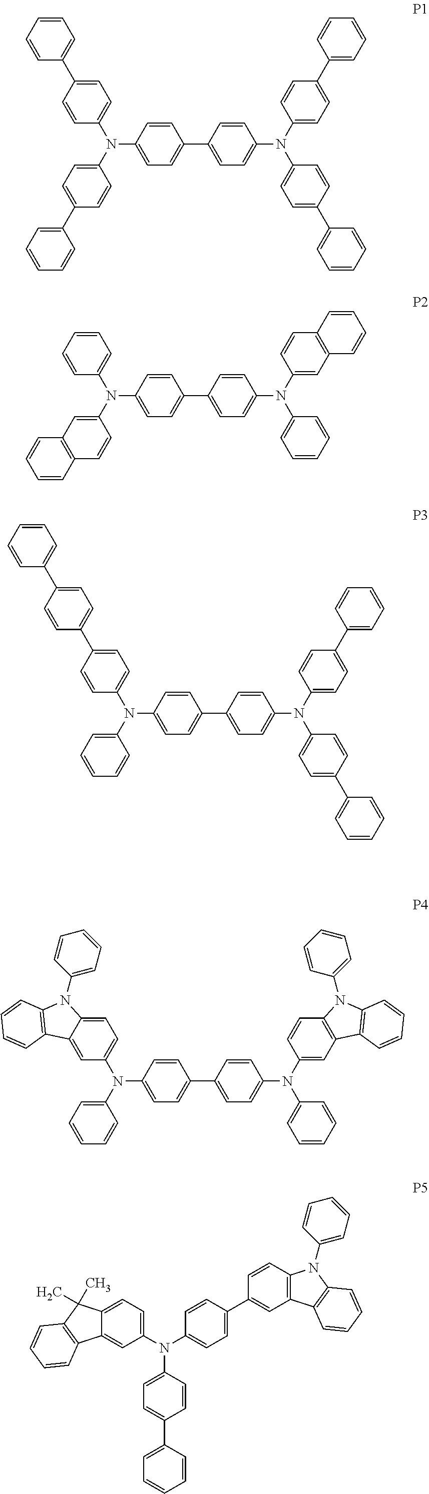 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or greater. For example, the refractive index of the capping layer CPL may be about 1.6 or greater with respect to light in a wavelength range of about 550 nm to about 660 nm.

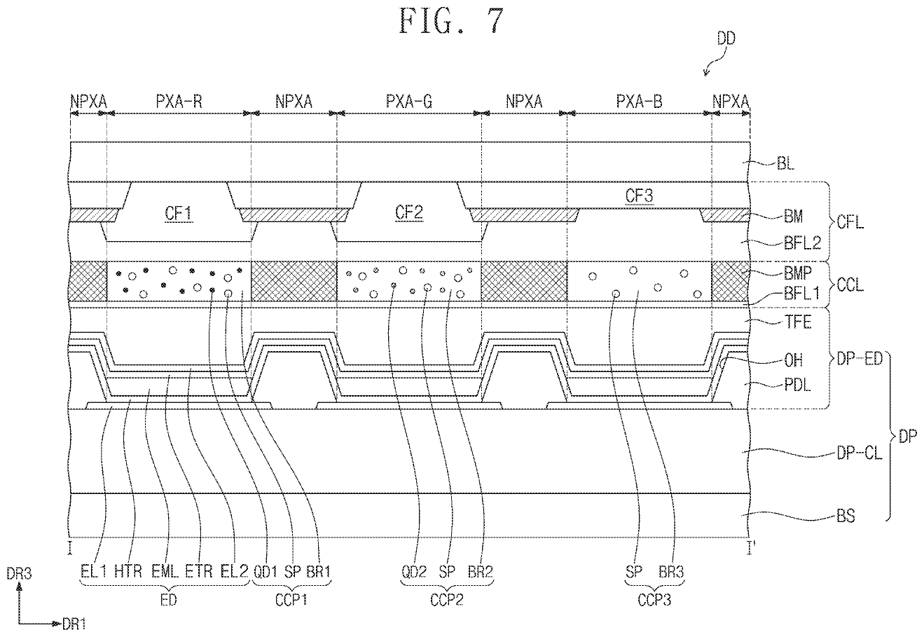

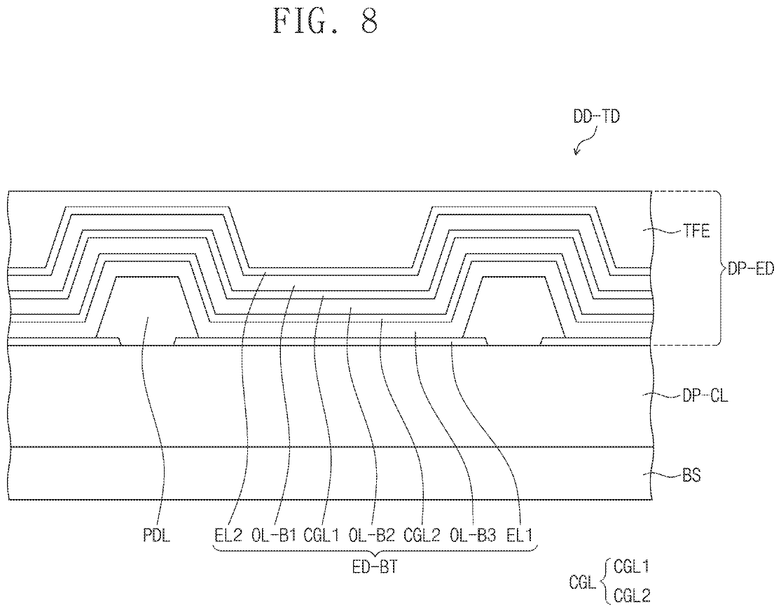

FIGS. 7 and 8 each are a cross-sectional view of a display device according to an embodiment. Hereinafter, in describing the display device of an embodiment with reference to FIGS. 7 and 8, contents overlapping with the ones described above with reference to FIGS. 1 to 6 are not described again, but the differences will be mainly described.

Referring to FIG. 7, the display device DD according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In one or more embodiments, the structures of the light emitting elements of FIGS. 3 to 6 as described above may be equally applied to the structure of the light emitting element ED shown in FIG. 7.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may emit light in the same wavelength range. In the display device DD of an embodiment, the emission layer EML may emit blue light. In one or more embodiments, different from the one illustrated, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may convert the wavelength of received light and emit the resulting light. That is, the light control layer CCL may be a layer containing the quantum dot and/or a layer containing the phosphor.

The light control layer CCL may include a plurality of light control parts (e.g., light controllers) CCP1, CCP2 and CCP3. The light control parts CCP1, CCP2, and CCP3 may be spaced apart from one another.

Referring to FIG. 7, divided patterns BMP may be disposed between the light control parts CCP1, CCP2 and CCP3, which are spaced apart from each other, but the present disclosure is not limited thereto. FIG. 7 illustrates that the divided patterns BMP do not overlap the light control parts CCP1, CCP2 and CCP3, but in some embodiments, at least a portion of the edges of the light control parts CCP1, CCP2 and CCP3 may overlap the divided patterns BMP.

The light control layer CCL may include a first light control part CCP1 containing a first quantum dot QD1, which converts a first color light provided from the light emitting element ED into a second color light, a second light control part CCP2 containing a second quantum dot QD2, which converts the first color light into a third color light, and a third light control part CCP3, which transmits the first color light.

In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described above may be applied with respect to the quantum dots QD1 and QD2.

In addition, the light control layer CCL may further include a scatterer SP (e.g., a light scatterer SP). The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, or hollow silica. The scatterer SP may include any one of TiO₂, ZnO, Al₂O₃, SiO₂, or hollow silica, or may be a mixture of two or more materials selected from among TiO₂, ZnO, Al₂O₃, SiO₂, and hollow silica.

The first light control part CCP1, the second light control part CCP2, and the third light control part CCP3 each may include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are medium in which the quantum dots QD1 and QD2 and the scatterer SP are dispersed, and may be formed of various suitable resin compositions, which may be generally referred to as a binder. For example, the base resins BR1, BR2, and BR3 may be one or more acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 each may be the same as or different from each other.

The light control layer CCL may include a barrier layer BFL1. The barrier layer BFL1 may serve to prevent or substantially prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2 and CCP3 from being exposed to moisture/oxygen. In one or more embodiments, the barrier layer BFL1 may cover the light control parts CCP1, CCP2, and CCP3. In addition, a barrier layer BFL2 may be provided between the light control parts CCP1, CCP2, and CCP3 and the color filter layer CFL.

The barrier layers BFL1 and BFL2 may include at least one inorganic layer. That is, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film with a suitable transmittance, etc. In one or more embodiments, the barrier layers BFL1 and BFL2 may further include an organic film. The barrier layers BFL1 and BFL2 may be formed of a single layer or a plurality of layers.

In the display device DD of an embodiment, the color filter layer CFL may be disposed on the light control layer CCL. For example, the color filter layer CFL may be directly disposed on the light control layer CCL. In this case, the barrier layer BFL2 may be omitted.

The color filter layer CFL may include a light shielding unit BM and filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin, and a pigment and/or a dye. The first filter CF1 may include a red pigment and/or dye, the second filter CF2 may include a green pigment and/or dye, and the third filter CF3 may include a blue pigment and/or dye. However, the present disclosure is not limited thereto, and the third filter CF3 may not include a pigment or a dye. The third filter CF3 may include a polymeric photosensitive resin and may not include a pigment or a dye. The third filter CF3 may be transparent. The third filter CF3 may be formed of a transparent photosensitive resin.

Furthermore, in an embodiment, the first filter CF1 and the second filter CF2 may each be a yellow filter. The first filter CF1 and the second filter CF2 may not be separated but may be provided as one filter.

The light shielding unit BM may be a black matrix. The light shielding unit BM may include an organic light shielding material and/or an inorganic light shielding material containing a black pigment and/or dye. The light shielding unit BM may prevent or reduce light leakage, and may separate boundaries between the adjacent filters CF1, CF2, and CF3. In addition, in an embodiment, the light shielding unit BM may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the present disclosure is not limited thereto, and the base substrate BL may be an inorganic layer, an organic layer, or a composite material layer (e.g., a composite material layer including an inorganic material and an organic material). In addition, different from the one shown, in an embodiment, the base substrate BL may be omitted.

FIG. 8 is a cross-sectional view illustrating a part of a display device according to an embodiment. FIG. 8 illustrates a cross-sectional view of a part corresponding to the display panel DP of FIG. 7. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 facing each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR with the emission layer EML (FIG. 7) therebetween.

That is, the light emitting element ED-BT included in the display device DD-TD of an embodiment may be a light emitting element having a tandem structure and including a plurality of emission layers.

In an embodiment illustrated in FIG. 8, light (e.g., light beams) respectively emitted from the light emitting structures OL-B1, OL-B2, and OL-B3 may all be blue light. However, the present disclosure is not limited thereto, and the light (e.g., light beams) respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3, which emit light beams having wavelength ranges different from each other, may emit white light.

A charge generation layer CGL may be disposed between the neighboring light emitting structures OL-B1, OL-B2, and OL-B3. For example, a charge generation layer CGL1 may be between the light emitting structure OL-B1 and the light emitting structure OL-B2, and a charge generation layer CGL2 may be between the light emitting structure OL-B2 and the light emitting structure OL-B3. The charge generation layer CGL may include a p-type charge generation layer and/or an n-type charge generation layer.

Hereinafter, with reference to Examples and Comparative Examples, a polycyclic compound according to an embodiment of the present disclosure and a light emitting element of an embodiment of the present disclosure will be described in more detail. In addition, Examples shown below are illustrated only for the understanding of the present disclosure, and the scope of the present disclosure is not limited thereto.

### EXAMPLES

### 1. Synthesis of Polycyclic Compound

First, a synthesis method of a polycyclic compound according to an embodiment will be described in more detail by illustrating synthesis methods of Compounds 4, 6, 12, 39, and 60. In addition, in the following descriptions, the synthesis methods of the compounds are presented as an example, but the synthesis method for a compound according to an embodiment of the present disclosure is not limited to Examples below.

### (1) Synthesis of Compound 4

Compound 4 may be synthesized by, for example, the steps (tasks) shown in Reaction Scheme 1 below:

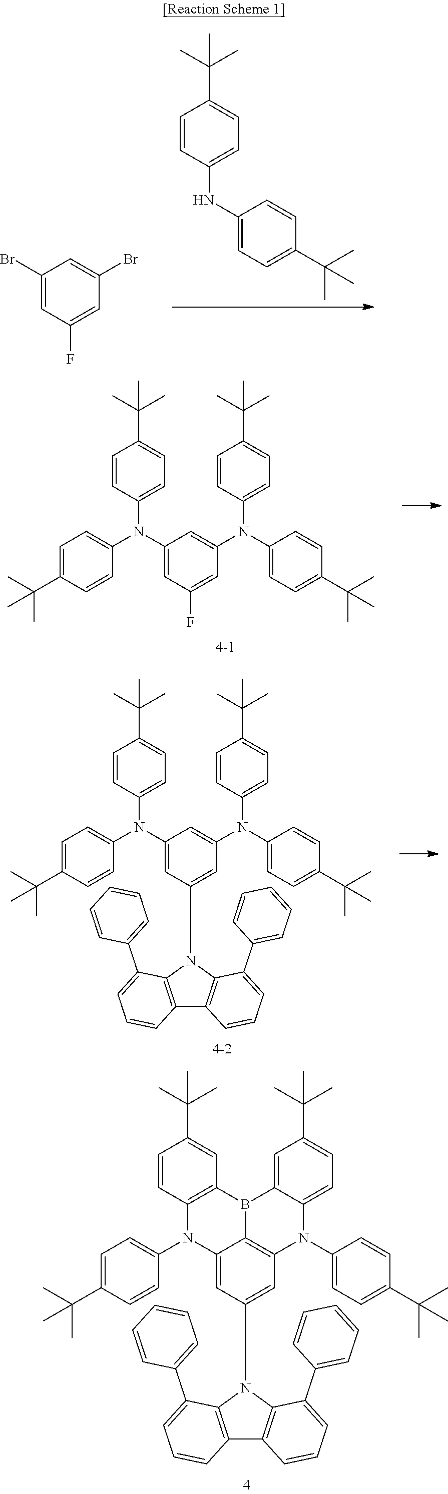

### Synthesis of Intermediate 4-1

1,3-dibromo-5-fluorobenzene (1 equiv), bis(4-(tert-butyl)phenyl)amine (2 equiv), tris(dibenzylideneacetone)dipalladium(0) (0.05 equiv), P(tBu)₃ (0.1 equiv), and sodium tert-butoxide (2 equiv) were dissolved in toluene, and then stirred at about 110° C. for about 12 hours in a nitrogen atmosphere. The stirred mixture was cooled and then washed three times with ethyl acetate and water to obtain an organic layer. The obtained organic layer was dried over magnesium sulfate (MgSO₄), and then dried under reduced pressure to obtain residues (e.g., dried materials). The obtained residues were separated and purified by column chromatography to obtain Intermediate 4-1. (yield: 80%)

### Synthesis of Intermediate 4-2

Intermediate 4-1 (1 equiv), 1,8-diphenyl-9H-carbazole (1.5 equiv), copper iodide (1 equiv), and K₂CO₃ (10 equiv) were dissolved in DMF and stirred at about 160° C. for about 50 hours in a nitrogen atmosphere. The stirred mixture was cooled and then washed three times with ethyl acetate and water to obtain an organic layer. The obtained organic layer was dried over MgSO₄, and then dried under reduced pressure to obtain residues. The obtained residues were separated and purified by column chromatography to obtain Intermediate 4-2. (yield: 20%)

### Synthesis of Compound 4

Intermediate 4-2 (1 equiv) and boron triiodide (3 equiv) were dissolved in ODCB, and then stirred at about 180° C. for about 24 hours in a nitrogen atmosphere. The stirred mixture was cooled and then quenched with triethylamine and filtered with methanol to obtain a solid. The solid was dried to obtain residues. The obtained residues were separated and purified by column chromatography to obtain Compound 4. (yield: 15%)

### (2) Synthesis of Compound 6

Compound 6 may be synthesized by, for example, the steps (tasks) shown in Reaction Scheme 2 below:

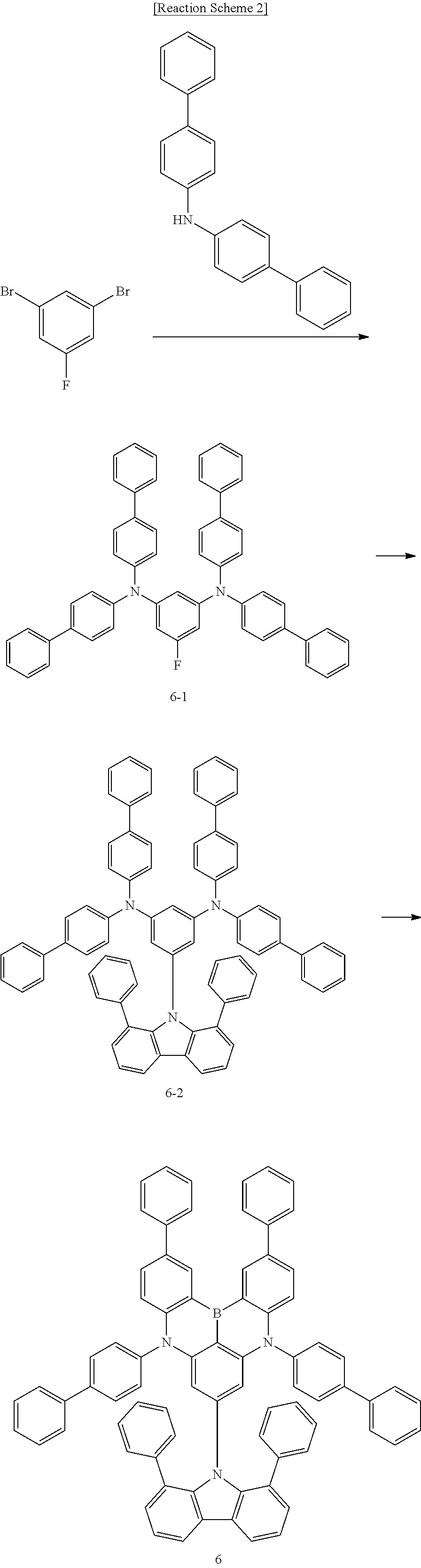 [SMILES: Fc1cc(Br)cc(Br)c1 ; c1ccc(-c2ccc(Nc3ccc(-c4ccccc4)cc3)cc2)cc1 ; Fc1cc(N(c2ccc(-c3ccccc3)cc2)c2ccc(-c3ccccc3)cc2)cc(N(c2ccc(-c3ccccc3)cc2)c2ccc(-c3ccccc3)cc2)c1 ; c1ccc(-c2ccc(N(c3ccc(-c4ccccc4)cc3)c3cc(N(c4ccc(-c5ccccc5)cc4)c4ccc(-c5ccccc5)cc4)cc(-n4c5c(-c6ccccc6)cccc5c5cccc(-c6ccccc6)c54)c3)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7c(-c8ccccc8)cccc7c7cccc(-c8ccccc8)c76)cc3c54)cc2)cc1]

### Synthesis of Intermediate 6-1

Intermediate 6-1 was synthesized in the same manner as the synthesis of Intermediate 4-1 except that di([1,1′-biphenyl]-4-yl)amine was utilized instead of bis(4-(tert-butyl)phenyl)amine. (yield: 76%)

### Synthesis of Intermediate 6-2

Intermediate 6-2 was synthesized in the same manner as the synthesis of Intermediate 4-2 except that Intermediate 6-1 was utilized instead of Intermediate 4-1. (yield: 20%)

### Synthesis of Compound 6

Compound 6 was synthesized in the same manner as the synthesis of Compound 4 except that Intermediate 6-2 was utilized instead of Intermediate 4-2. (yield: 13%)

### Synthesis of Compound 12

Compound 12 may be synthesized by, for example, the steps (tasks) shown in Reaction Scheme 3 below:

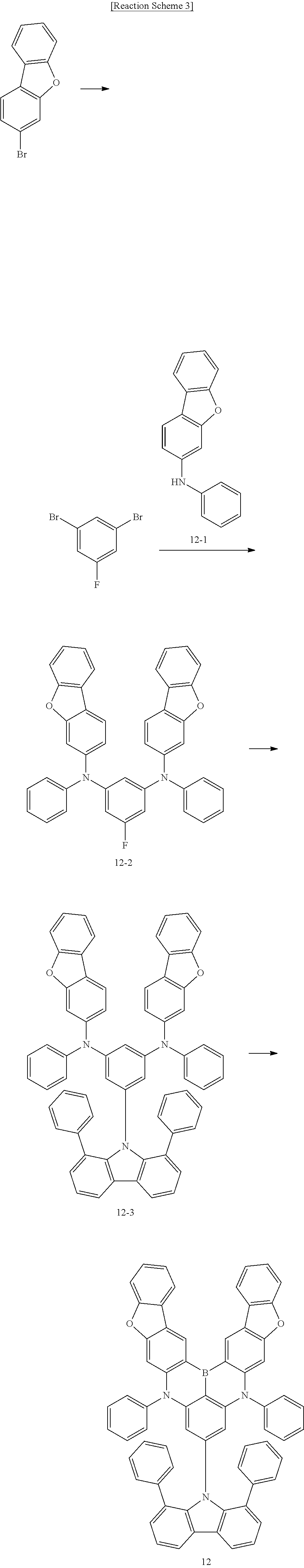 [SMILES: Brc1ccc2c(c1)oc1ccccc12 ; Fc1cc(Br)cc(Br)c1 ; c1ccc(Nc2ccc3c(c2)oc2ccccc23)cc1 ; Fc1cc(N(c2ccccc2)c2ccc3c(c2)oc2ccccc23)cc(N(c2ccccc2)c2ccc3c(c2)oc2ccccc23)c1 ; c1ccc(-c2cccc3c4cccc(-c5ccccc5)c4n(-c4cc(N(c5ccccc5)c5ccc6c(c5)oc5ccccc56)cc(N(c5ccccc5)c5ccc6c(c5)oc5ccccc56)c4)c23)cc1 ; c1ccc(-c2cccc3c4cccc(-c5ccccc5)c4n(-c4cc5c6c(c4)N(c4ccccc4)c4cc7oc8ccccc8c7cc4B6c4cc6c(cc4N5c4ccccc4)oc4ccccc46)c23)cc1]

### Synthesis of Intermediate 12-1

3-bromodibenzo[b,d]furan (1 equiv), aniline (1 equiv), tris(dibenzylideneacetone)dipalladium (0) (0.05 equiv), P(tBU)₃ (0.1 equiv), and sodium tert-butoxide (2 equiv) were dissolved in toluene, and then stirred at about 110° C. for about 12 hours in a nitrogen atmosphere. The stirred mixture was cooled and then washed three times with ethyl acetate and water to obtain an organic layer. The obtained organic layer was dried over MgSO₄, and then dried under reduced pressure to obtain residues. The obtained residues were separated and purified by column chromatography to obtain Intermediate 12-1. (yield: 85%)

### Synthesis of Intermediate 12-2

Intermediate 12-2 was synthesized in the same manner as the synthesis of Intermediate 4-1 except that Intermediate 12-1 was utilized instead of bis(4-(tert-butyl)phenyl)amine. (yield: 70%)

### Synthesis of Intermediate 12-3

Intermediate 12-3 was synthesized in the same manner as the synthesis of Intermediate 4-2 except that Intermediate 12-2 was utilized instead of Intermediate 4-1. (yield: 18%)

### Synthesis of Compound 12

Compound 12 was synthesized in the same method as the synthesis of Compound 4 except that Intermediate 12-3 was utilized instead of Intermediate 4-2. (yield: 15%)

### (4) Synthesis of Compound 39

Compound 39 may be synthesized by, for example, the steps (tasks) shown in Reaction Scheme 4 below:

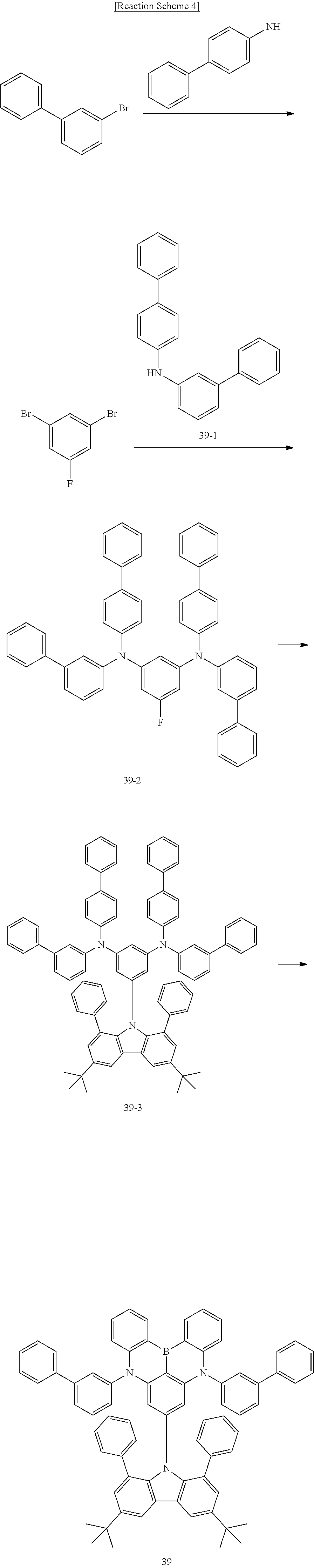

### Synthesis of Intermediate 39-1

3-bromo-1,1′-biphenyl (1 equiv), [1,1′-biphenyl]-4-amine (1 equiv), tris(dibenzylideneacetone)dipalladium(0) (0.05 equiv), P(tBu)₃ (0.1 equiv), and sodium tert-butoxide (2 equiv) were dissolved in toluene, and then stirred at about 110° C. for about 12 hours in a nitrogen atmosphere. The stirred mixture was cooled and then washed three times with ethyl acetate and water to obtain an organic layer. The obtained organic layer was dried over MgSO₄, and then dried under reduced pressure to obtain residues. The obtained residues were separated and purified by column chromatography to obtain Intermediate 39-1. (yield: 80%)

### Synthesis of Intermediate 39-2

Intermediate 39-2 was synthesized in the same manner as the synthesis of Intermediate 4-1 except that N-([1,1′-biphenyl]-4-yl)-[1,1′-biphenyl]-3-amine (2 equiv) was utilized instead of bis(4-(tert-butyl)phenyl)amine (2 equiv). (yield: 80%)

### Synthesis of Intermediate 39-3

Intermediate 39-3 was synthesized in the same manner as the synthesis of Intermediate 4-2 except that Intermediate 39-2 was utilized instead of Intermediate 4-1 and 3,6-di-tert-butyl-1,8-diphenyl-9H-carbazole was utilized instead of 1,8-diphenyl-9H-carbazole. (yield: 20%)

### Synthesis of Compound 39

Compound 39 was synthesized in the same method as the synthesis of Compound 4 except that Intermediate 39-3 was utilized instead of Intermediate 4-2. (yield: 10%)

### (5) Synthesis of Compound 60

Compound 60 may be synthesized by, for example, the steps (tasks) shown in Reaction Scheme 5 below:

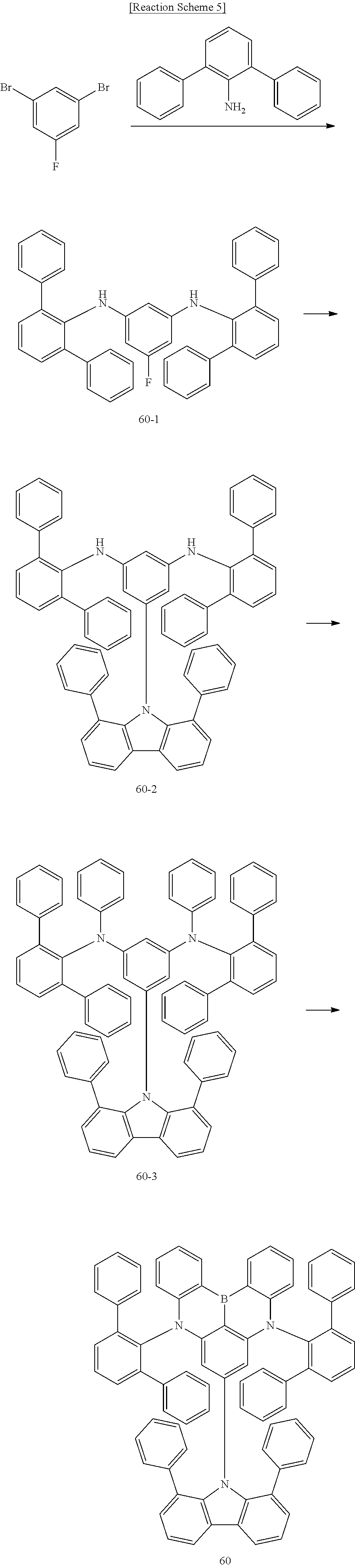

### Synthesis of Intermediate 60-1

Intermediate 60-1 was synthesized in the same manner as the synthesis of Intermediate 4-1 except that [1,1′:3′,1″-terphenyl]-2′-amine was utilized instead of bis(4-(tert-butyl)phenyl)amine. (yield: 70%)

### Synthesis of Intermediate 60-2

Intermediate 60-2 was synthesized in the same manner as the synthesis of Intermediate 4-2 except that Intermediate 60-1 was utilized instead of Intermediate 4-1. (yield: 15%)

### Synthesis of Intermediate 60-3

Intermediate 60-2 (1 equiv), iodobenzene (10 equiv), copper iodide (1 equiv), and potassium carbonate (10 equiv) were stirred at about 190° C. for about 3 days in a nitrogen atmosphere. The stirred mixture was cooled and then washed three times with ethyl acetate and water to obtain an organic layer. The obtained organic layer was dried over MgSO₄, and then dried under reduced pressure to obtain residues. The obtained residues were separated and purified by column chromatography to obtain Intermediate 60-3. (yield: 60%)

### Synthesis of Compound 60

Compound 60 was synthesized in the same manner as the synthesis of Compound 4 except that Intermediate 60-3 was utilized instead of Intermediate 4-2. (yield: 13%)

Results of 1H NMR and MS/FAB of Compounds 4, 6, 12, 39, and 60 synthesized above are shown in Table 1 below:

TABLE 1

| | | MS/FAB | |
|---|---|---|---|
| | | Calculated | Measured |
| Compound | H NMR (δ) | value | value |
| 4 | 1H-NMR (400 MHz, CDCI3): 8.83 | 961.55 | 961.53 |
| | (d, 2H), 8.29 (d, 2H), | | |
| | 7.76-7.48 (m, 17H), | | |
| | 7.24-7.17 (m, 9H), | | |
| | 7.03 (ss, 2H) 1.33 | | |
| | (s, 18H), 1.32 (s, 18H). | | |
| 6 | 1H-NMR (400 MHz, CDCI3): | 1041.43 | 1041.42 |
| | 8.75 (d, 2H), 8.30 (d, 2H), | | |
| | 7.90-7.71 (m, 12H), | | |
| | 7.69-7.31 (m, 19H), 7.27-7.10 | | |
| | (m, 15H), 6.83 (s, 2H). | | |
| 12 | 1H-NMR (400 MHz, CDCI3): | 917.32 | 917.31 |
| | 8.87 (s, 2H), 8.23 (d, 2H), | | |
| | 7.88-7.56 (m, 14H), | | |
| | 7.53-7.28 (m, 10H), 7.27-7.11 | | |
| | (m, 12H), 6.99 (s, 2H). | | |
| 39 | 1H-NMR (400 MHz, CDCI3): 9.05 | 1153.55 | 1153.54 |
| | (d, 2H), 8.27 (s, 2H), 7.79-7.49 | | |
| | (m, 16H), 7.47-7.23 (m, 18H), | | |
| | 7.23-7.10 (m, 10H), | | |
| | 7.01 (ss, 2H), 1.33 (s, 18H). | | |
| 60 | 1H-NMR (400 MHz, CDCI3): | 1041.43 | 1043.41 |
| | 8.96 (d, 2H), 8.23 (d, 2H), | | |
| | 7.80-7.62 (m, 18H), | | |
| | 7.62-7.37 (m, 19H), 7.35-7.13 | | |
| | (m, 9H), 6.97 (s, 2H). | | |

### 2. Manufacture and Evaluation of Light Emitting Element

### Manufacture of Light Emitting Element

An ITO glass substrate of about 15 Ω/cm² (with the ITO layer being about 1,200 Å in thickness) made by Corning Co. was cut to a size of 50 mm×50 mm×0.7 mm, cleansed by ultrasonic waves utilizing isopropyl alcohol and pure water for about five minutes each, and then irradiated with ultraviolet rays for about 30 minutes and exposed to ozone, and cleansed to produce a first electrode.

A compound NPD was deposited in vacuum on the upper portion of the produced first electrode to form a 300 Å-thick hole injection layer, and then G-1 was deposited in vacuum on the hole injection layer to form a 200 Å-thick hole transport layer.

CzSi as a hole transporting compound was deposited in vacuum on the upper portion of the produced hole transport layer to form a 100 Å-thick emission-auxiliary layer.

mCP and a respective Example Compound, mCP, or a respective Comparative Example Compound were co-deposited on the emission-auxiliary layer at a weight ratio of 99:1 to form a 200 Å-thick emission layer.

TSP01 was formed on the upper portion of the emission layer to a thickness of about 200 Å, and then TPBI was deposited to form a 300 Å-thick electron transport layer.

LiF as an alkaline metal halide was deposited on the upper portion of the electron transport layer to a thickness of about 10 Å, and aluminum (AI) was deposited in vacuum to a thickness of about 3,000 Å to form a second electrode, thereby manufacturing a light emitting element.

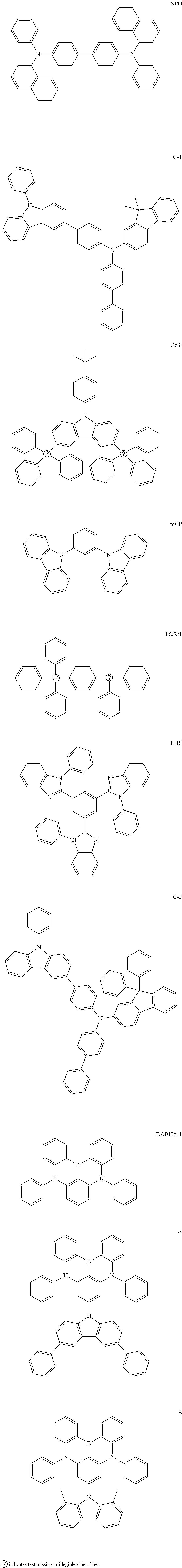

### Evaluation of Light Emitting Element Characteristics

The evaluation results of the light emitting elements of Examples and Comparative Examples are listed in Table 2. Driving voltage (V), luminous efficiency (Cd/A), maximum quantum efficiency (%), and luminous color of the manufactured light emitting elements are listed in comparison in Table 2.

TABLE 2

| | | | | Lumi- | Maximum | |
|---|---|---|---|---|---|---|
| | Hole | | | nous | external | |
| | transport | Dopant in | Driving | effici- | quantum | Lumi- |
| | layer | emission | voltage | ency | efficiency | nous |
| | material | layer | (V) | (Cd/A) | (%) | color |
| Example 1 | G-1 | Compound | 44.6 | 24.8 | 24.4 | Blue |
| Example 2 | G-1 | Compound | 64.7 | 24.3 | 23.5 | Blue |
| Example 3 | G-1 | Compound | 4.6 | 25.0 | 25.0 | Blue |
| | | 12 | | | | |
| Example 4 | G-1 | Compound | 4.7 | 24.4 | 23.7 | Blue |
| | | 39 | | | | |
| Example 5 | G-1 | Compound | 4.7 | 24.6 | 24.1 | Blue |
| | | 60 | | | | |
| Comparative | G-1 | DABNA-1 | 5.7 | 16.3 | 15.7 | Blue |
| Example 1 | | | | | | |
| Comparative | G-1 | Compound | A5.4 | 18.0 | 17.6 | Blue |
| Example 2 | | | | | | |
| Comparative | G-1 | Compound | B5.4 | 18.3 | 18.0 | Blue |
| Example 3 | | | | | | |
| Example 6 | G-2 | Compound | 44.6 | 25.0 | 24.7 | Blue |
| Example 7 | G-2 | Compound | 64.6 | 24.8 | 24.0 | Blue |
| Example 8 | G-2 | Compound | 4.6 | 25.3 | 24.9 | Blue |
| | | 12 | | | | |
| Example 9 | G-2 | Compound | 4.7 | 24.5 | 23.7 | Blue |
| | | 39 | | | | |
| Example 10 | G-2 | Compound | 4.7 | 24.5 | 24.2 | Blue |
| | | 60 | | | | |
| Cornparative | G-2 | DABNA-1 | 5.6 | 16.0 | 15.4 | Blue |
| Example 4 | | | | | | |
| Cornparative | G-2 | Compound | A5.4 | 18.2 | 17.7 | Blue |
| Example 5 | | | | | | |
| Cornparative | G-2 | Compound | B5.4 | 18.7 | 18.2 | Blue |
| Example 6 | | | | | | |

Referring to the results shown in Table 2, it may be seen that Examples of the light emitting elements utilizing the polycyclic compound according to embodiments of the present disclosure as a dopant material in the emission layer exhibit low driving voltage, high luminous efficiency, and suitable (e.g., excellent) maximum external quantum efficiency.

That is, referring to Table 2, it may be seen that the light emitting elements of Examples 1 to 10, including Compounds 4, 6, 12, 39, and 60 respectively, each exhibit low driving voltage, high luminous efficiency, and excellent maximum external quantum efficiency compared to the light emitting elements of Comparative Examples 1 to 6, including DABNA-1, Compound A, or Compound B, respectively.

Example Compounds according to embodiments of the present disclosure are different from DABNA-1 in that a carbazole group having a high steric hindrance is bonded to boron at the para-position in a scaffold. Example Compounds in which the carbazole group having a high steric hindrance is bonded to the boron at the para-position in the scaffold may have a more stable molecular structure compared to DABNA-1 because the multiple resonance is promoted (e.g., enhanced). In addition, Example Compounds may maintain a stable molecular structure because the carbazole group is substituted at the para-position with a boron atom, which is a highly reactive position, thereby reducing the reactivity of the compound. That is, Example Compounds each have a molecular structure more stable than the DABNA-1 compound has, and as a result, it may be confirmed that the light emitting elements of the Examples each exhibit low driving voltage, high luminous efficiency, and excellent maximum external quantum efficiency compared to Comparative Example 1.

For Compound A, the phenyl groups are substituted at the para-position with a nitrogen atom in a carbazole group bonded to a scaffold, and for Example Compounds, the phenyl groups are substituted at the ortho-position with a nitrogen atom in a carbazole group bonded to a scaffold. That is, for Example Compounds, the phenyl groups are substituted at the position closer to the boron atom contained in the molecule compared to Compound A, and thus may better protect the vacant p-orbital of the boron atom contained in the molecule. Therefore, Example Compounds may have a molecular structure more stable than Compound A has, and as a result, it may be confirmed that the light emitting elements of the Examples each exhibit low driving voltage, high luminous efficiency, and excellent maximum external quantum efficiency compared to the light emitting elements of Comparative Examples 2 and 5.

For Compound B, the methyl groups are substituted at the ortho-position with a nitrogen atom in a carbazole group bonded to a scaffold, and for Example Compounds, the phenyl groups are substituted at the ortho-position with a nitrogen atom in a carbazole group bonded to a scaffold. That is, Example Compounds have a substituent larger than Compound B has, and thus may better protect the vacant p-orbital of the boron atom contained in the molecule. Therefore, Example Compounds may have a molecular structure more stable than Compound B has, and as a result, it may be confirmed that the light emitting elements of the Examples each exhibit low driving voltage, high luminous efficiency, and excellent maximum external quantum efficiency compared to the light emitting elements of Comparative Examples 3 and 6.

As described above, Examples 1 to 10 show the results of improvement in all of the driving voltage, the luminous efficiency and the quantum efficiency compared to Comparative Examples 1 to 6. That is, all of the driving voltage, the luminous efficiency, and the quantum efficiency of the light emitting element of an embodiment may be improved by utilizing the polycyclic compound of an embodiment having a structure in which phenyl groups having a high steric hindrance are substituted at the ortho-position with the nitrogen atom in the carbazole group substituted at the scaffold.

An embodiment may provide a light emitting element having improved luminous efficiency by including, in the emission layer, the polycyclic compound having a DABNA structure in which a substituent having a high steric hindrance is substituted at the core and thus induce a high electron density in the core and promote multiple resonance.

The light emitting element of an embodiment may include the polycyclic compound of an embodiment in an emission layer, thereby achieving high luminous efficiency.

Expressions such as “at least one of” or “at least one selected from” when preceding a list of elements, modify the entire list of elements and do not modify the individual elements of the list. Further, the use of “may” when describing embodiments of the present disclosure refers to “one or more embodiments of the present disclosure.”

Although the present disclosure has been described with reference to an example embodiment of the present disclosure, it will be understood that the present disclosure should not be limited to these embodiments but various changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode and comprising a polycyclic compound represented by Formula 1,
wherein the first electrode and the second electrode each independently comprise Ag, Mg, Cu, Al, Pt, Pd, Au, Ni, Nd, Ir, Cr, Li, Ca, LiF/Ca, LiF/Al, Mo, Ti, W, In, Sn, Zn, a compound of two or more thereof, a mixture of two or more thereof, or an oxide thereof: 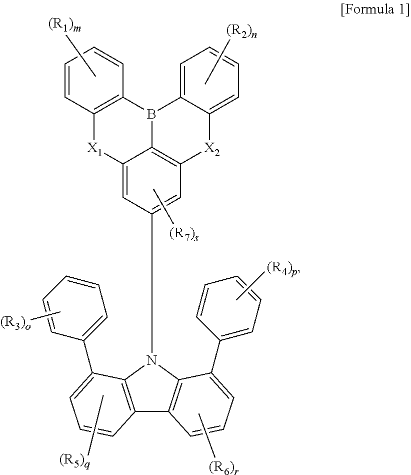
and
wherein, in Formula 1,
m and n are each independently an integer of 0 to 4,
and p are each independently an integer of 0 to 5,
q and r are each independently an integer of 0 to 3,
s is an integer of 0 to 2,
R₁ to R₇ are each independently a hydrogen atom, a deuterium atom, a halogen atom, a cyano group, a nitro group, a hydroxy group, a substituted or unsubstituted alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted oxy group, a substituted or unsubstituted thio group, or a substituted or unsubstituted amine group, and/or bonded to an adjacent group to form a ring,
X₁ and X₂ are each independently NRₐ, O, S, or Se, and
Rₐ is a substituted or unsubstituted aryl group having 6 to 12 ring-forming carbon atoms, or a substituted or unsubstituted heteroaryl group having 2 to 15 ring-forming carbon atoms, and/or bonded to an adjacent group to form a ring.

2. The light emitting element of claim 1, wherein in Formula 1, X₁ and X₂ are the same.

3. The light emitting element of claim 2, wherein the polycyclic compound represented by Formula 1 is represented by any one selected among Formula 2A to Formula 2D: 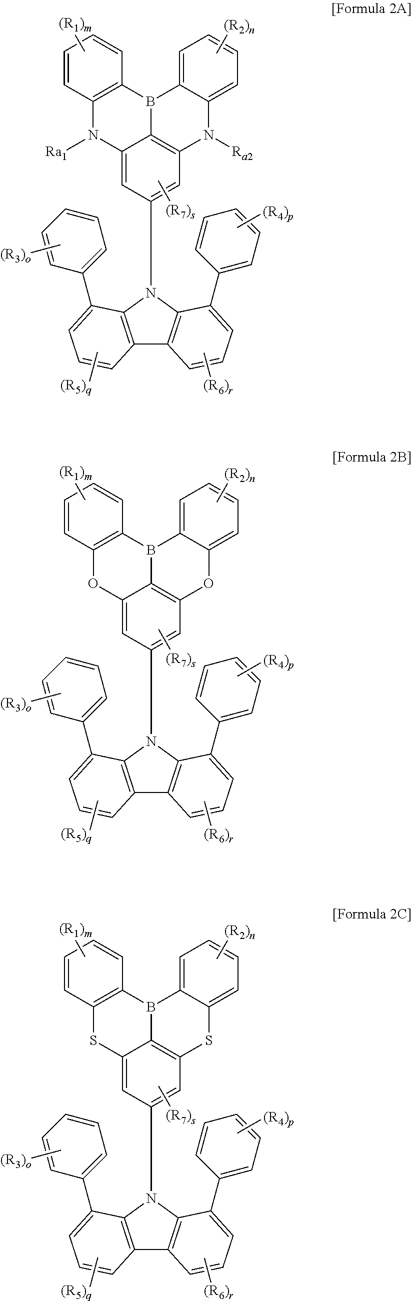 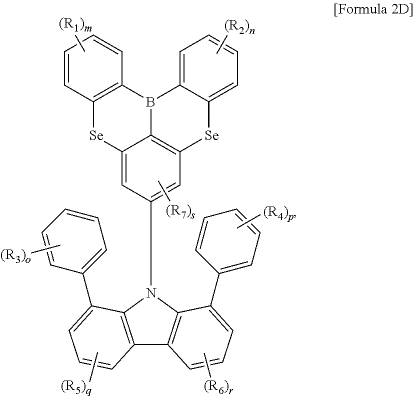
and
wherein in Formula 2A, Rₐ₁ and Rₐ₂ are each independently a substituted or unsubstituted phenyl group, a substituted or unsubstituted biphenyl group, a substituted or unsubstituted carbazole group, or a substituted or unsubstituted furan group, and/or bonded to an adjacent group to form a ring, and
in Formula 2A and Formula 2D, m to s and R₁ to R₇ are the same as respectively defined in connection with Formula 1.

4. The light emitting element of claim 2, wherein the polycyclic compound represented by Formula 2A is represented by any one selected among Formula 2A-1 to Formula 2A-5: 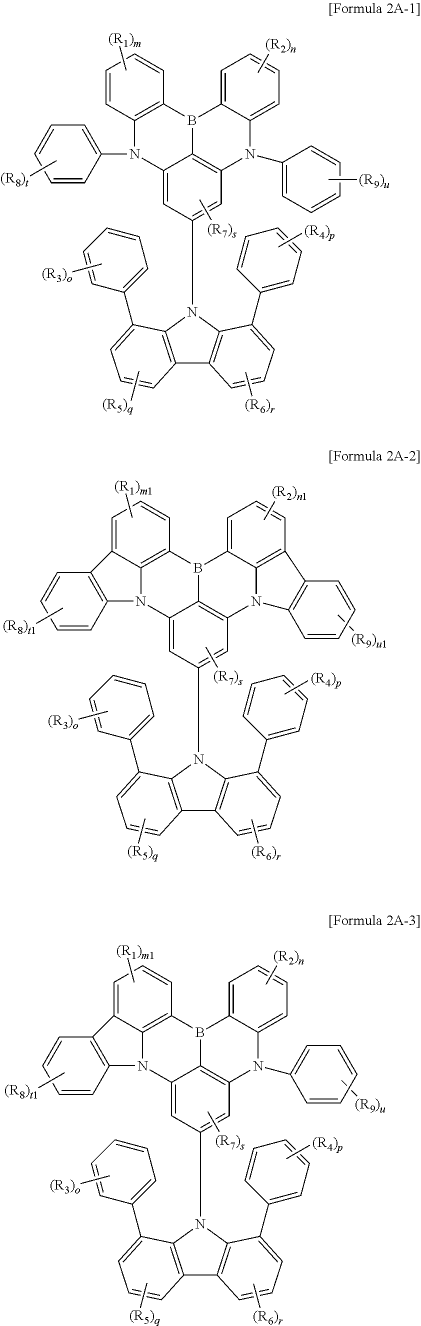 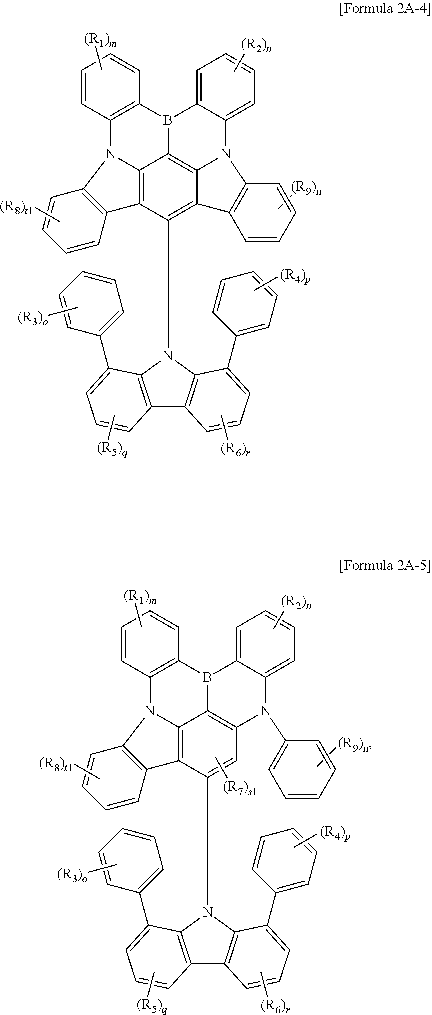
and
wherein in Formulae 2A-1 to 2A-5,
m1 and n1 are each independently an integer of 0 to 3,
t and u are each independently an integer of 0 to 5,
t1 and u1 are each independently an integer of 0 to 4,
s1 is 0 or 1,
R₈ and R₉ are each independently a substituted or unsubstituted methyl group, a substituted or unsubstituted t-butyl group, a substituted or unsubstituted phenyl group, a substituted or unsubstituted oxy group, a substituted or unsubstituted thio group, or a substituted or unsubstituted amine group, and/or bonded to an adjacent group to form a ring, and
R₁ to R₇, and m to s are the same as respectively defined in connection with Formula 1.

5. The light emitting element of claim 4, wherein in Formulae 2A-1 to 2A-5, R₈ and R₉ are each independently represented by any one selected among moieties represented by Formulae 2A-1 to 2A-17:

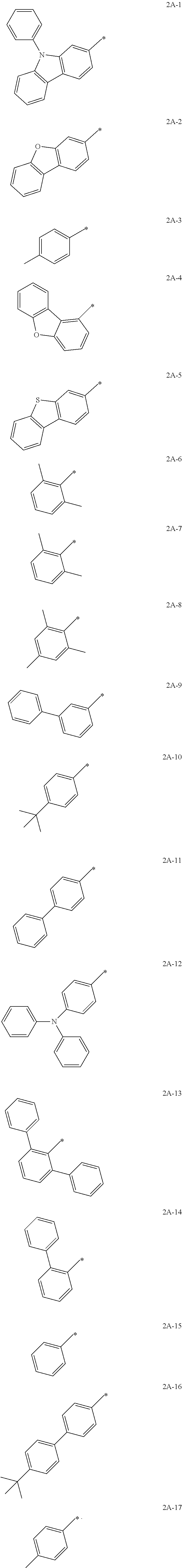

6. The light emitting element of claim 1, wherein in Formula 1, X₁ and X₂ are different from each other.

7. The light emitting element of claim 6, wherein the polycyclic compound represented by Formula 1 is represented by Formula 3A: 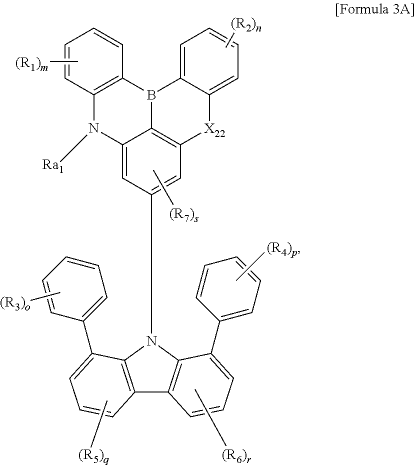
and
wherein, in Formula 3A,
X₂₂ is O, S or Se,
Rₐ₁ is a substituted or unsubstituted phenyl group, a substituted or unsubstituted biphenyl group, a substituted or unsubstituted carbazole group, or a substituted or unsubstituted furan group, and/or bonded to an adjacent group to form a ring, and
R₁ to R₇, and m to s are the same as respectively defined in connection with Formula 1.

8. The light emitting element of claim 7, wherein the polycyclic compound represented by Formula 3A is represented by any one selected among Formula 3A-1 to Formula 3A-3: 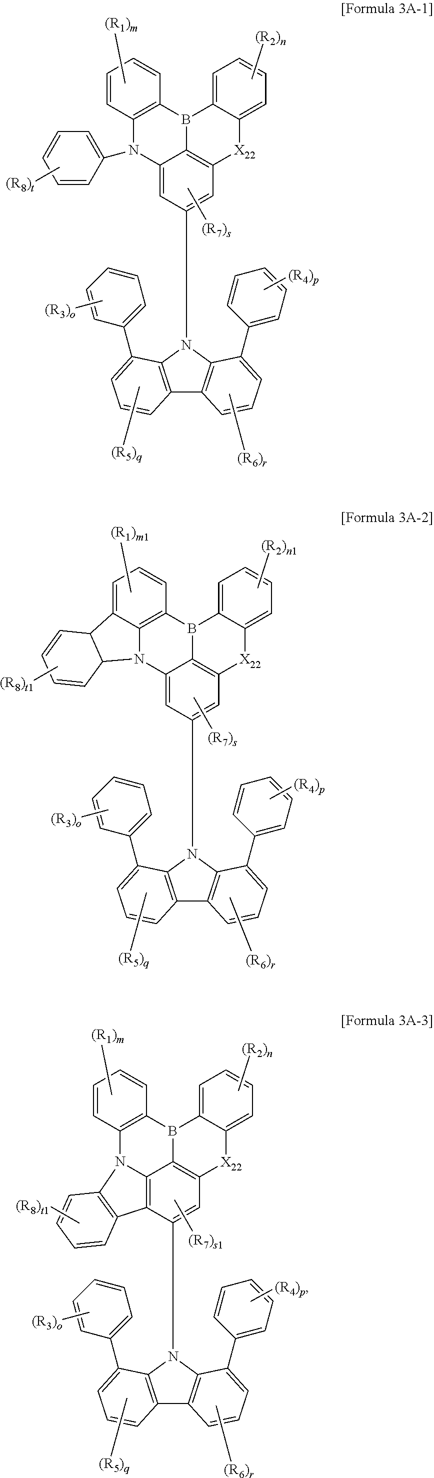
and
wherein, in Formula 3A-1 to Formula 3A-3,
t is an integer of 0 to 5,
s1 is 0 or 1,
m1 is an integer of 0 to 3,
t1 is an integer of 0 to 4,
R₈ is a substituted or unsubstituted methyl group, a substituted or unsubstituted t-butyl group, a substituted or unsubstituted phenyl group, a substituted or unsubstituted oxy group, a substituted or unsubstituted thio group, or a substituted or unsubstituted amine group, and/or bonded to an adjacent group to form a ring,
X₂₂ is the same as defined in connection with Formula 3A, and
R₁ to R₇, and m to s are the same as respectively defined in connection with Formula 1.

9. The light emitting element of claim 8, wherein, in Formula 3A-1 to Formula 3A-3, R₈ is represented by any one selected among moieties represented by Formulae 2A-1 to 2A-17:

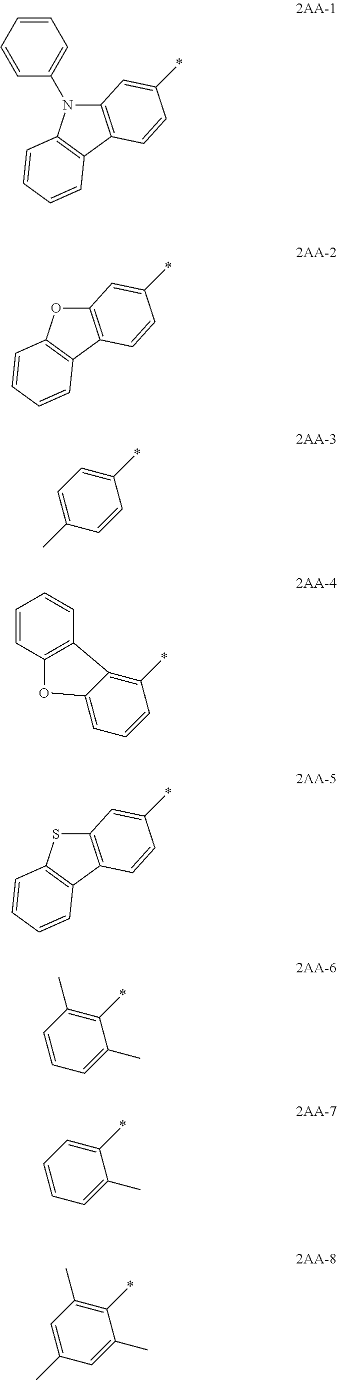

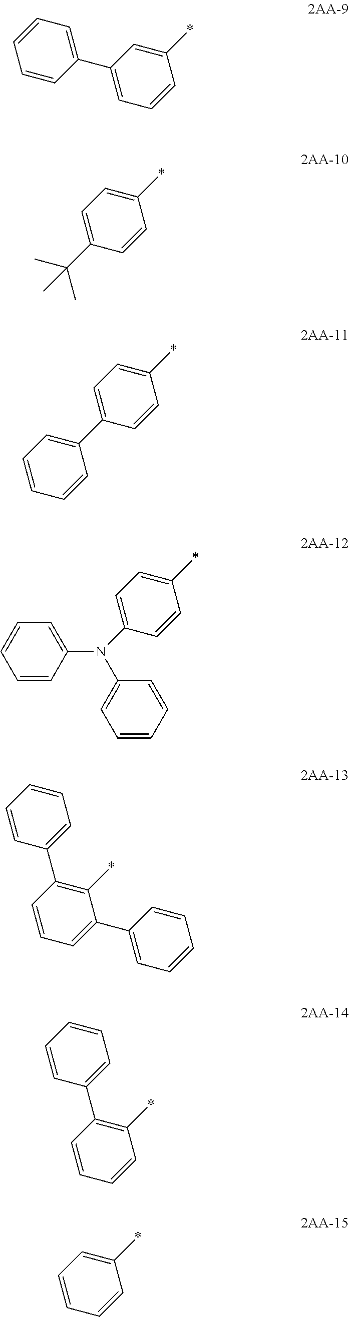

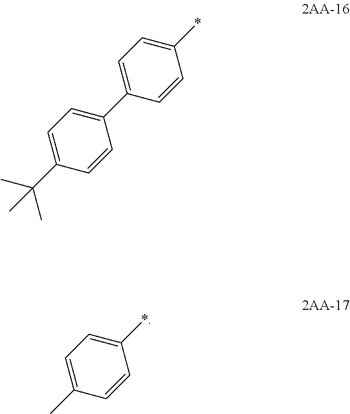

10. The light emitting element of claim 1, wherein the polycyclic compound represented by Formula 1 is represented by Formula 4-1 or Formula 4-2: 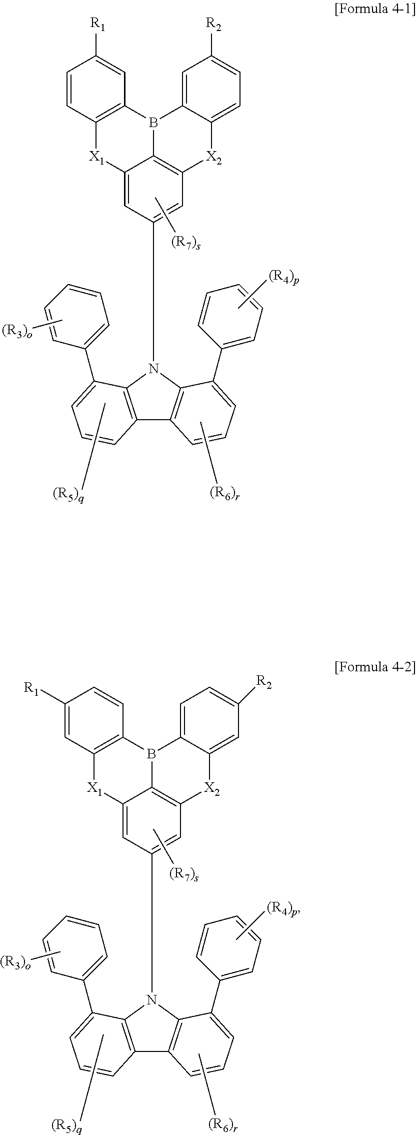
and
wherein, in Formulae 4-1 and Formula 4-2,
R₁ and R₂ are each independently a substituted or unsubstituted t-butyl group, a substituted or unsubstituted phenyl group, a substituted or unsubstituted thio group, a substituted or unsubstituted amine group, or a substituted or unsubstituted oxy group, and/or bonded to an adjacent group to form a ring, and
to s, X₁, X₂, and R₃ to R₇ are the same as respectively defined in connection with Formula 1.

11. The light emitting element of claim 10, wherein the polycyclic compound represented by Formula 4-1 is represented by any one selected among Formula 4A to Formula 4C: 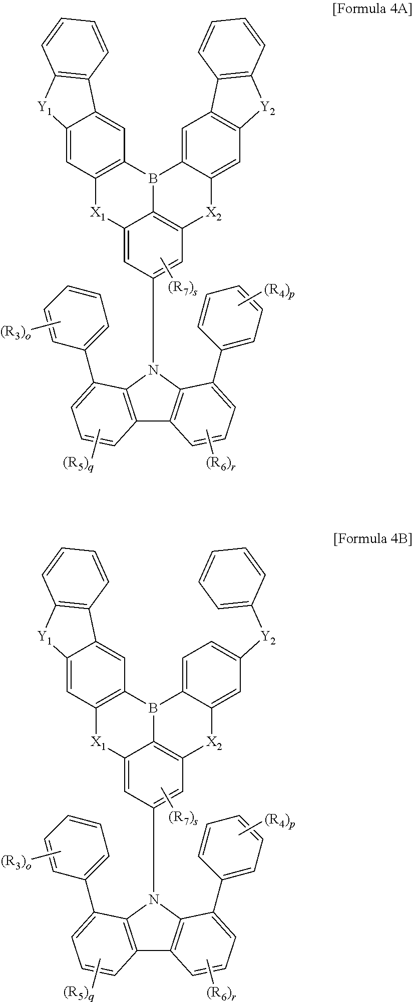 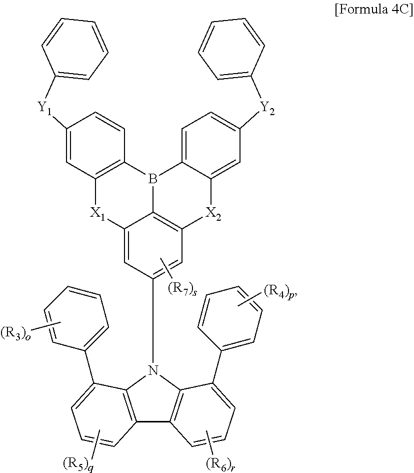
and
wherein, in Formulae 4A to 4C,
Y₁ and Y₂ are each independently O, S, or NRₑ,
Rₑ is a substituted or unsubstituted phenyl group, and
X₁, X₂, R₃ to R₇, and o to s are the same as respectively defined in connection with Formula 1.

12. The light emitting element of claim 1, wherein the polycyclic compound represented by Formula 1 is represented by Formula 5: 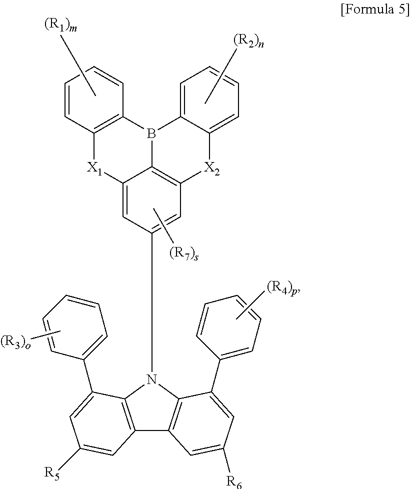
and
wherein, in Formula 5,
R₅ and R₆ are each independently an unsubstituted methyl group, an unsubstituted t-butyl group, or a cyano group, and
m to p, s, X₁, X₂, R₁ to R₄, and R₇ are the same as respectively defined in connection with Formula 1.

13. The light emitting element of claim 1, wherein the polycyclic compound represented b Formula 1 is represented by Formula 6-1 or Formula 6-2: 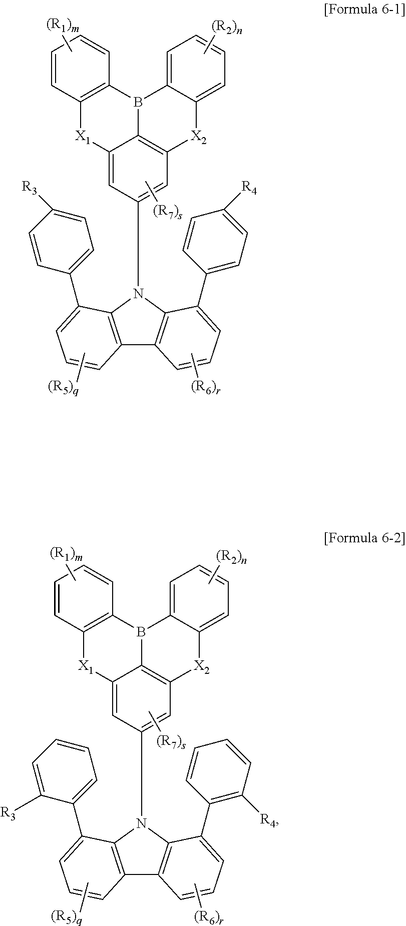
and
wherein, in Formula 6-1 and Formula 6-2,
R₃ and R₄ are each independently a substituted or unsubstituted t-butyl group, a fluorine group, or a substituted or unsubstituted oxy group, the substituted or unsubstituted oxy group being optionally bonded to an adjacent group to form a ring, and
m, n, q to s, X₁, X₂, R₁, R₂, and R₅ to R₇ are the same as respectively defined in connection with Formula 1.

14. The light emitting element of claim 1, wherein the emission layer is to emit blue light.

15. The light emitting element of claim 1, wherein
the emission layer comprises a dopant and a host, and
the dopant comprises the polycyclic compound.

16. The light emitting element of claim 1, wherein the polycyclic compound is to emit thermally activated delayed fluorescence.

17. The light emitting element of claim 1, further comprising a hole transport region between the first electrode and the emission layer, and the hole transport region comprises Compound G-1 or Compound G-2:

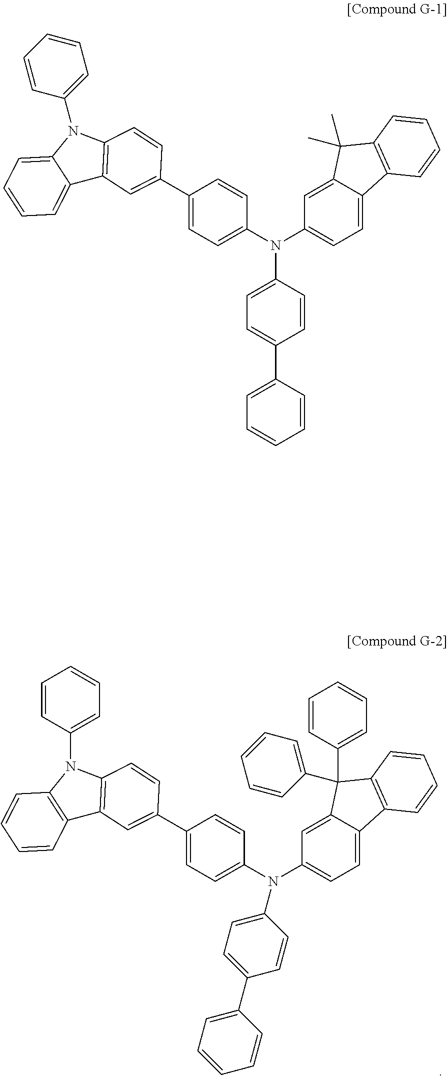 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

18. The light emitting element of claim 1, wherein the emission layer comprises at least one selected among compounds of Compound Group 1:

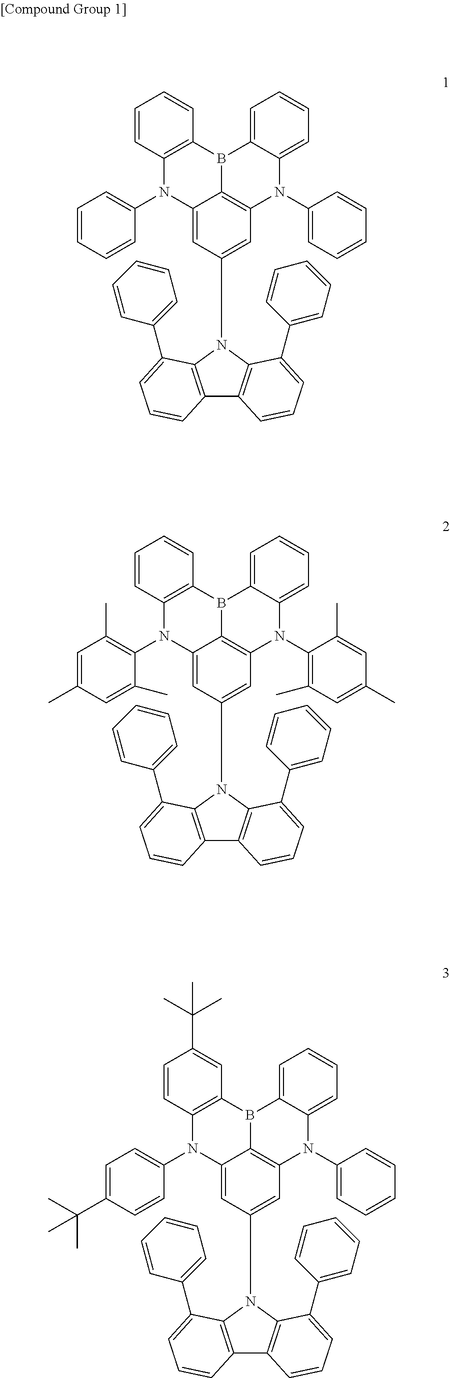

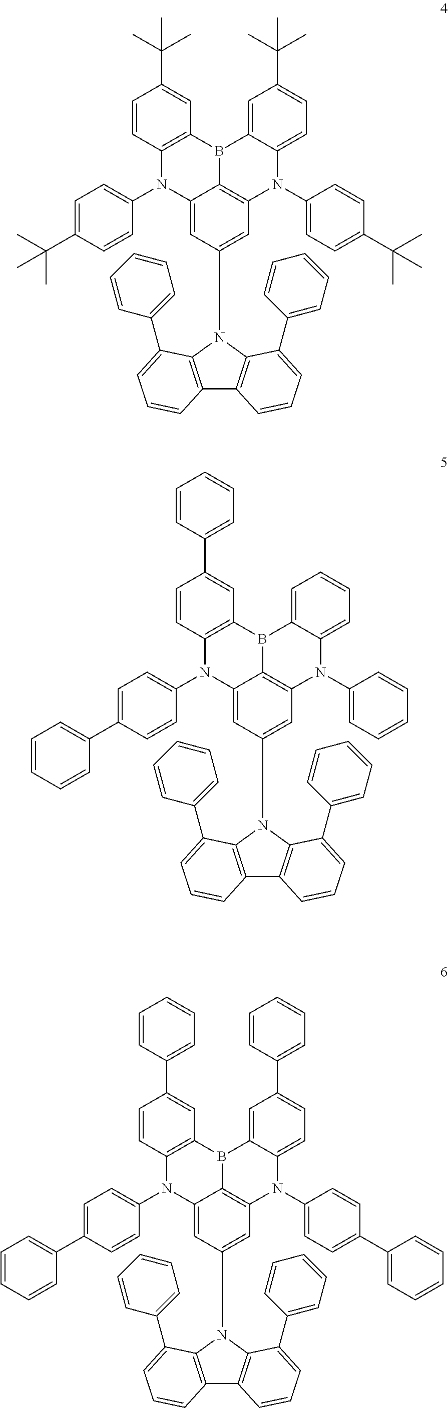 [SMILES: CC(C)(C)c1ccc(N2c3ccc(C(C)(C)C)cc3B3c4cc(C(C)(C)C)ccc4N(c4ccc(C(C)(C)C)cc4)c4cc(-n5c6c(-c7ccccc7)cccc6c6cccc(-c7ccccc7)c65)cc2c43)cc1 ; c1ccc(-c2ccc(N3c4ccc(-c5ccccc5)cc4B4c5ccccc5N(c5ccccc5)c5cc(-n6c7c(-c8ccccc8)cccc7c7cccc(-c8ccccc8)c76)cc3c54)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7c(-c8ccccc8)cccc7c7cccc(-c8ccccc8)c76)cc3c54)cc2)cc1]

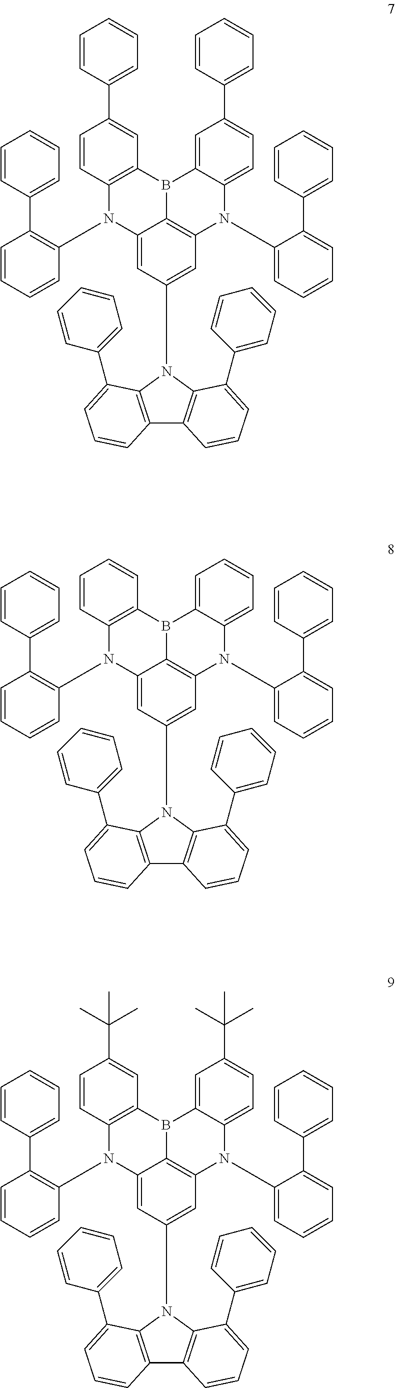 [SMILES: c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)N3c2ccccc2-c2ccccc2)cc1 ; c1ccc(-c2ccccc2N2c3ccccc3B3c4ccccc4N(c4ccccc4-c4ccccc4)c4cc(-n5c6c(-c7ccccc7)cccc6c6cccc(-c7ccccc7)c65)cc2c43)cc1 ; CC(C)(C)c1ccc2c(c1)B1c3cc(C(C)(C)C)ccc3N(c3ccccc3-c3ccccc3)c3cc(-n4c5c(-c6ccccc6)cccc5c5cccc(-c6ccccc6)c54)cc(c31)N2c1ccccc1-c1ccccc1]

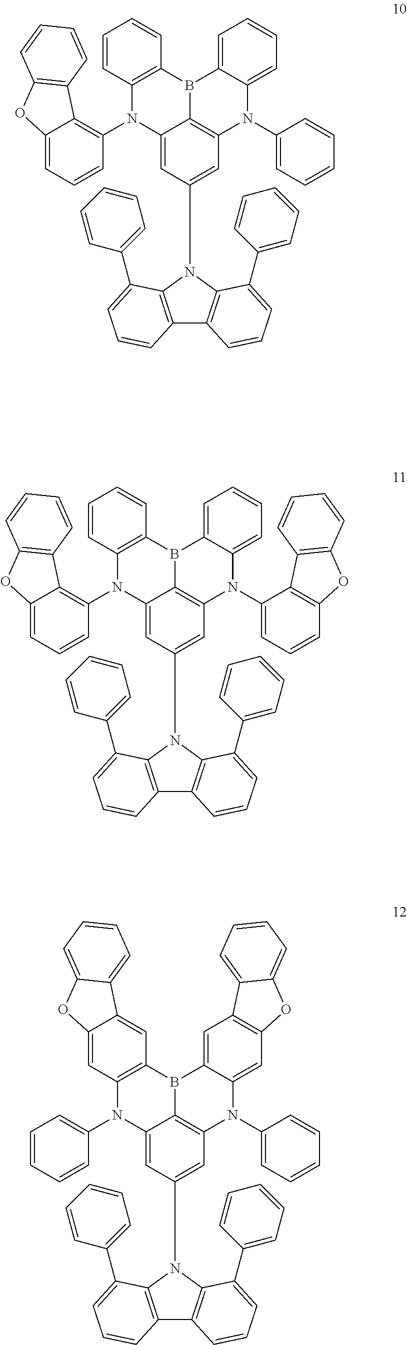 [SMILES: c1ccc(-c2cccc3c4cccc(-c5ccccc5)c4n(-c4cc5c6c(c4)N(c4cccc7oc8ccccc8c47)c4ccccc4B6c4ccccc4N5c4ccccc4)c23)cc1 ; c1ccc(-c2cccc3c4cccc(-c5ccccc5)c4n(-c4cc5c6c(c4)N(c4cccc7oc8ccccc8c47)c4ccccc4B6c4ccccc4N5c4cccc5oc6ccccc6c45)c23)cc1 ; c1ccc(-c2cccc3c4cccc(-c5ccccc5)c4n(-c4cc5c6c(c4)N(c4ccccc4)c4cc7oc8ccccc8c7cc4B6c4cc6c(cc4N5c4ccccc4)oc4ccccc46)c23)cc1]

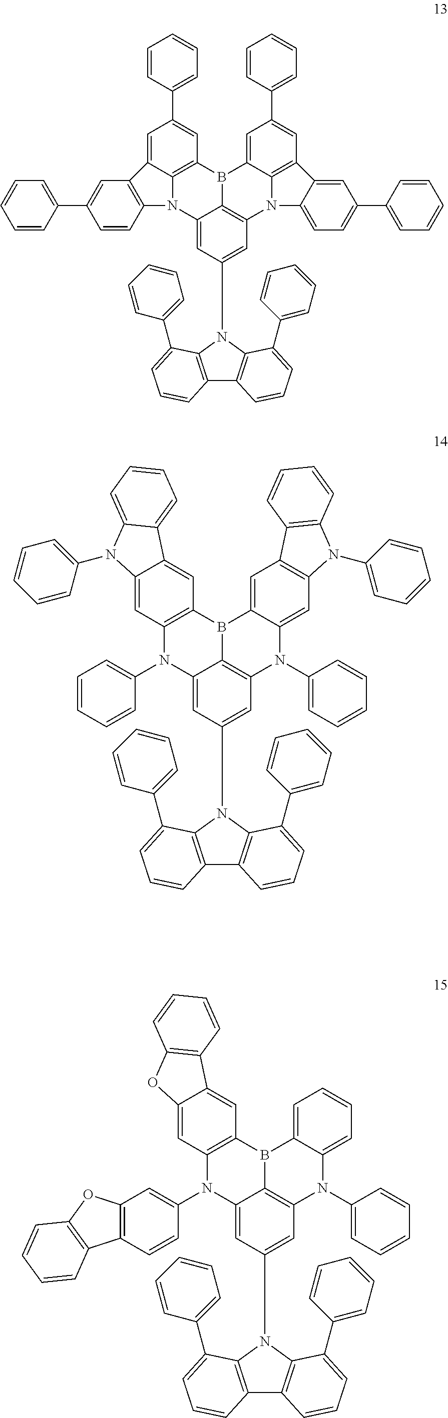 [SMILES: c1ccc(-c2ccc3c(c2)c2cc(-c4ccccc4)cc4c2n3-c2cc(-n3c5c(-c6ccccc6)cccc5c5cccc(-c6ccccc6)c53)cc3c2B4c2cc(-c4ccccc4)cc4c5cc(-c6ccccc6)ccc5n-3c24)cc1 ; c1ccc(-c2cccc3c4cccc(-c5ccccc5)c4n(-c4cc5c6c(c4)N(c4ccccc4)c4cc7c(cc4B6c4cc6c8ccccc8n(-c8ccccc8)c6cc4N5c4ccccc4)c4ccccc4n7-c4ccccc4)c23)cc1 ; c1ccc(-c2cccc3c4cccc(-c5ccccc5)c4n(-c4cc5c6c(c4)N(c4ccc7c(c4)oc4ccccc47)c4cc7oc8ccccc8c7cc4B6c4ccccc4N5c4ccccc4)c23)cc1]

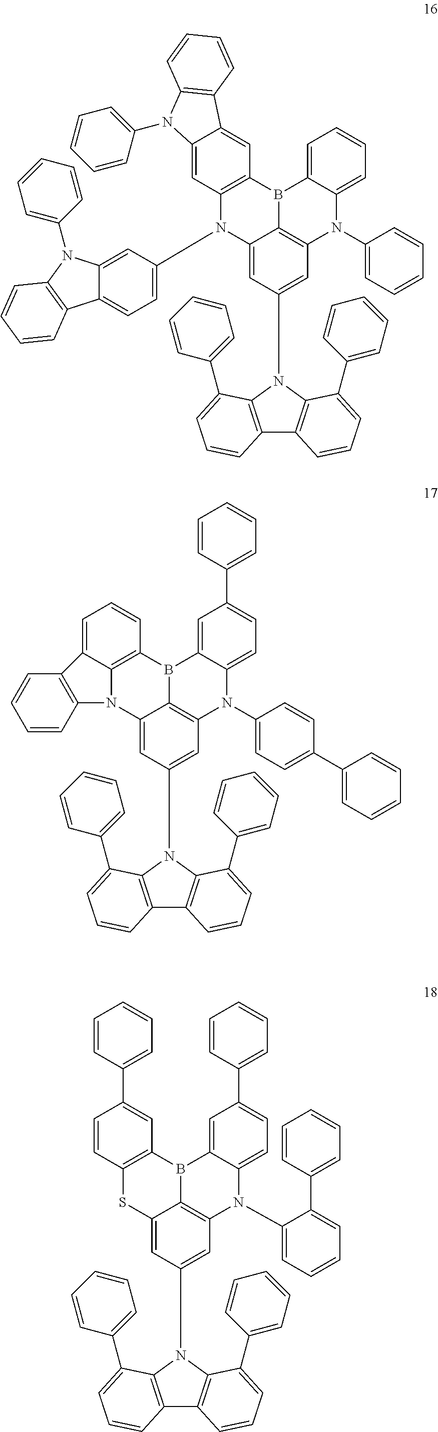 [SMILES: c1ccc(-c2cccc3c4cccc(-c5ccccc5)c4n(-c4cc5c6c(c4)N(c4ccc7c8ccccc8n(-c8ccccc8)c7c4)c4cc7c(cc4B6c4ccccc4N5c4ccccc4)c4ccccc4n7-c4ccccc4)c23)cc1 ; c1ccc(-c2ccc(N3c4ccc(-c5ccccc5)cc4B4c5c3cc(-n3c6c(-c7ccccc7)cccc6c6cccc(-c7ccccc7)c63)cc5-n3c5ccccc5c5cccc4c53)cc2)cc1 ; c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)S3)cc1]

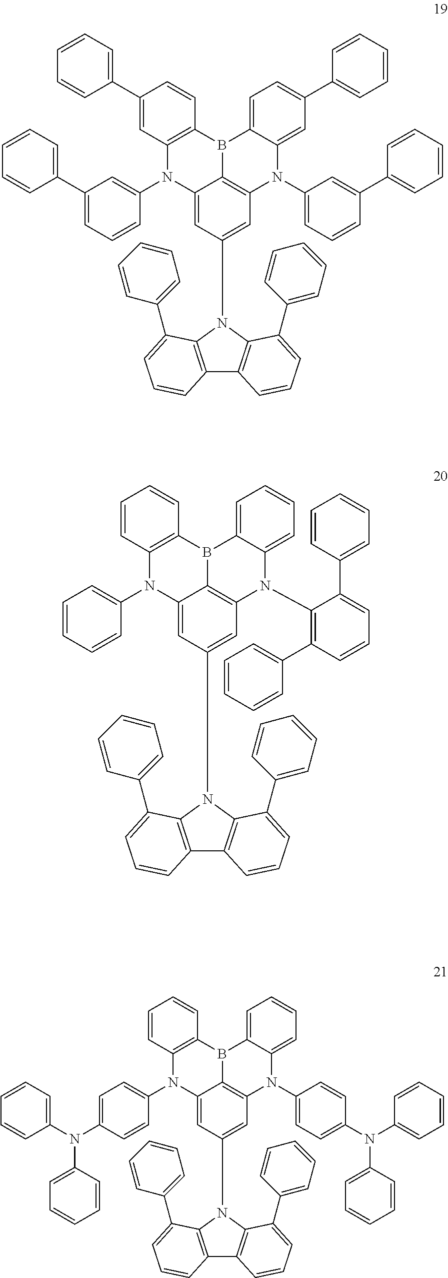 [SMILES: c1ccc(-c2cccc(N3c4cc(-c5ccccc5)ccc4B4c5ccc(-c6ccccc6)cc5N(c5cccc(-c6ccccc6)c5)c5cc(-n6c7c(-c8ccccc8)cccc7c7cccc(-c8ccccc8)c76)cc3c54)c2)cc1 ; c1ccc(-c2cccc(-c3ccccc3)c2N2c3ccccc3B3c4ccccc4N(c4ccccc4)c4cc(-n5c6c(-c7ccccc7)cccc6c6cccc(-c7ccccc7)c65)cc2c43)cc1 ; c1ccc(-c2cccc3c4cccc(-c5ccccc5)c4n(-c4cc5c6c(c4)N(c4ccc(N(c7ccccc7)c7ccccc7)cc4)c4ccccc4B6c4ccccc4N5c4ccc(N(c5ccccc5)c5ccccc5)cc4)c23)cc1]

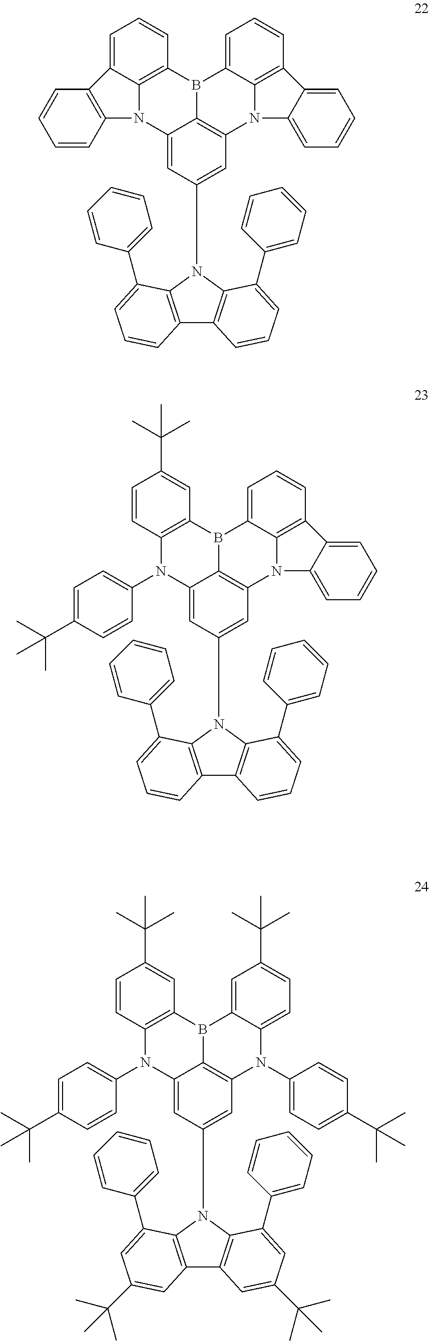 [SMILES: c1ccc(-c2cccc3c4cccc(-c5ccccc5)c4n(-c4cc5c6c(c4)-n4c7ccccc7c7cccc(c74)B6c4cccc6c7ccccc7n-5c46)c23)cc1 ; CC(C)(C)c1ccc(N2c3ccc(C(C)(C)C)cc3B3c4c2cc(-n2c5c(-c6ccccc6)cccc5c5cccc(-c6ccccc6)c52)cc4-n2c4ccccc4c4cccc3c42)cc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6c(-c7ccccc7)cc(C(C)(C)C)cc6c6cc(C(C)(C)C)cc(-c7ccccc7)c65)cc2c43)cc1]

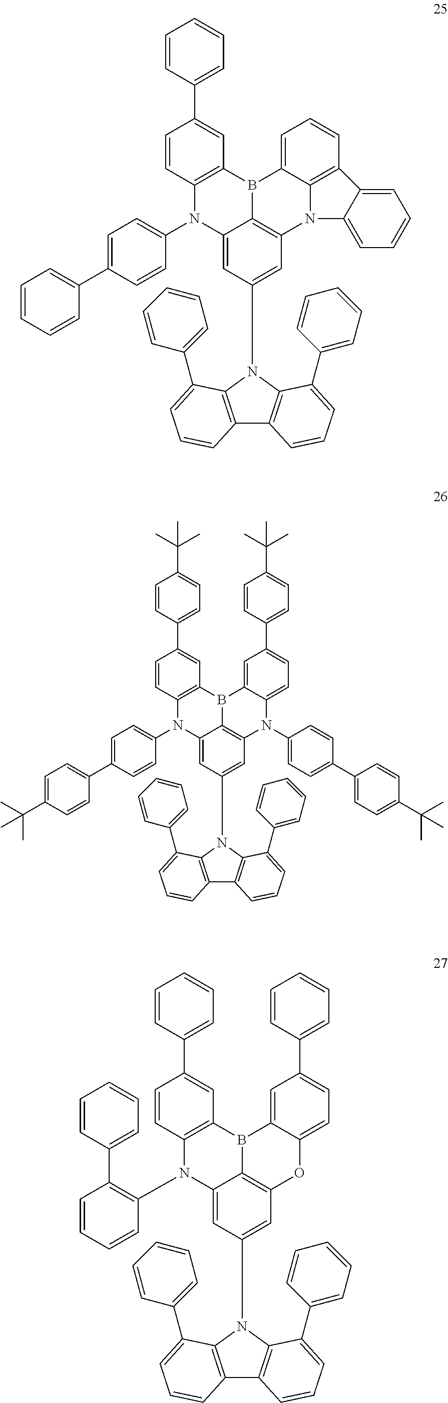 [SMILES: c1ccc(-c2ccc(N3c4ccc(-c5ccccc5)cc4B4c5c3cc(-n3c6c(-c7ccccc7)cccc6c6cccc(-c7ccccc7)c63)cc5-n3c5ccccc5c5cccc4c53)cc2)cc1 ; CC(C)(C)c1ccc(-c2ccc(N3c4ccc(-c5ccc(C(C)(C)C)cc5)cc4B4c5cc(-c6ccc(C(C)(C)C)cc6)ccc5N(c5ccc(-c6ccc(C(C)(C)C)cc6)cc5)c5cc(-n6c7c(-c8ccccc8)cccc7c7cccc(-c8ccccc8)c76)cc3c54)cc2)cc1 ; c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)O3)cc1]

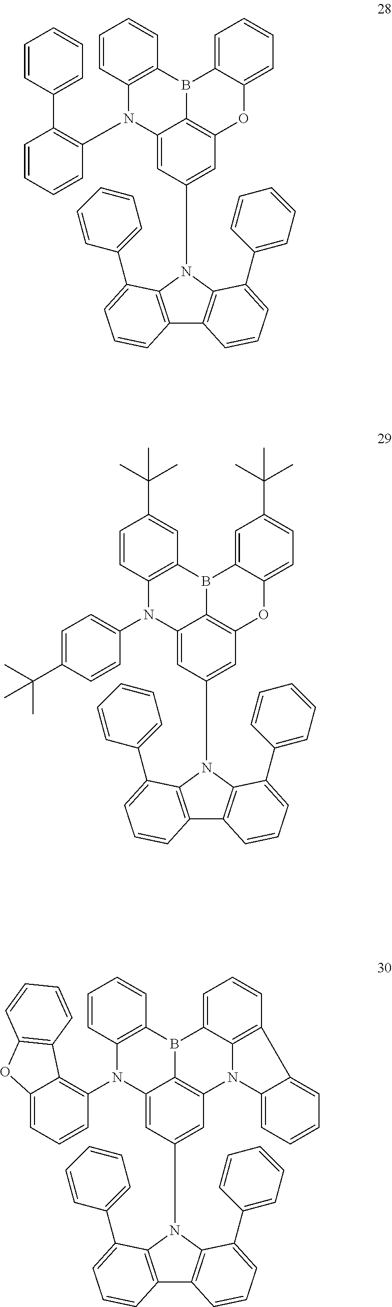 [SMILES: c1ccc(-c2ccccc2N2c3ccccc3B3c4ccccc4Oc4cc(-n5c6c(-c7ccccc7)cccc6c6cccc(-c7ccccc7)c65)cc2c43)cc1 ; CC(C)(C)c1ccc(N2c3ccc(C(C)(C)C)cc3B3c4cc(C(C)(C)C)ccc4Oc4cc(-n5c6c(-c7ccccc7)cccc6c6cccc(-c7ccccc7)c65)cc2c43)cc1 ; c1ccc(-c2cccc3c4cccc(-c5ccccc5)c4n(-c4cc5c6c(c4)-n4c7ccccc7c7cccc(c74)B6c4ccccc4N5c4cccc5oc6ccccc6c45)c23)cc1]

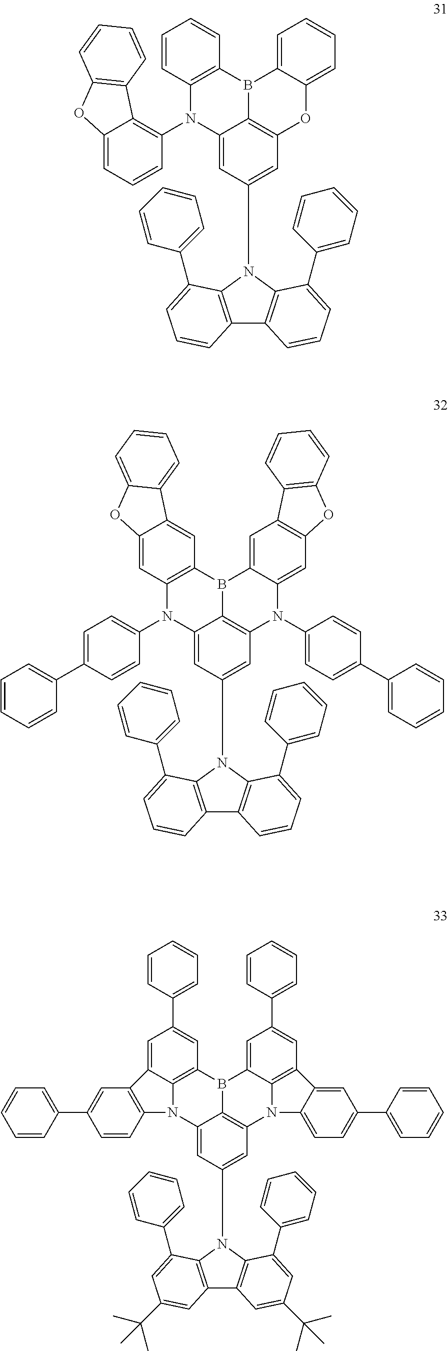 [SMILES: c1ccc(-c2cccc3c4cccc(-c5ccccc5)c4n(-c4cc5c6c(c4)N(c4cccc7oc8ccccc8c47)c4ccccc4B6c4ccccc4O5)c23)cc1 ; c1ccc(-c2ccc(N3c4cc5oc6ccccc6c5cc4B4c5cc6c(cc5N(c5ccc(-c7ccccc7)cc5)c5cc(-n7c8c(-c9ccccc9)cccc8c8cccc(-c9ccccc9)c87)cc3c54)oc3ccccc36)cc2)cc1 ; CC(C)(C)c1cc(-c2ccccc2)c2c(c1)c1cc(C(C)(C)C)cc(-c3ccccc3)c1n2-c1cc2c3c(c1)-n1c4ccc(-c5ccccc5)cc4c4cc(-c5ccccc5)cc(c41)B3c1cc(-c3ccccc3)cc3c4cc(-c5ccccc5)ccc4n-2c13]

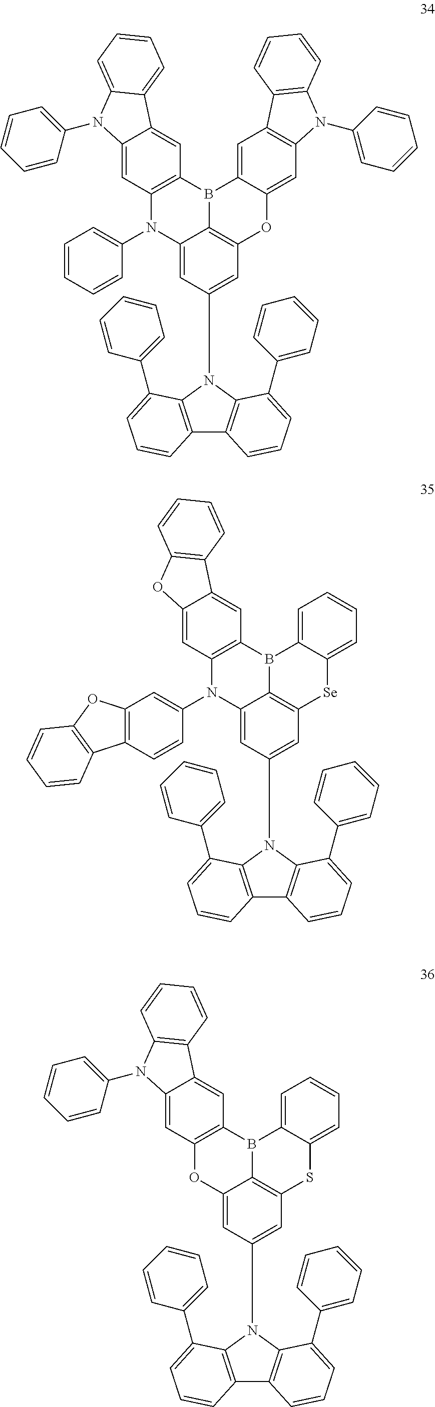

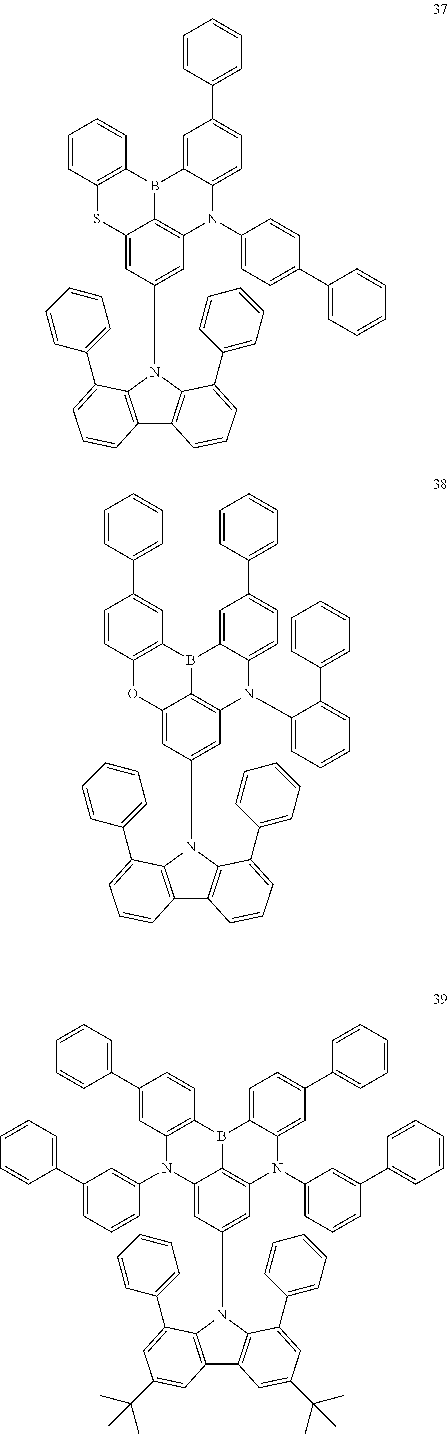 [SMILES: c1ccc(-c2ccc(N3c4ccc(-c5ccccc5)cc4B4c5ccccc5Sc5cc(-n6c7c(-c8ccccc8)cccc7c7cccc(-c8ccccc8)c76)cc3c54)cc2)cc1 ; c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)O3)cc1 ; CC(C)(C)c1cc(-c2ccccc2)c2c(c1)c1cc(C(C)(C)C)cc(-c3ccccc3)c1n2-c1cc2c3c(c1)N(c1cccc(-c4ccccc4)c1)c1cc(-c4ccccc4)ccc1B3c1ccc(-c3ccccc3)cc1N2c1cccc(-c2ccccc2)c1]

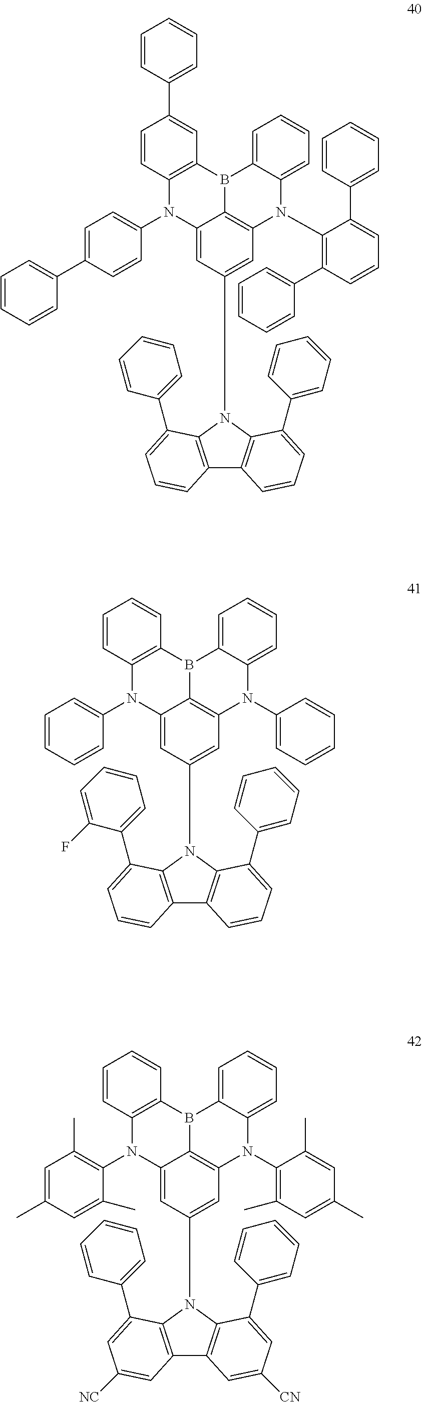

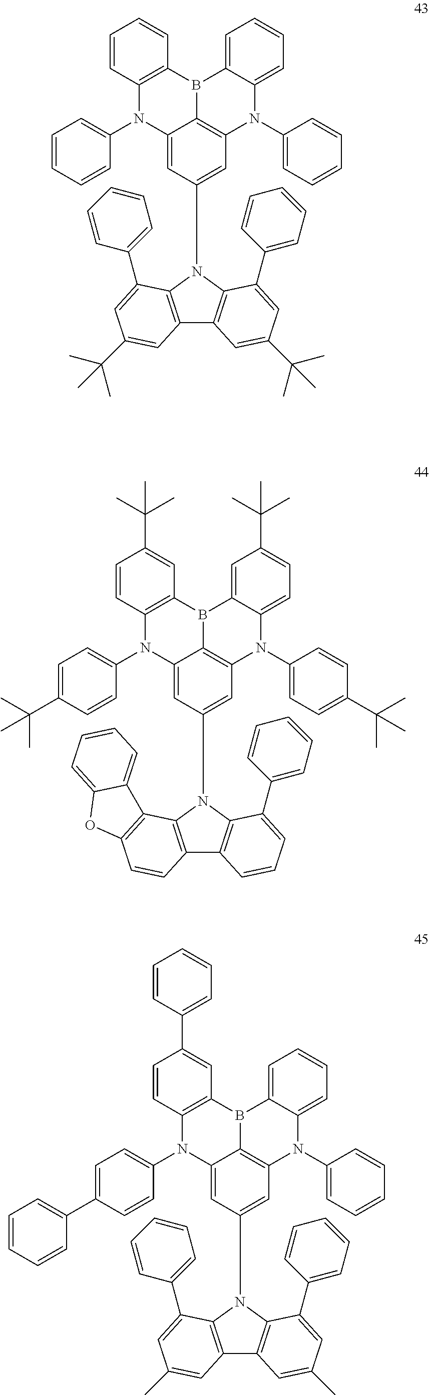 [SMILES: CC(C)(C)c1cc(-c2ccccc2)c2c(c1)c1cc(C(C)(C)C)cc(-c3ccccc3)c1n2-c1cc2c3c(c1)N(c1ccccc1)c1ccccc1B3c1ccccc1N2c1ccccc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6c(-c7ccccc7)cccc6c6ccc7oc8ccccc8c7c65)cc2c43)cc1 ; Cc1cc(-c2ccccc2)c2c(c1)c1cc(C)cc(-c3ccccc3)c1n2-c1cc2c3c(c1)N(c1ccc(-c4ccccc4)cc1)c1ccc(-c4ccccc4)cc1B3c1ccccc1N2c1ccccc1]

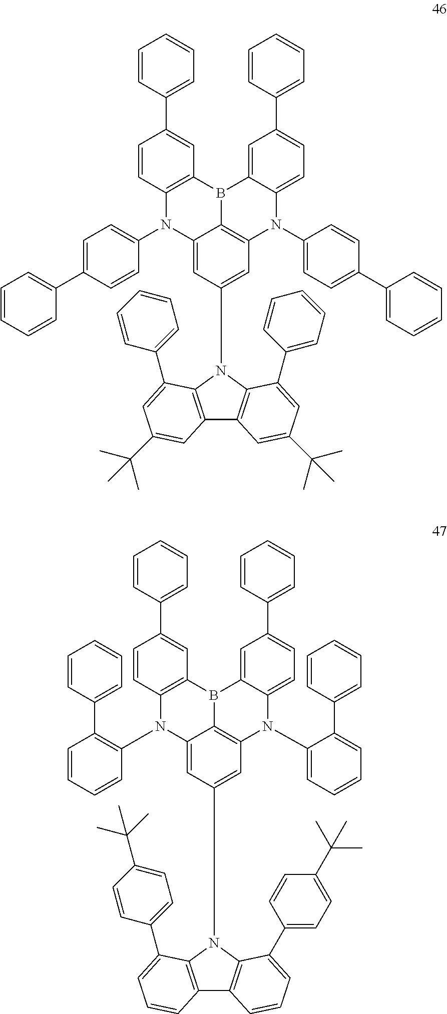 [SMILES: CC(C)(C)c1cc(-c2ccccc2)c2c(c1)c1cc(C(C)(C)C)cc(-c3ccccc3)c1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1ccc(-c2cccc3c4cccc(-c5ccc(C(C)(C)C)cc5)c4n(-c4cc5c6c(c4)N(c4ccccc4-c4ccccc4)c4ccc(-c7ccccc7)cc4B6c4cc(-c6ccccc6)ccc4N5c4ccccc4-c4ccccc4)c23)cc1]

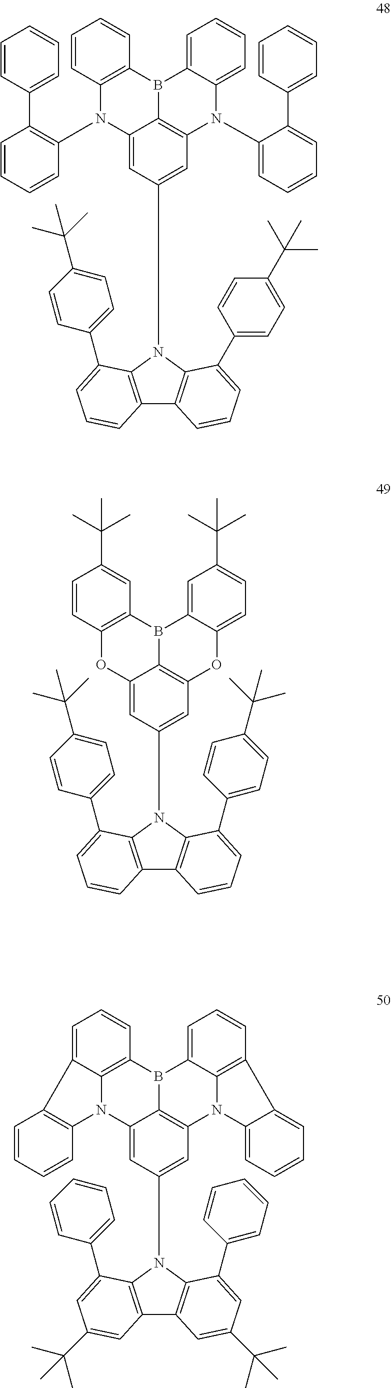

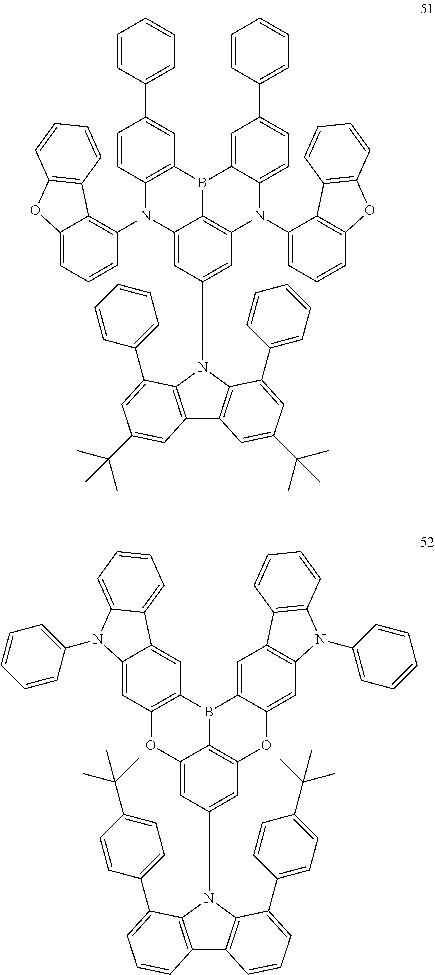 [SMILES: CC(C)(C)c1cc(-c2ccccc2)c2c(c1)c1cc(C(C)(C)C)cc(-c3ccccc3)c1n2-c1cc2c3c(c1)N(c1cccc4oc5ccccc5c14)c1ccc(-c4ccccc4)cc1B3c1cc(-c3ccccc3)ccc1N2c1cccc2oc3ccccc3c12 ; CC(C)(C)c1ccc(-c2cccc3c4cccc(-c5ccc(C(C)(C)C)cc5)c4n(-c4cc5c6c(c4)Oc4cc7c(cc4B6c4cc6c8ccccc8n(-c8ccccc8)c6cc4O5)c4ccccc4n7-c4ccccc4)c23)cc1]

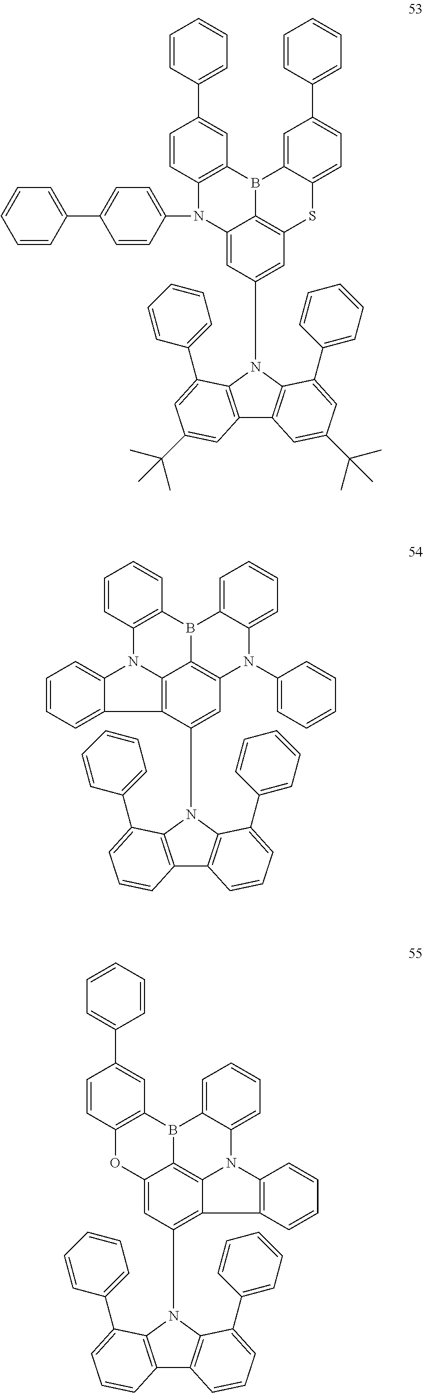 [SMILES: CC(C)(C)c1cc(-c2ccccc2)c2c(c1)c1cc(C(C)(C)C)cc(-c3ccccc3)c1n2-c1cc2c3c(c1)N(c1ccc(-c4ccccc4)cc1)c1ccc(-c4ccccc4)cc1B3c1cc(-c3ccccc3)ccc1S2 ; c1ccc(-c2cccc3c4cccc(-c5ccccc5)c4n(-c4cc5c6c7c4c4ccccc4n7-c4ccccc4B6c4ccccc4N5c4ccccc4)c23)cc1 ; c1ccc(-c2ccc3c(c2)B2c4ccccc4-n4c5ccccc5c5c(-n6c7c(-c8ccccc8)cccc7c7cccc(-c8ccccc8)c76)cc(c2c54)O3)cc1]

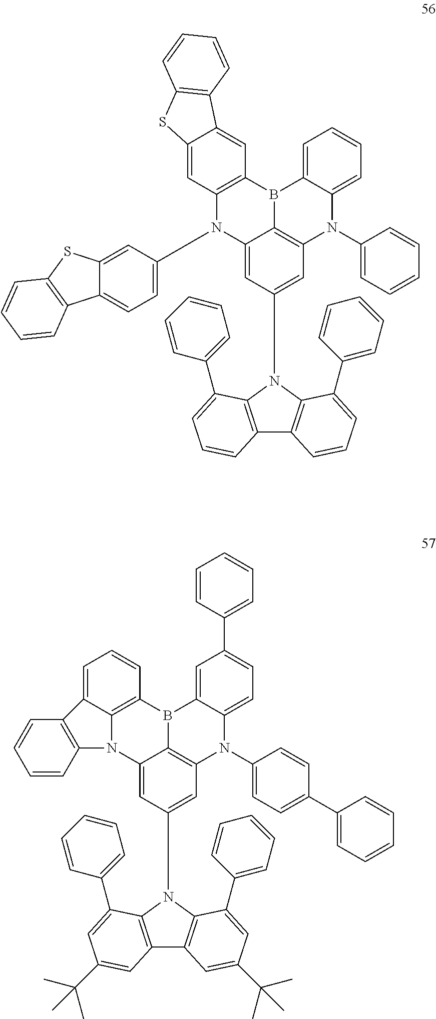 [SMILES: c1ccc(-c2cccc3c4cccc(-c5ccccc5)c4n(-c4cc5c6c(c4)N(c4ccc7c(c4)sc4ccccc47)c4cc7sc8ccccc8c7cc4B6c4ccccc4N5c4ccccc4)c23)cc1 ; CC(C)(C)c1cc(-c2ccccc2)c2c(c1)c1cc(C(C)(C)C)cc(-c3ccccc3)c1n2-c1cc2c3c(c1)-n1c4ccccc4c4cccc(c41)B3c1cc(-c3ccccc3)ccc1N2c1ccc(-c2ccccc2)cc1]

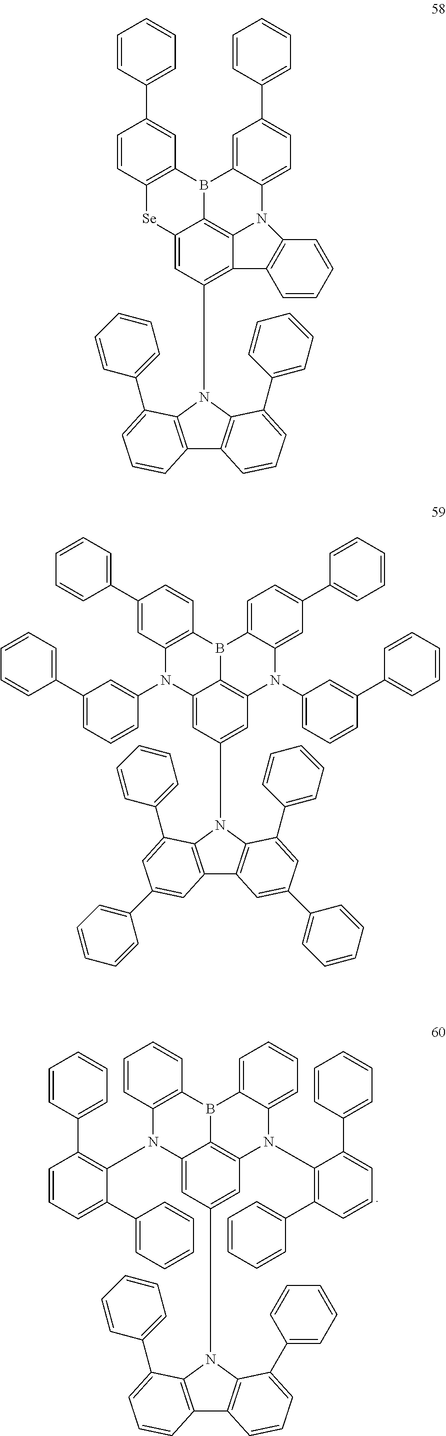 [SMILES: c1ccc(-c2ccc3c(c2)B2c4cc(-c5ccccc5)ccc4-n4c5ccccc5c5c(-n6c7c(-c8ccccc8)cccc7c7cccc(-c8ccccc8)c76)cc(c2c54)[Se]3)cc1 ; c1ccc(-c2cccc(N3c4cc(-c5ccccc5)ccc4B4c5ccc(-c6ccccc6)cc5N(c5cccc(-c6ccccc6)c5)c5cc(-n6c7c(-c8ccccc8)cc(-c8ccccc8)cc7c7cc(-c8ccccc8)cc(-c8ccccc8)c76)cc3c54)c2)cc1 ; c1ccc(-c2cccc(-c3ccccc3)c2N2c3ccccc3B3c4ccccc4N(c4c(-c5ccccc5)cccc4-c4ccccc4)c4cc(-n5c6c(-c7ccccc7)cccc6c6cccc(-c7ccccc7)c65)cc2c43)cc1]

19. A light emitting element comprising:
a first electrode;
a hole transport region on the first electrode and comprising Compound G-1 or Compound G-2;
a second electrode on the hole transport region; and
an emission layer between the hole transport region and the second electrode and comprising a polycyclic compound represented by Formula 1, 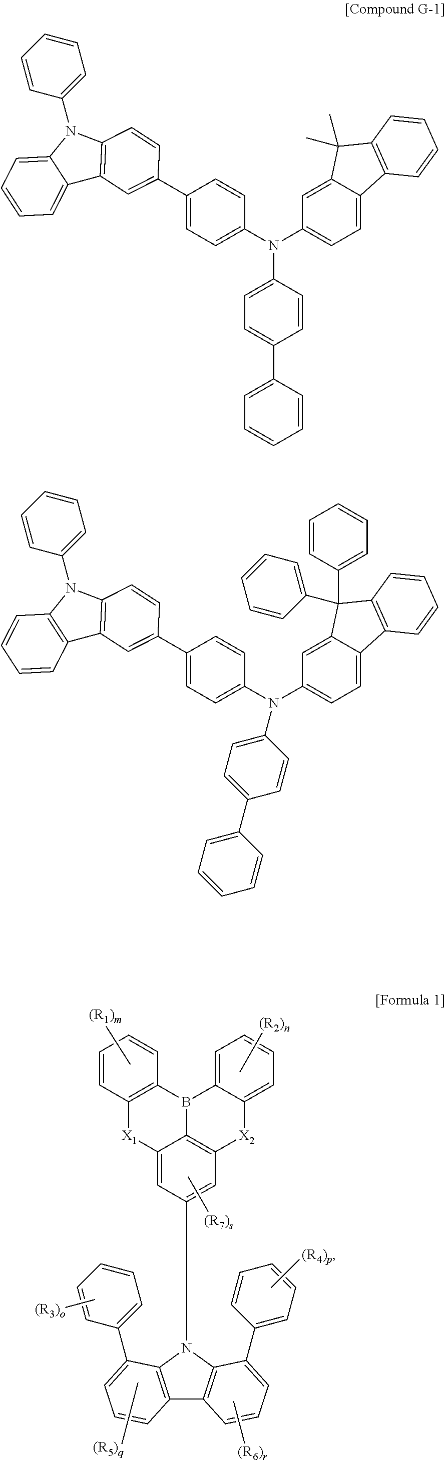
and
wherein, in Formula 1,
m and n are each independently an integer of 0 to 4,
and p are each independently an integer of 0 to 5,
q and r are each independently an integer of 0 to 3,
s is an integer of 0 to 2,
R₁ to R₇ are each independently a hydrogen atom, a deuterium atom, a halogen atom, a cyano group, a nitro group, a hydroxy group, a substituted or unsubstituted alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted oxy group, a substituted or unsubstituted thio group, or a substituted or unsubstituted amine group, and/or bonded to an adjacent group to form a ring,
X₁ and X₂ are each independently NRₐ, O, S, or Se, and
Rₐ is a substituted or unsubstituted aryl group having 6 to 12 ring-forming carbon atoms, or a substituted or unsubstituted heteroaryl group having 2 to 15 ring-forming carbon atoms, and/or bonded to an adjacent group to form a ring.

20. The light emitting element of claim 19, wherein the polycyclic compound represented by Formula 1 is represented by any one selected among Formula 7-1 to Formula 7-5: 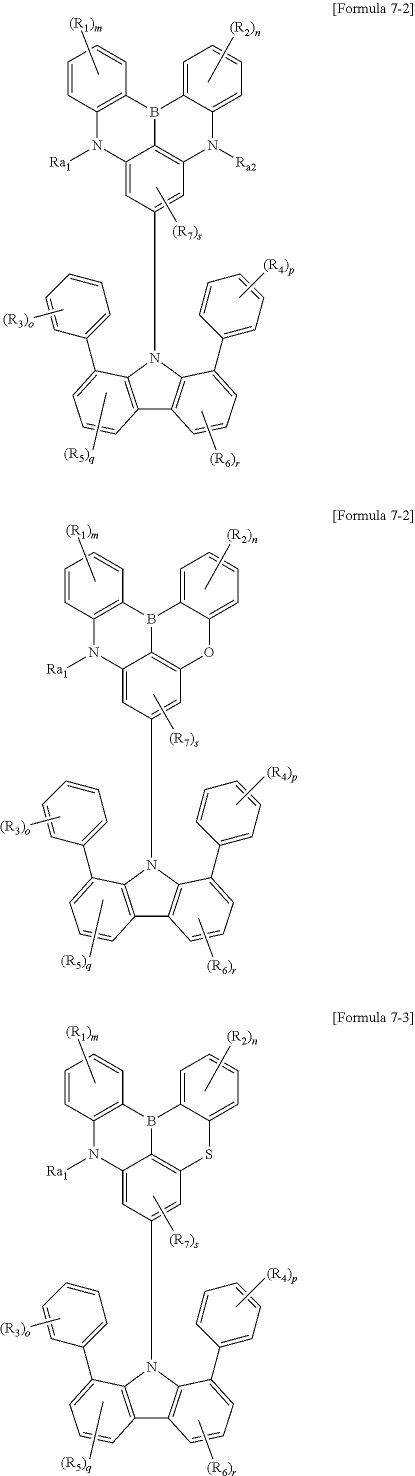 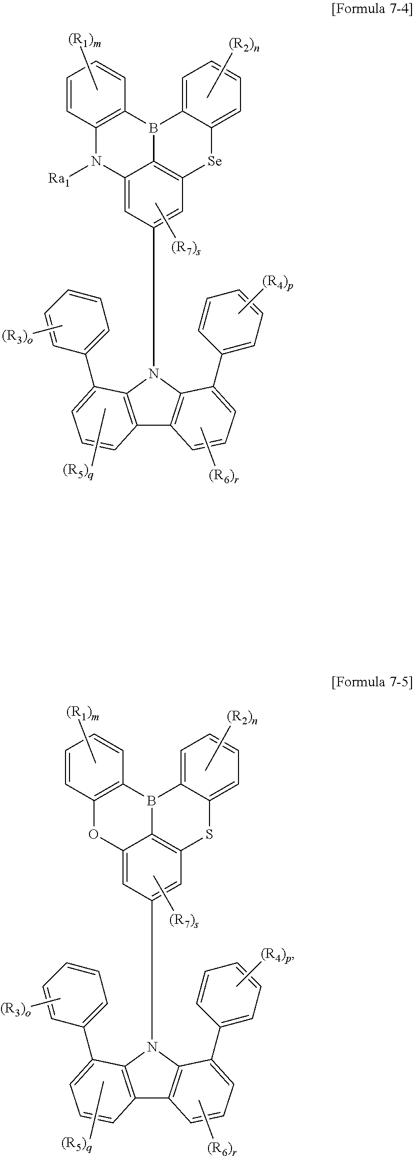
and
wherein, in Formula 7-1 to Formula 7-5,
Rₐ₁ and Rₐ₂ are each independently a hydrogen atom, a deuterium atom, a halogen atom, a cyano group, a nitro group, a hydroxy group, an alkyl group having 1 to 6 carbon atoms, a substituted or unsubstituted aryl group having 6 to 12 ring-forming carbon atoms, a substituted or unsubstituted heteroaryl group having 2 to 15 ring-forming carbon atoms, a substituted or unsubstituted alkoxy group, a substituted or unsubstituted thio group, or a substituted or unsubstituted amine group, and/or bonded to an adjacent group to form a ring, and
m to s and R₁ to R₇ are the same as respectively defined in connection with Formula 1.

21. The light emitting element of claim 19, wherein the emission layer comprises at least one selected among compounds of Compound Group 1: 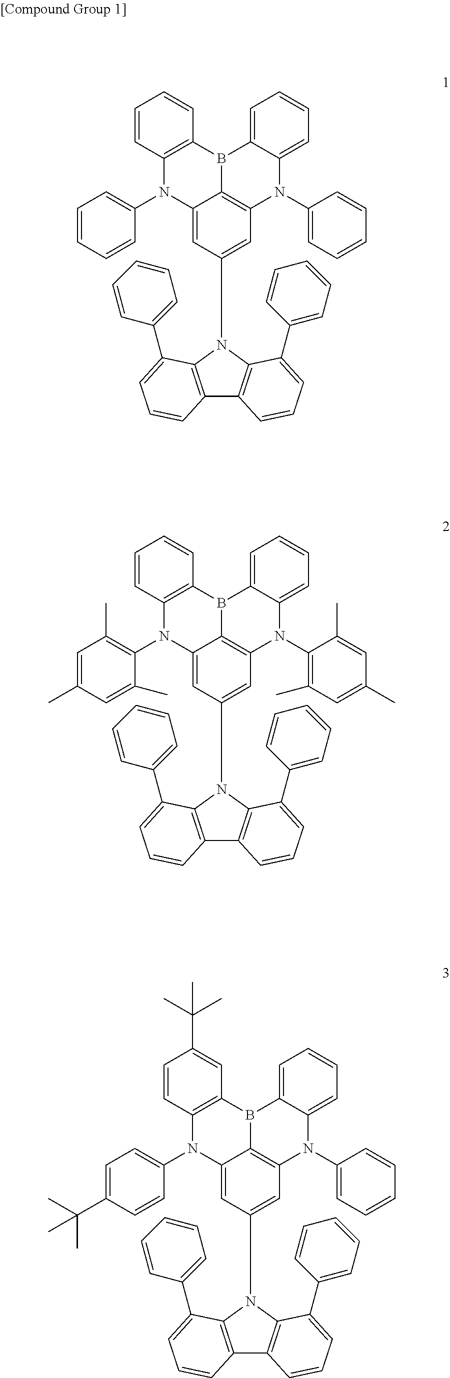 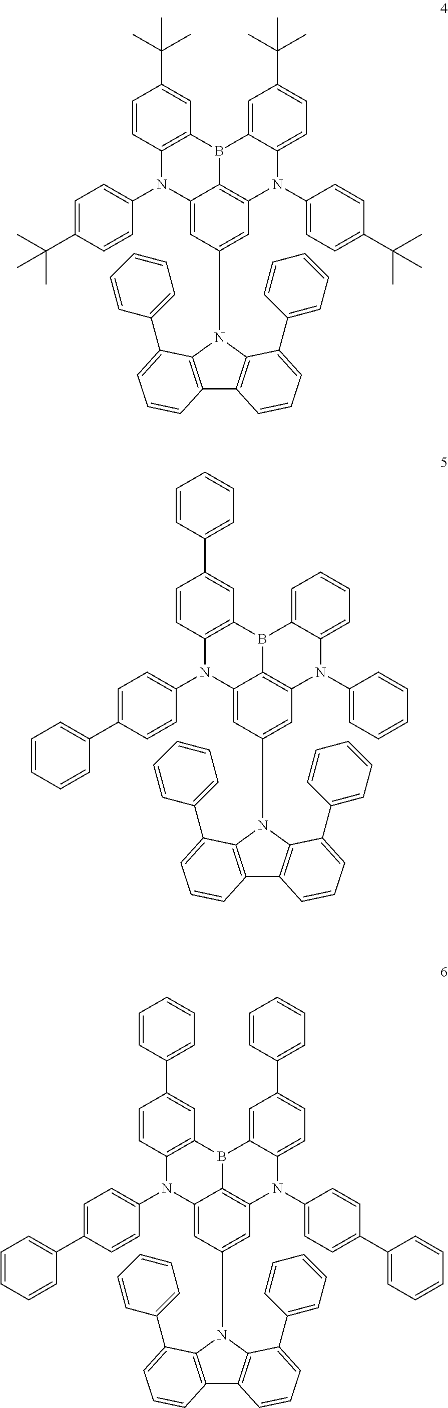 [SMILES: CC(C)(C)c1ccc(N2c3ccc(C(C)(C)C)cc3B3c4cc(C(C)(C)C)ccc4N(c4ccc(C(C)(C)C)cc4)c4cc(-n5c6c(-c7ccccc7)cccc6c6cccc(-c7ccccc7)c65)cc2c43)cc1 ; c1ccc(-c2ccc(N3c4ccc(-c5ccccc5)cc4B4c5ccccc5N(c5ccccc5)c5cc(-n6c7c(-c8ccccc8)cccc7c7cccc(-c8ccccc8)c76)cc3c54)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7c(-c8ccccc8)cccc7c7cccc(-c8ccccc8)c76)cc3c54)cc2)cc1] 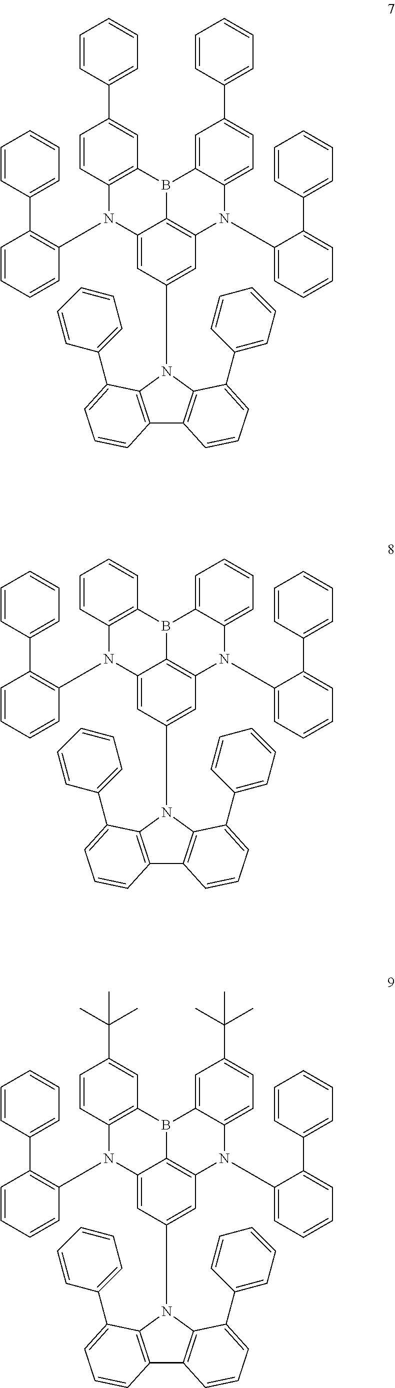 [SMILES: c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)N3c2ccccc2-c2ccccc2)cc1 ; c1ccc(-c2ccccc2N2c3ccccc3B3c4ccccc4N(c4ccccc4-c4ccccc4)c4cc(-n5c6c(-c7ccccc7)cccc6c6cccc(-c7ccccc7)c65)cc2c43)cc1 ; CC(C)(C)c1ccc2c(c1)B1c3cc(C(C)(C)C)ccc3N(c3ccccc3-c3ccccc3)c3cc(-n4c5c(-c6ccccc6)cccc5c5cccc(-c6ccccc6)c54)cc(c31)N2c1ccccc1-c1ccccc1] 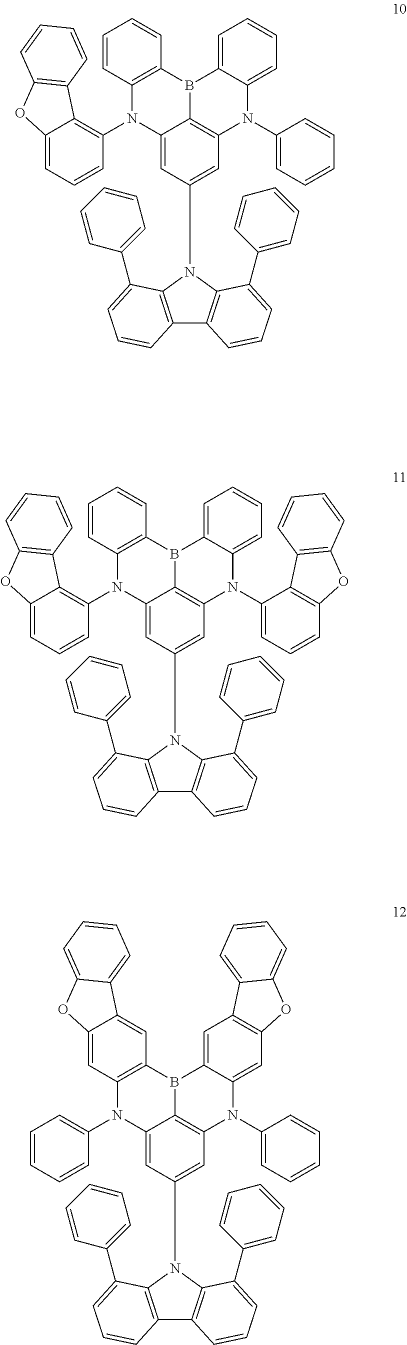 [SMILES: c1ccc(-c2cccc3c4cccc(-c5ccccc5)c4n(-c4cc5c6c(c4)N(c4cccc7oc8ccccc8c47)c4ccccc4B6c4ccccc4N5c4ccccc4)c23)cc1 ; c1ccc(-c2cccc3c4cccc(-c5ccccc5)c4n(-c4cc5c6c(c4)N(c4cccc7oc8ccccc8c47)c4ccccc4B6c4ccccc4N5c4cccc5oc6ccccc6c45)c23)cc1 ; c1ccc(-c2cccc3c4cccc(-c5ccccc5)c4n(-c4cc5c6c(c4)N(c4ccccc4)c4cc7oc8ccccc8c7cc4B6c4cc6c(cc4N5c4ccccc4)oc4ccccc46)c23)cc1] 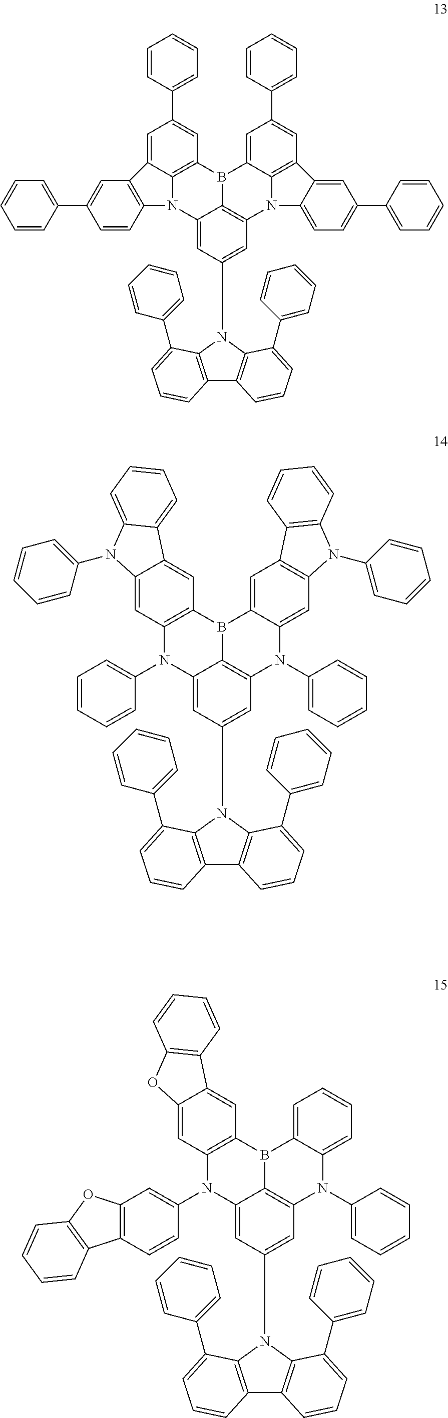 [SMILES: c1ccc(-c2ccc3c(c2)c2cc(-c4ccccc4)cc4c2n3-c2cc(-n3c5c(-c6ccccc6)cccc5c5cccc(-c6ccccc6)c53)cc3c2B4c2cc(-c4ccccc4)cc4c5cc(-c6ccccc6)ccc5n-3c24)cc1 ; c1ccc(-c2cccc3c4cccc(-c5ccccc5)c4n(-c4cc5c6c(c4)N(c4ccccc4)c4cc7c(cc4B6c4cc6c8ccccc8n(-c8ccccc8)c6cc4N5c4ccccc4)c4ccccc4n7-c4ccccc4)c23)cc1 ; c1ccc(-c2cccc3c4cccc(-c5ccccc5)c4n(-c4cc5c6c(c4)N(c4ccc7c(c4)oc4ccccc47)c4cc7oc8ccccc8c7cc4B6c4ccccc4N5c4ccccc4)c23)cc1] 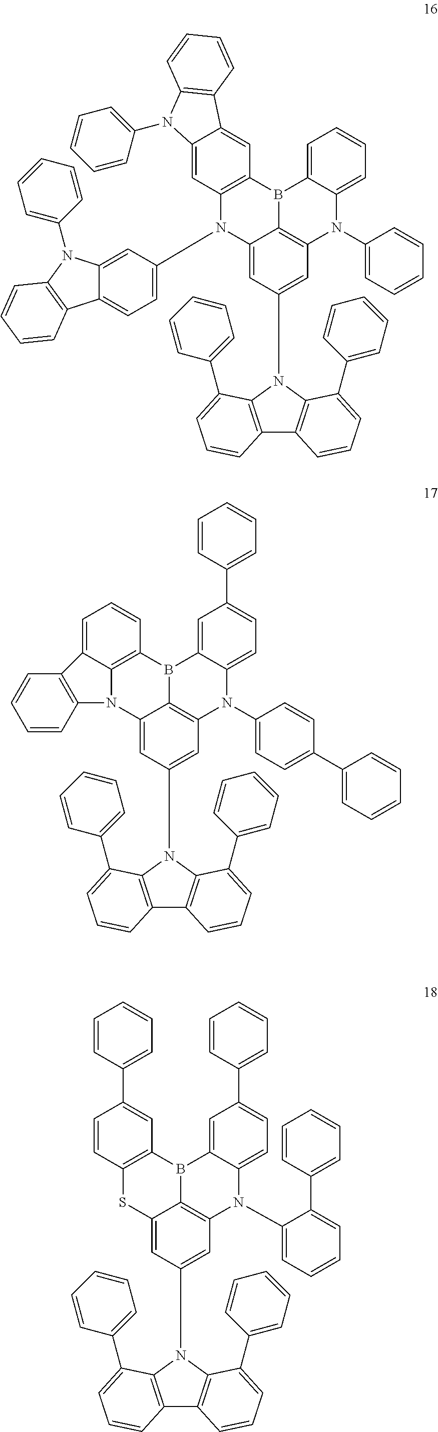 [SMILES: c1ccc(-c2cccc3c4cccc(-c5ccccc5)c4n(-c4cc5c6c(c4)N(c4ccc7c8ccccc8n(-c8ccccc8)c7c4)c4cc7c(cc4B6c4ccccc4N5c4ccccc4)c4ccccc4n7-c4ccccc4)c23)cc1 ; c1ccc(-c2ccc(N3c4ccc(-c5ccccc5)cc4B4c5c3cc(-n3c6c(-c7ccccc7)cccc6c6cccc(-c7ccccc7)c63)cc5-n3c5ccccc5c5cccc4c53)cc2)cc1 ; c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)S3)cc1] 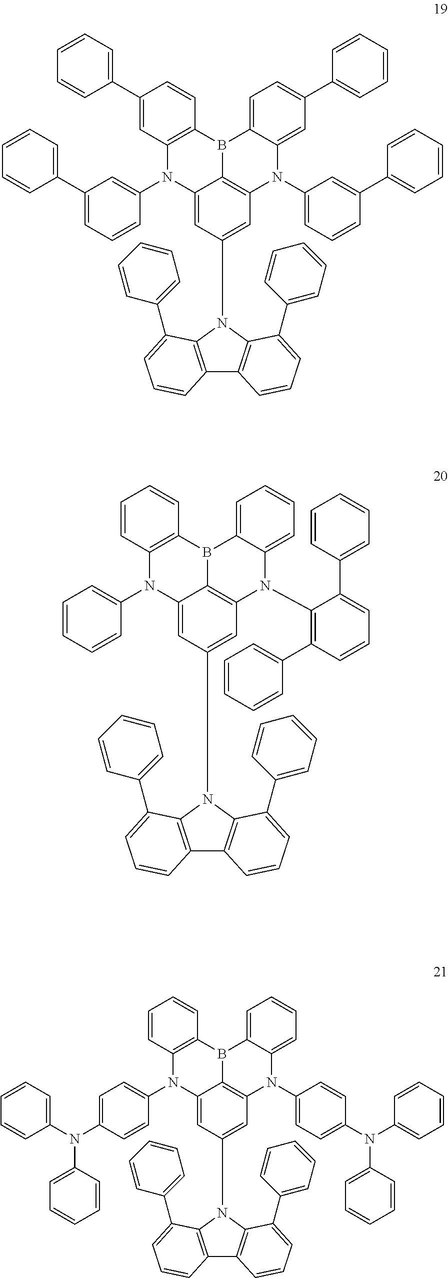 [SMILES: c1ccc(-c2cccc(N3c4cc(-c5ccccc5)ccc4B4c5ccc(-c6ccccc6)cc5N(c5cccc(-c6ccccc6)c5)c5cc(-n6c7c(-c8ccccc8)cccc7c7cccc(-c8ccccc8)c76)cc3c54)c2)cc1 ; c1ccc(-c2cccc(-c3ccccc3)c2N2c3ccccc3B3c4ccccc4N(c4ccccc4)c4cc(-n5c6c(-c7ccccc7)cccc6c6cccc(-c7ccccc7)c65)cc2c43)cc1 ; c1ccc(-c2cccc3c4cccc(-c5ccccc5)c4n(-c4cc5c6c(c4)N(c4ccc(N(c7ccccc7)c7ccccc7)cc4)c4ccccc4B6c4ccccc4N5c4ccc(N(c5ccccc5)c5ccccc5)cc4)c23)cc1] 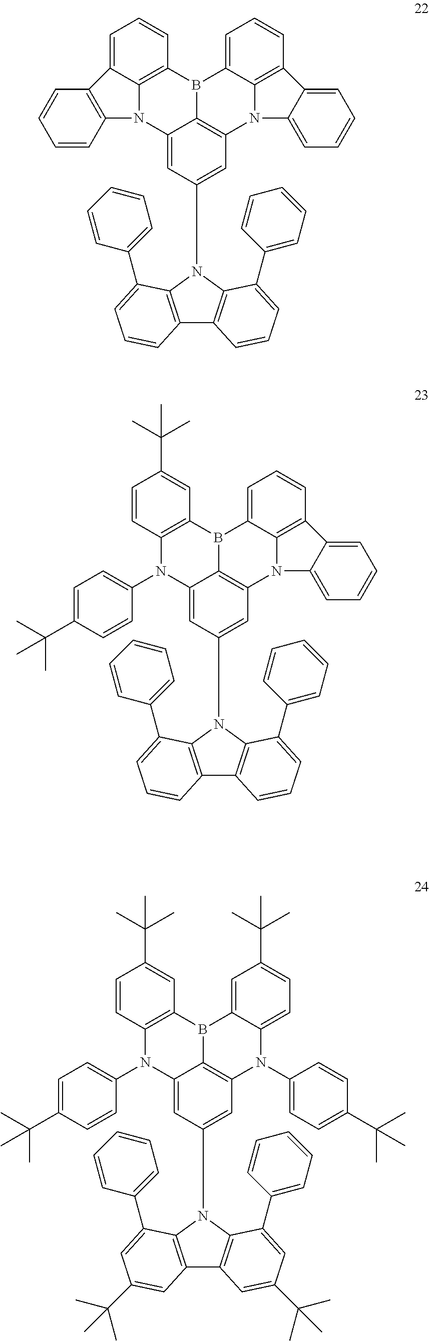 [SMILES: c1ccc(-c2cccc3c4cccc(-c5ccccc5)c4n(-c4cc5c6c(c4)-n4c7ccccc7c7cccc(c74)B6c4cccc6c7ccccc7n-5c46)c23)cc1 ; CC(C)(C)c1ccc(N2c3ccc(C(C)(C)C)cc3B3c4c2cc(-n2c5c(-c6ccccc6)cccc5c5cccc(-c6ccccc6)c52)cc4-n2c4ccccc4c4cccc3c42)cc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6c(-c7ccccc7)cc(C(C)(C)C)cc6c6cc(C(C)(C)C)cc(-c7ccccc7)c65)cc2c43)cc1] 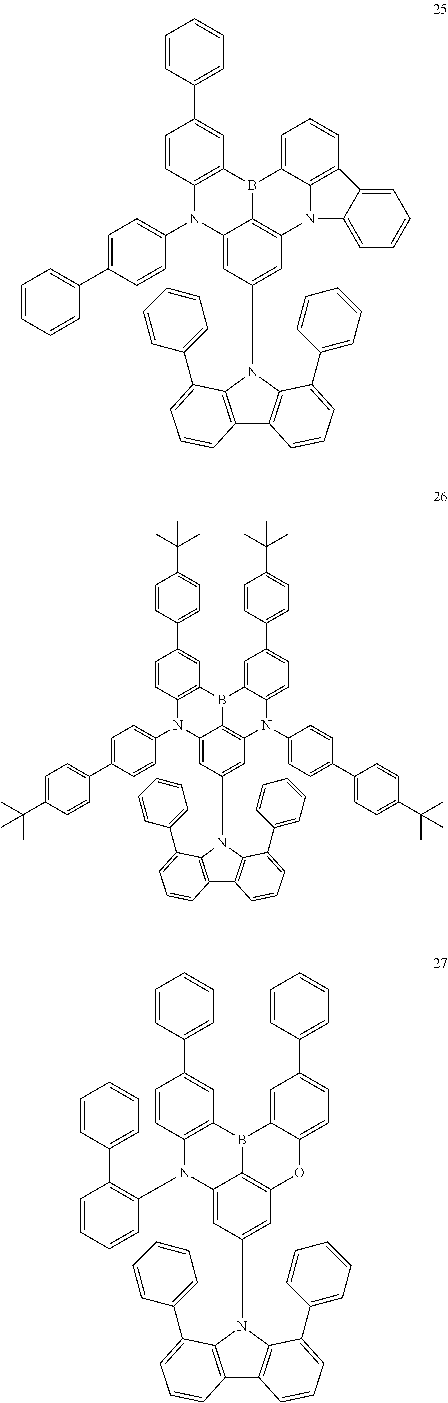 [SMILES: c1ccc(-c2ccc(N3c4ccc(-c5ccccc5)cc4B4c5c3cc(-n3c6c(-c7ccccc7)cccc6c6cccc(-c7ccccc7)c63)cc5-n3c5ccccc5c5cccc4c53)cc2)cc1 ; CC(C)(C)c1ccc(-c2ccc(N3c4ccc(-c5ccc(C(C)(C)C)cc5)cc4B4c5cc(-c6ccc(C(C)(C)C)cc6)ccc5N(c5ccc(-c6ccc(C(C)(C)C)cc6)cc5)c5cc(-n6c7c(-c8ccccc8)cccc7c7cccc(-c8ccccc8)c76)cc3c54)cc2)cc1 ; c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)O3)cc1] 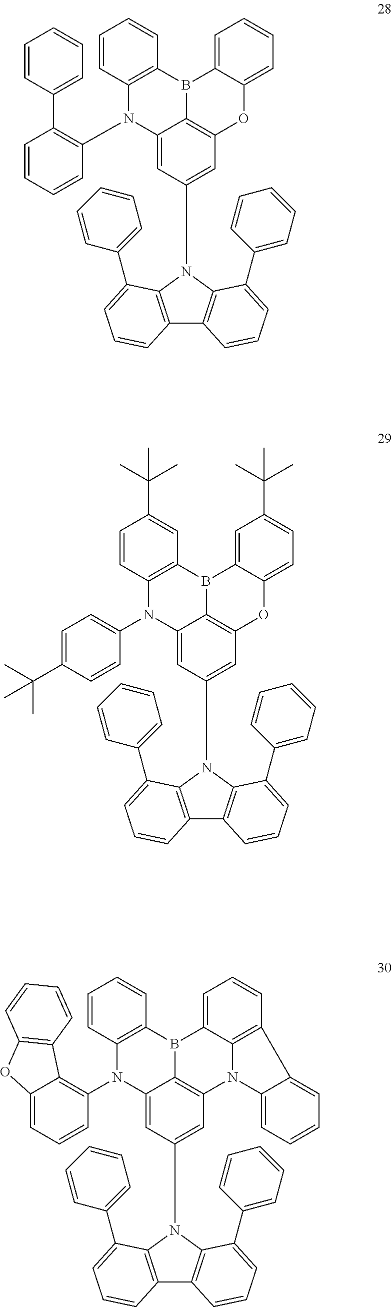 [SMILES: c1ccc(-c2ccccc2N2c3ccccc3B3c4ccccc4Oc4cc(-n5c6c(-c7ccccc7)cccc6c6cccc(-c7ccccc7)c65)cc2c43)cc1 ; CC(C)(C)c1ccc(N2c3ccc(C(C)(C)C)cc3B3c4cc(C(C)(C)C)ccc4Oc4cc(-n5c6c(-c7ccccc7)cccc6c6cccc(-c7ccccc7)c65)cc2c43)cc1 ; c1ccc(-c2cccc3c4cccc(-c5ccccc5)c4n(-c4cc5c6c(c4)-n4c7ccccc7c7cccc(c74)B6c4ccccc4N5c4cccc5oc6ccccc6c45)c23)cc1] 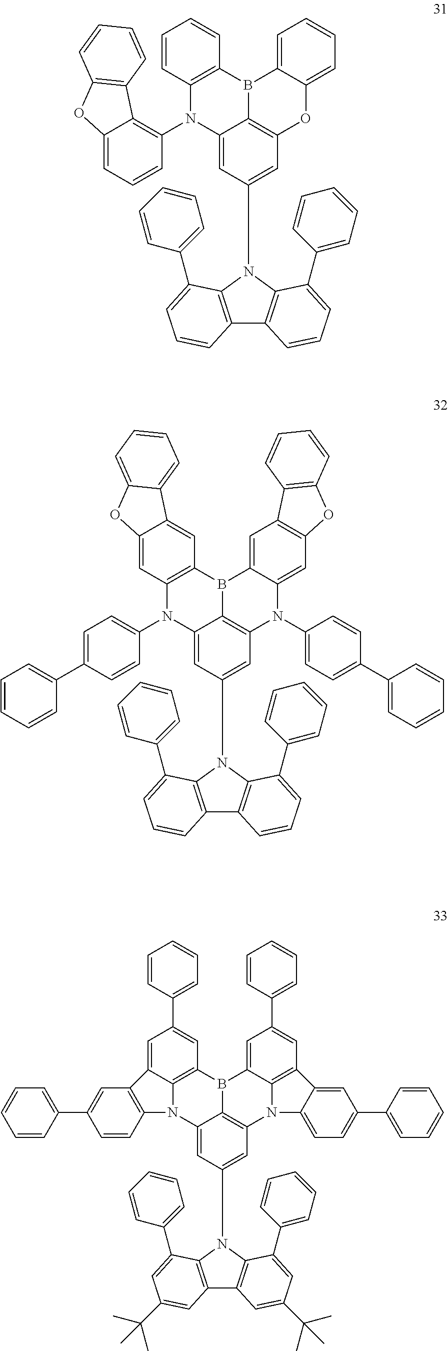 [SMILES: c1ccc(-c2cccc3c4cccc(-c5ccccc5)c4n(-c4cc5c6c(c4)N(c4cccc7oc8ccccc8c47)c4ccccc4B6c4ccccc4O5)c23)cc1 ; c1ccc(-c2ccc(N3c4cc5oc6ccccc6c5cc4B4c5cc6c(cc5N(c5ccc(-c7ccccc7)cc5)c5cc(-n7c8c(-c9ccccc9)cccc8c8cccc(-c9ccccc9)c87)cc3c54)oc3ccccc36)cc2)cc1 ; CC(C)(C)c1cc(-c2ccccc2)c2c(c1)c1cc(C(C)(C)C)cc(-c3ccccc3)c1n2-c1cc2c3c(c1)-n1c4ccc(-c5ccccc5)cc4c4cc(-c5ccccc5)cc(c41)B3c1cc(-c3ccccc3)cc3c4cc(-c5ccccc5)ccc4n-2c13] 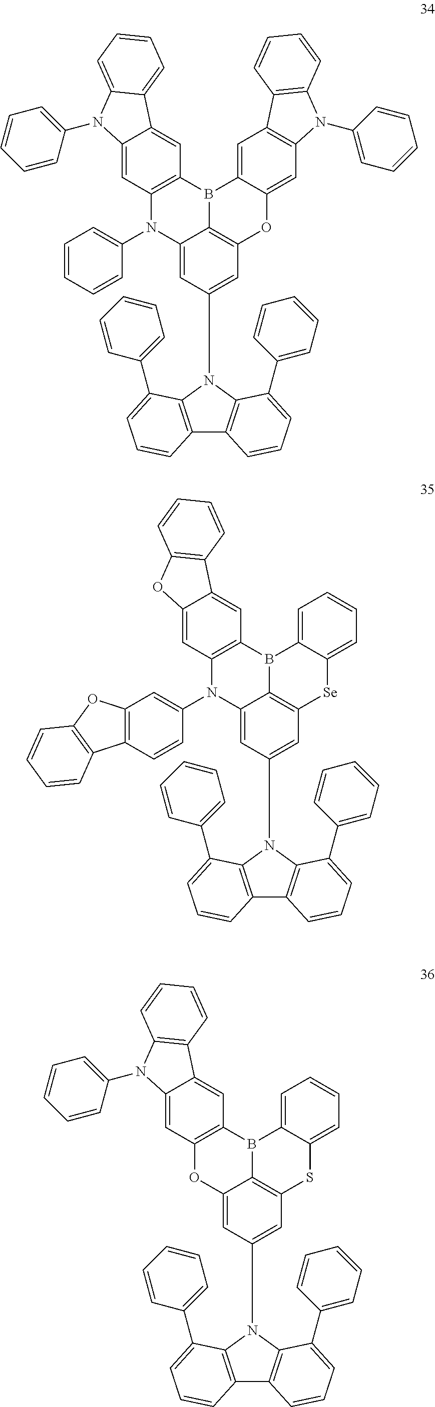 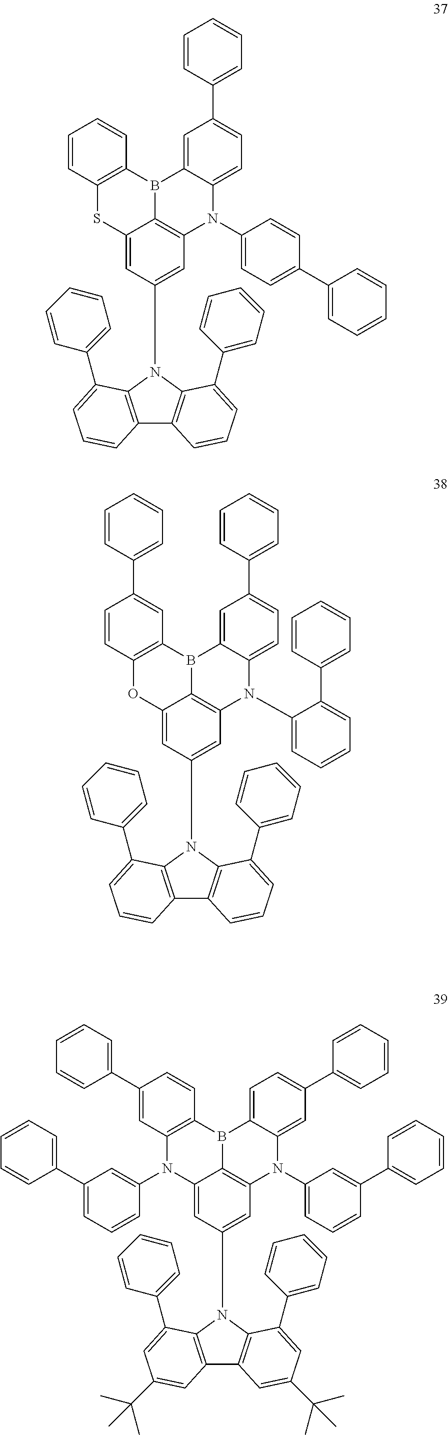 [SMILES: c1ccc(-c2ccc(N3c4ccc(-c5ccccc5)cc4B4c5ccccc5Sc5cc(-n6c7c(-c8ccccc8)cccc7c7cccc(-c8ccccc8)c76)cc3c54)cc2)cc1 ; c1ccc(-c2ccc3c(c2)B2c4cc(-c5ccccc5)ccc4N(c4ccccc4-c4ccccc4)c4cc(-n5c6c(-c7ccccc7)cccc6c6cccc(-c7ccccc7)c65)cc(c42)O3)cc1 ; CC(C)(C)c1cc(-c2ccccc2)c2c(c1)c1cc(C(C)(C)C)cc(-c3ccccc3)c1n2-c1cc2c3c(c1)N(c1cccc(-c4ccccc4)c1)c1cc(-c4ccccc4)ccc1B3c1ccc(-c3ccccc3)cc1N2c1cccc(-c2ccccc2)c1] 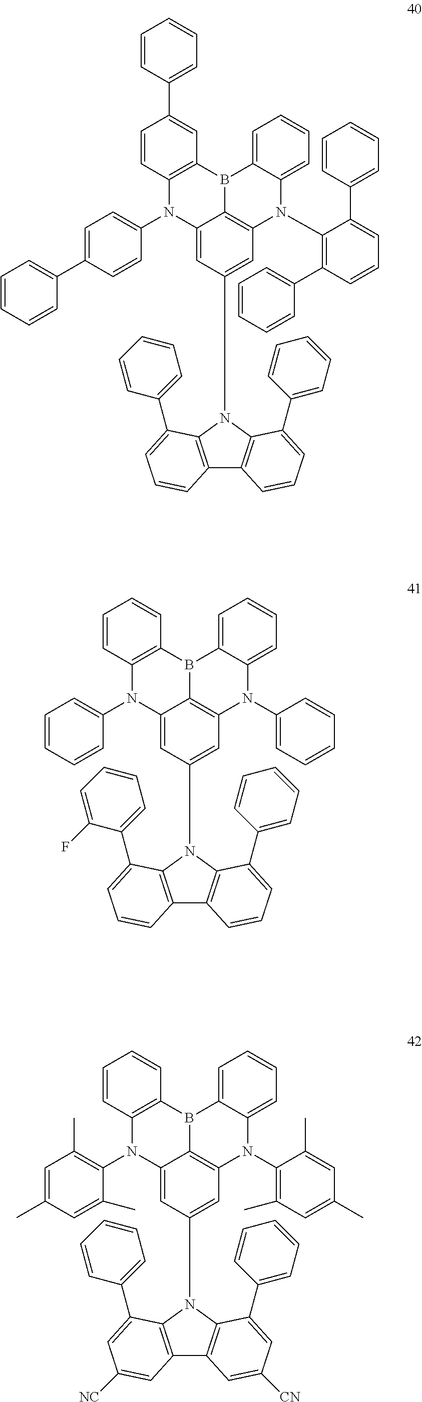 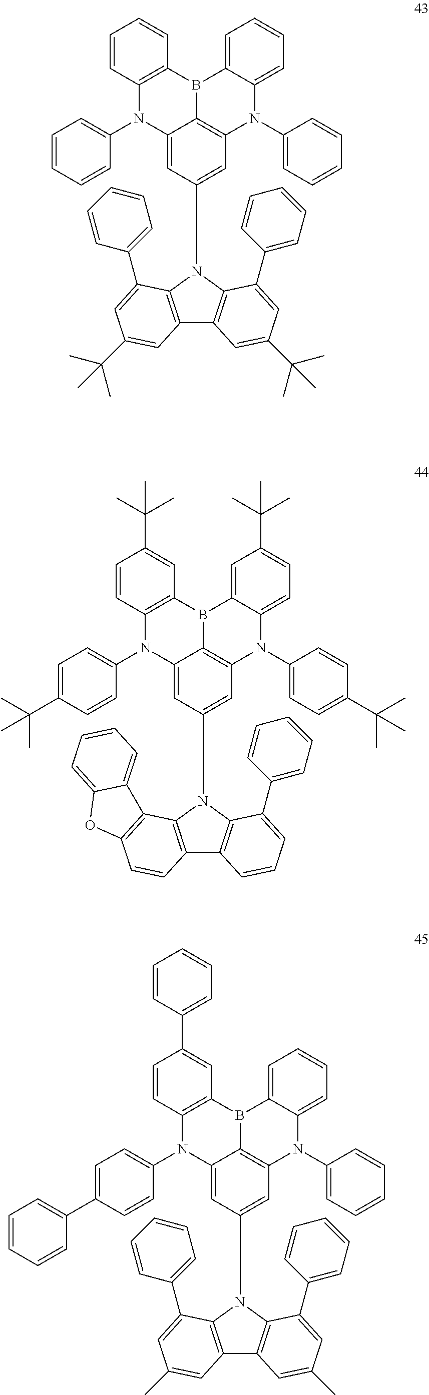 [SMILES: CC(C)(C)c1cc(-c2ccccc2)c2c(c1)c1cc(C(C)(C)C)cc(-c3ccccc3)c1n2-c1cc2c3c(c1)N(c1ccccc1)c1ccccc1B3c1ccccc1N2c1ccccc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6c(-c7ccccc7)cccc6c6ccc7oc8ccccc8c7c65)cc2c43)cc1 ; Cc1cc(-c2ccccc2)c2c(c1)c1cc(C)cc(-c3ccccc3)c1n2-c1cc2c3c(c1)N(c1ccc(-c4ccccc4)cc1)c1ccc(-c4ccccc4)cc1B3c1ccccc1N2c1ccccc1] 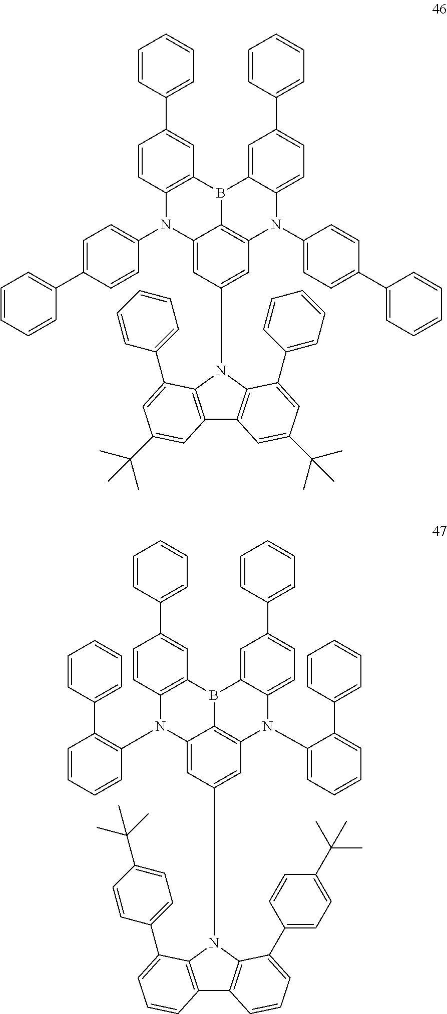 [SMILES: CC(C)(C)c1cc(-c2ccccc2)c2c(c1)c1cc(C(C)(C)C)cc(-c3ccccc3)c1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1ccc(-c2cccc3c4cccc(-c5ccc(C(C)(C)C)cc5)c4n(-c4cc5c6c(c4)N(c4ccccc4-c4ccccc4)c4ccc(-c7ccccc7)cc4B6c4cc(-c6ccccc6)ccc4N5c4ccccc4-c4ccccc4)c23)cc1] 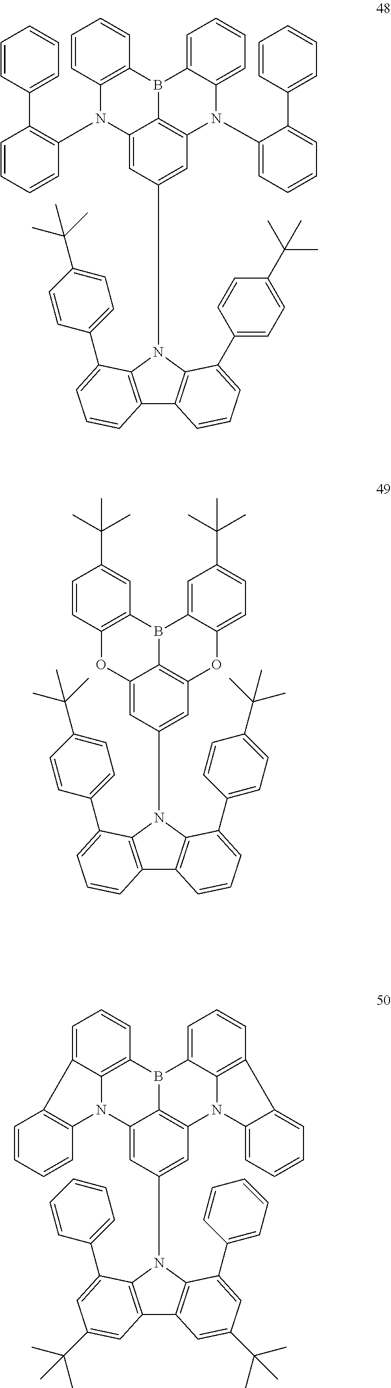 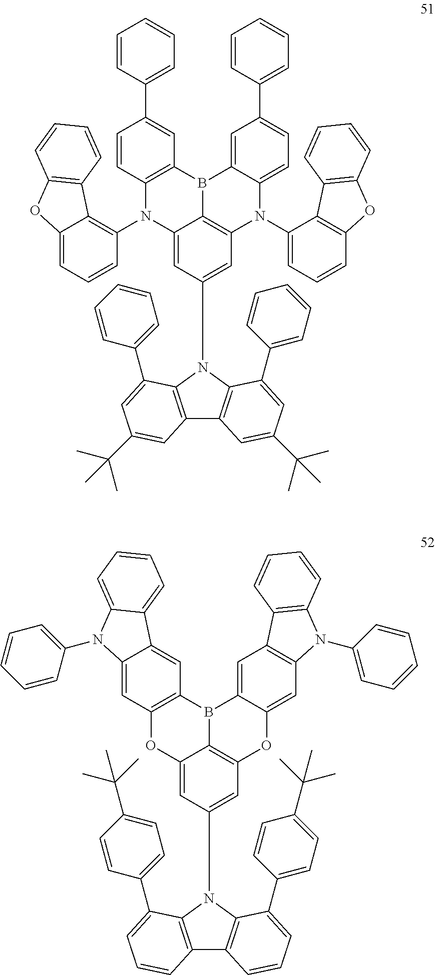 [SMILES: CC(C)(C)c1cc(-c2ccccc2)c2c(c1)c1cc(C(C)(C)C)cc(-c3ccccc3)c1n2-c1cc2c3c(c1)N(c1cccc4oc5ccccc5c14)c1ccc(-c4ccccc4)cc1B3c1cc(-c3ccccc3)ccc1N2c1cccc2oc3ccccc3c12 ; CC(C)(C)c1ccc(-c2cccc3c4cccc(-c5ccc(C(C)(C)C)cc5)c4n(-c4cc5c6c(c4)Oc4cc7c(cc4B6c4cc6c8ccccc8n(-c8ccccc8)c6cc4O5)c4ccccc4n7-c4ccccc4)c23)cc1] 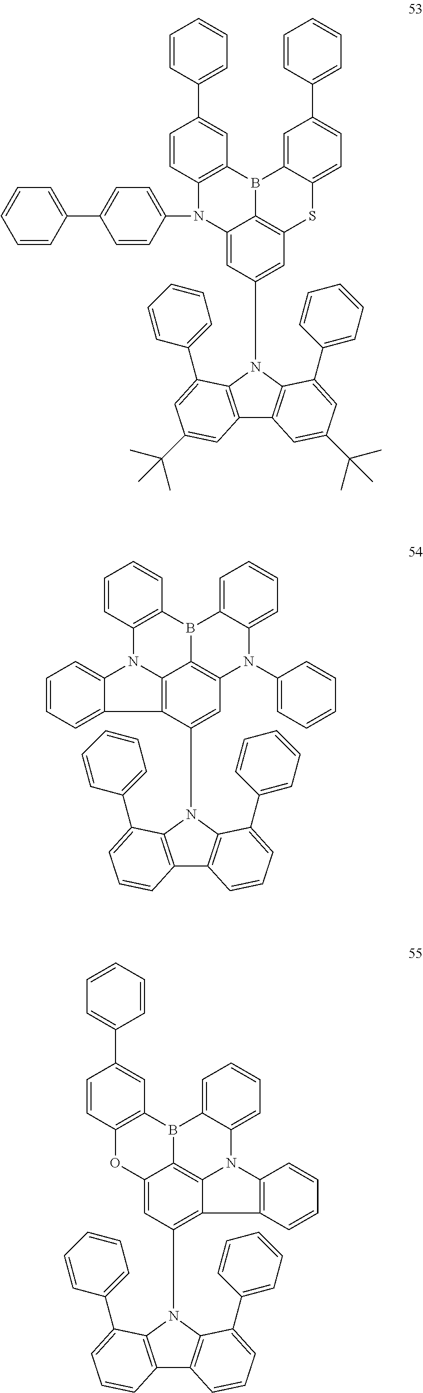 [SMILES: CC(C)(C)c1cc(-c2ccccc2)c2c(c1)c1cc(C(C)(C)C)cc(-c3ccccc3)c1n2-c1cc2c3c(c1)N(c1ccc(-c4ccccc4)cc1)c1ccc(-c4ccccc4)cc1B3c1cc(-c3ccccc3)ccc1S2 ; c1ccc(-c2cccc3c4cccc(-c5ccccc5)c4n(-c4cc5c6c7c4c4ccccc4n7-c4ccccc4B6c4ccccc4N5c4ccccc4)c23)cc1 ; c1ccc(-c2ccc3c(c2)B2c4ccccc4-n4c5ccccc5c5c(-n6c7c(-c8ccccc8)cccc7c7cccc(-c8ccccc8)c76)cc(c2c54)O3)cc1] 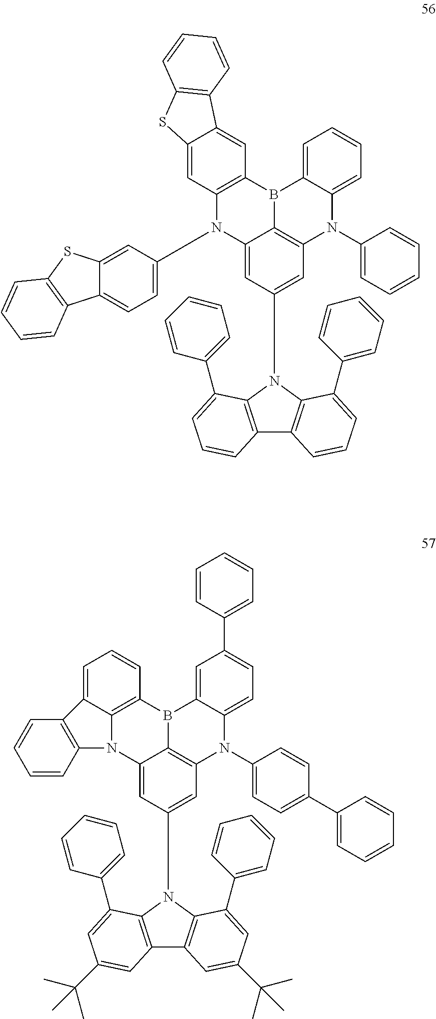 [SMILES: c1ccc(-c2cccc3c4cccc(-c5ccccc5)c4n(-c4cc5c6c(c4)N(c4ccc7c(c4)sc4ccccc47)c4cc7sc8ccccc8c7cc4B6c4ccccc4N5c4ccccc4)c23)cc1 ; CC(C)(C)c1cc(-c2ccccc2)c2c(c1)c1cc(C(C)(C)C)cc(-c3ccccc3)c1n2-c1cc2c3c(c1)-n1c4ccccc4c4cccc(c41)B3c1cc(-c3ccccc3)ccc1N2c1ccc(-c2ccccc2)cc1] 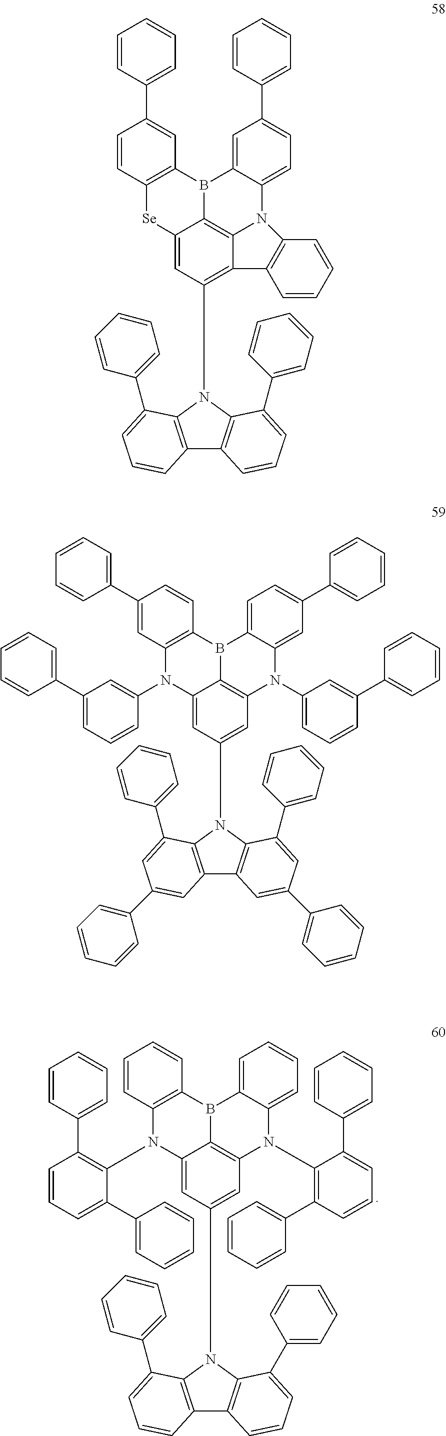 [SMILES: c1ccc(-c2ccc3c(c2)B2c4cc(-c5ccccc5)ccc4-n4c5ccccc5c5c(-n6c7c(-c8ccccc8)cccc7c7cccc(-c8ccccc8)c76)cc(c2c54)[Se]3)cc1 ; c1ccc(-c2cccc(N3c4cc(-c5ccccc5)ccc4B4c5ccc(-c6ccccc6)cc5N(c5cccc(-c6ccccc6)c5)c5cc(-n6c7c(-c8ccccc8)cc(-c8ccccc8)cc7c7cc(-c8ccccc8)cc(-c8ccccc8)c76)cc3c54)c2)cc1 ; c1ccc(-c2cccc(-c3ccccc3)c2N2c3ccccc3B3c4ccccc4N(c4c(-c5ccccc5)cccc4-c4ccccc4)c4cc(-n5c6c(-c7ccccc7)cccc6c6cccc(-c7ccccc7)c65)cc2c43)cc1]
